(19) United States
(12) Patent Application Publication
(10) Pub. No.: US 2026/0362673 A1
(43) Pub. Date: Nov. 12, 2026

(54) SEMICONDUCTOR DEVICE HAVING SELF-ALIGNED PAD

(71) Applicant: Samsung Electronics Co., Ltd., Suwon-si (KR)

(72) Inventors: Minju Kang, Suwon-si (KR); YONG KWAN KIM, Suwon-si (KR); HUI-JUNG KIM, Suwon-si (KR); HYUNJIN LEE, Suwon-si (KR); HEEJAE CHAE, Suwon-si (KR)

(21) Appl. No.: 19/427,885

(22) Filed: Dec. 19, 2025

(30) Foreign Application Priority Data
May 8, 2025 (KR) 10-2025-0059788

(51) Int. Cl. H10B 12/00; H10D 1/68

(52) U.S. Cl. CPC H10B 12/315; H10B 12/34; H10B 12/482; H10B 12/488; H10D 1/716; H10B 12/0335; H10B 12/053

(57) ABSTRACT

A semiconductor device may include a substrate including an active region extending in a first direction, and including a first end portion, a central portion, and a second end portion, a word line structure extending in a second direction, a bit line structure extending in a third direction and connected to the first end portion, a landing pad connected to the second end portion, a first contact pad positioned between the first end portion and the bit line structure, and a second contact pad positioned between the second end portion and the landing pad, the active region includes a first portion positioned at a lower level than the contact pads in a fourth direction, and a second portion extending in the fourth direction along a side of the contact pads. The first portion of the active region overlaps the contact pads and the second portion in the fourth direction.

### CROSS-REFERENCE TO RELATED APPLICATION

This application claims priority to and the benefit of Korean Patent Application No. 10-2025-0059788 filed with the Korean Intellectual Property Office on May 8, 2025, the entire contents of which are incorporated herein by reference.

### BACKGROUND

### 1. Field

This disclosure relates to a semiconductor device.

### 2. Description of the Related Art

A technology for increasing the integration degree of a semiconductor device is required. In the case of a two-dimensional semiconductor device, the integration degree is mainly determined by the area occupied by a unit memory cell, and the integration degree in this aspect may be dependent on the level of fine pattern formation technology.

However, in the case of fine pattern formation technology, since expensive equipment is required, although the integration degree of two-dimensional semiconductor devices is increasing, it is still limited. Accordingly, three-dimensional semiconductor memory devices including memory cells arranged in three dimensions are being proposed.

As constituents included in three-dimensional semiconductor memory devices become integrated and miniaturized, it is important to minimize influences between the constituents included in semiconductor devices in order to enhance operational performance of the semiconductor device.

### SUMMARY

The embodiments are for providing a semiconductor device having improved reliability and productivity.

A semiconductor device according to an embodiment includes a substrate including an active region extending lengthwise in a first direction, the active region including a first end portion, a second end portion, and a central portion between the first end portion and the second end portion, a word line structure extending lengthwise in a second direction crossing the first direction, the word line structure being positioned in the central portion of the active region, a bit line structure extending lengthwise in a third direction crossing the first direction and the second direction and connected to the first end portion of the active region, a landing pad electrically connected to the second end portion of the active region, a first contact pad positioned between the first end portion of the active region and the bit line structure, and a second contact pad positioned the second end portion of the active region and the landing pad, wherein the active region includes first contact pad and the second contact pad in a fourth direction perpendicular to the first direction, the second direction, and the third direction, and a second portion extending in the fourth direction from the first portion along side surfaces of the first contact pad and the second contact pad, and the first portion of the active region overlaps the first contact pad, the second contact pad, and the second portion in the fourth direction.

A semiconductor device according to an embodiment includes a substrate including an active region extending lengthwise in a first direction, the active region comprising a first end portion, a second end portion, and a central portion between the first end portion and the second end portion in the first direction, a word line structure extending lengthwise in a second direction crossing the first direction and positioned at the central portion of the active region, a bit line structure extending lengthwise in a third direction intersecting the first direction and the second direction, and connected to the first end of the active region, a storage contact connected to the second end of the active region, and a plurality of contact pads including a first contact pad positioned between the first end portion of the active region and the bit line structure, and a second contact pad positioned between the second end portion of the active region and the storage contact, wherein the active region includes a first portion positioned at a level lower than the plurality of contact pads in a fourth direction perpendicular to the first direction, the second direction, and the third direction, and a second portion extending in the fourth direction from the first portion along a side surface of the plurality of contact pads, the first portion of the active region overlaps the plurality of contact pads and the second portion in a fourth direction, and the uppermost surface of the first contact pad and the uppermost surface of the second contact pad are each positioned at different levels in the fourth direction.

A semiconductor device according to an embodiment includes a substrate including an active region extending lengthwise in a first direction and including a first end portion and a second end portion spaced apart from each other by a central portion in the first direction, a word line structure extending lengthwise in a second direction crossing the first direction and the central portion of the active region, a bit line structure extending lengthwise in a third direction crossing the first direction and the second direction and connected to the first end of the active region, a storage contact connected to the second end of the active region, a landing pad positioned on the storage contact, a capacitor positioned on the landing pad, a first contact pad positioned between the first end of the active region and the bit line structure, and a second contact pad positioned between the second end of the active region and the storage contact, wherein the active region includes a first portion positioned at a lower level than the first contact pad and the second contact pad in a fourth direction perpendicular to the first direction, the second direction, and the third direction, and a second portion extending from the first portion in a fourth direction along side surfaces of the first contact pad and the second contact pad, wherein the first portion of the active region overlaps the first contact pad, the second contact pad, and the second portion in the fourth direction, and the uppermost surface of the second portion of the active region is positioned at a lower level in the fourth direction than the uppermost surface of the first contact pad and an uppermost surface of the second contact pad.

According to embodiments, as a contact pad is formed to be self-aligned at both end portions of an active region included in a substrate, it may be possible to prevent adjacent active regions and/or components connected to the active region from being shorted through the contact pad due to the contact pad being mis-aligned with the active region.

In addition, according to embodiments, since the lower surface and side surface of the contact pad are formed to be in contact with the active region, the contact area between the active region and the contact pad may be increased.

### BRIEF DESCRIPTION OF THE DRAWINGS

FIG. 1 is a plan view of a portion of a semiconductor device according to an embodiment.

FIG. 2 is a cross-sectional view illustrating the cross-sections taken along lines A-A′, B-B′, and C-C′ of FIG. 1.

FIG. 3 is a cross-sectional view illustrating the cross-sections taken along the D-D′, E-E′, and F-F′ lines of FIG. 1.

FIG. 4 is a cross-sectional view illustrating a section taken along the G-G′ line of FIG. 1.

FIG. 5 is a partially enlarged view showing the R1 region of FIG. 2.

FIG. 6 is a partially enlarged view showing the R2 region of FIG. 2.

FIG. 7 is a partially enlarged view showing the R3 region of FIG. 4.

FIGS. 8 to 19 are views illustrating cross-sections of a semiconductor device according to some embodiments.

FIGS. 20 to 55 are drawings for explaining a method of manufacturing a semiconductor device according to an embodiment.

### DETAILED DESCRIPTION

Hereinafter, embodiments of the invention will be described in detail with reference to the accompanying drawings so that those skilled in the art to which the invention pertains may easily carry out the invention. The invention may be embodied in various different forms and is not limited to the embodiments described herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

In order to clearly explain embodiments of the invention, a description of elements unrelated to the invention may be omitted, and throughout the entire specification, the same reference numerals are used for identical or similar components.

In addition, the size and thickness of each component shown in the drawings are depicted arbitrarily for the convenience of description, and thus, the invention is not necessarily limited to what is illustrated. The thickness has been enlarged in the drawings to clearly illustrate various layers and regions. In the drawings, for convenience of explanation, the thicknesses of some layers and regions are illustrated in an exaggerated manner.

In addition, when a portion such as a layer, film, region, or plate is described as being on or above another portion, this includes not only cases where it is directly on the other portion but also cases where another portion is therebetween. Conversely, when any portion is described as being “directly on” another portion, it means that there is no other portion in between. In addition, stating that a portion is “on” or “on” with respect to a reference portion means that it is positioned above or below the reference portion, and does not necessarily mean that it is positioned “on” or “on” in a direction opposite to gravity.

It will be understood that when an element is referred to as being “connected” or “coupled” to another element, it can be directly connected or coupled to the other element or intervening elements may be present. In contrast, when an element is referred to as being “directly connected” or “directly coupled” to another element, or as “contacting” or “in contact with” another element (or using any form of the word “contact”), there are no intervening elements at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

The various pads described herein may generally have a planar upper surface having horizontal dimensions (e.g., in both the X and Y directions) that are both larger than wiring to which the pad is connected to facilitate connections thereto (e.g., to provide a larger surface to contact a later formed via). For example, a horizontal wiring may be integrally formed with a pad (e.g., patterned out of the same metal layer) such that the wiring and pad have coplanar upper surfaces, with both of the X and Y horizontal dimensions of the pad being greater than the horizontal width of the wiring (e.g., greater or equal to 3 times the horizontal width of the wiring). In other examples, a pad may be discretely formed such that it is not in contact with any wiring formed at its vertical level within the device and is only connected to wiring within the device by vias. From a top down view, a pad may have a symmetrical shape (e.g., a square or rectangular footprint) and may have X and Y horizontal dimensions that are about the same (e.g., within half to two times of the other).

In addition, throughout the entire specification, when any portion is said to “include” or “contain” any component, this means that unless specifically stated otherwise, it does not exclude other components but may further include other components.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

In addition, throughout the specification, when referring to “in a plan view,” this means when the relevant portion is viewed from above, and when referring to “in cross-section,” this means when a cross-section obtained by vertically cutting the relevant portion is viewed from the side. “Viewed from above” refers to a view looking downward towards a base component, such as a substrate.

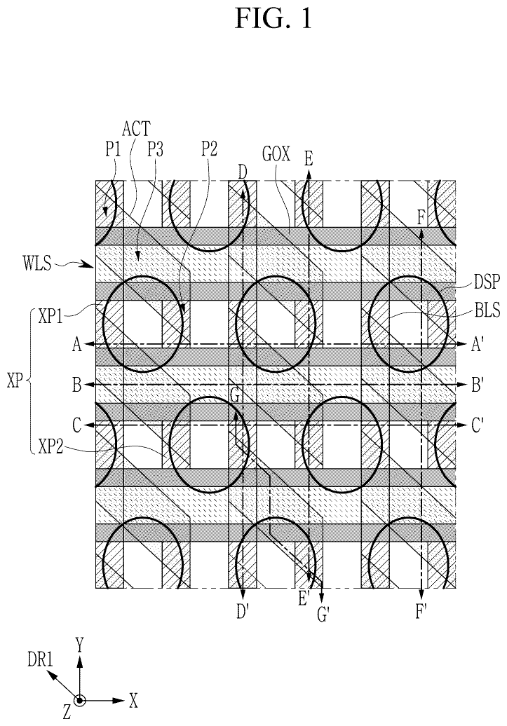

Hereinafter, a semiconductor device according to an embodiment will be described with reference to FIGS. 1 to 7.

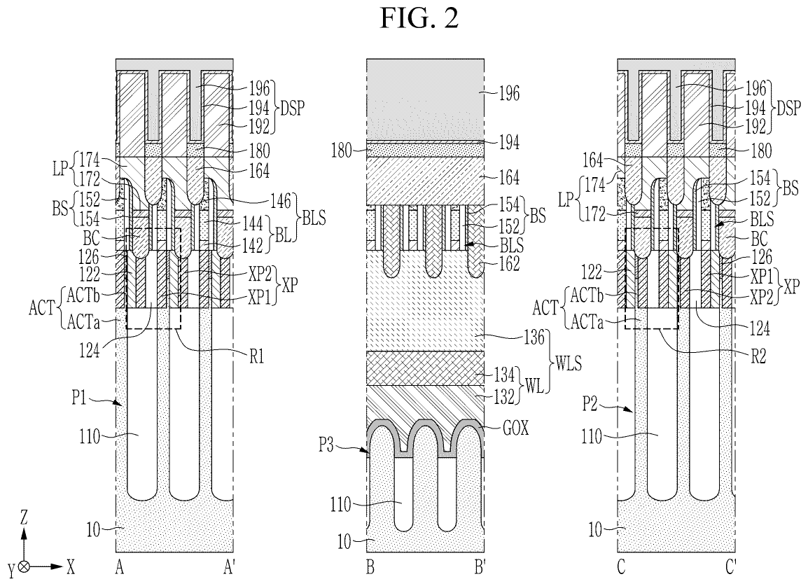

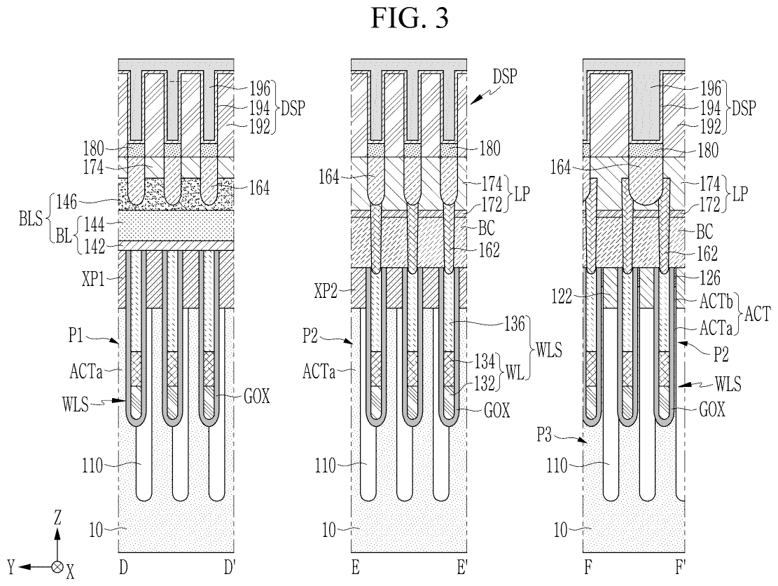

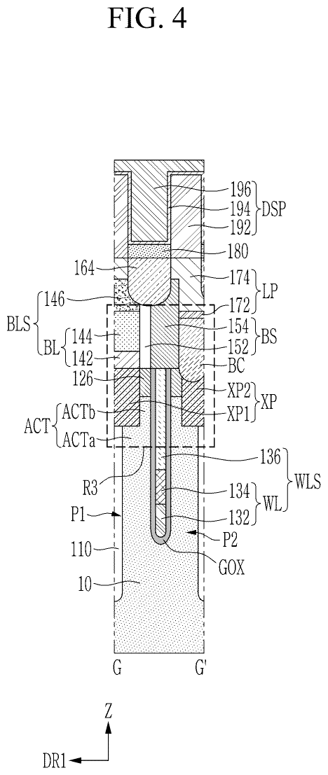

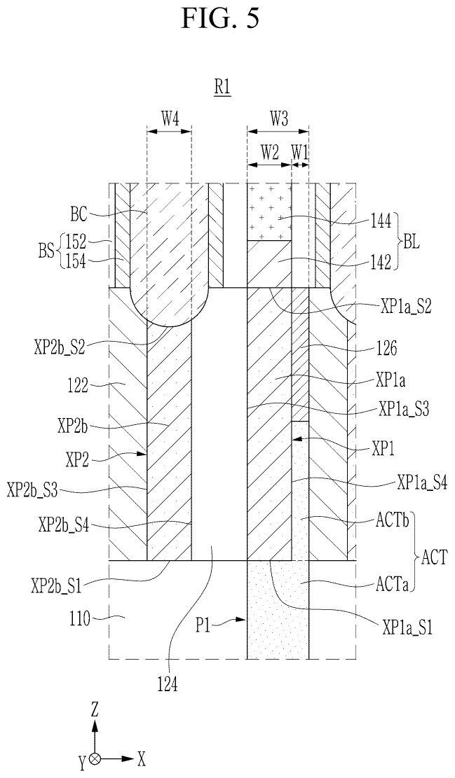

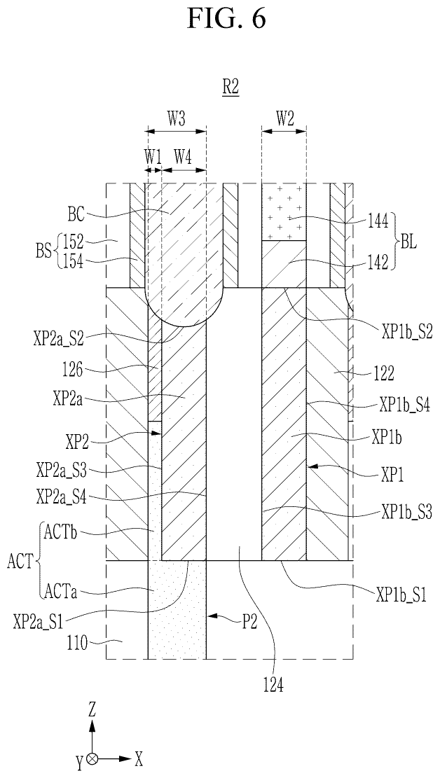

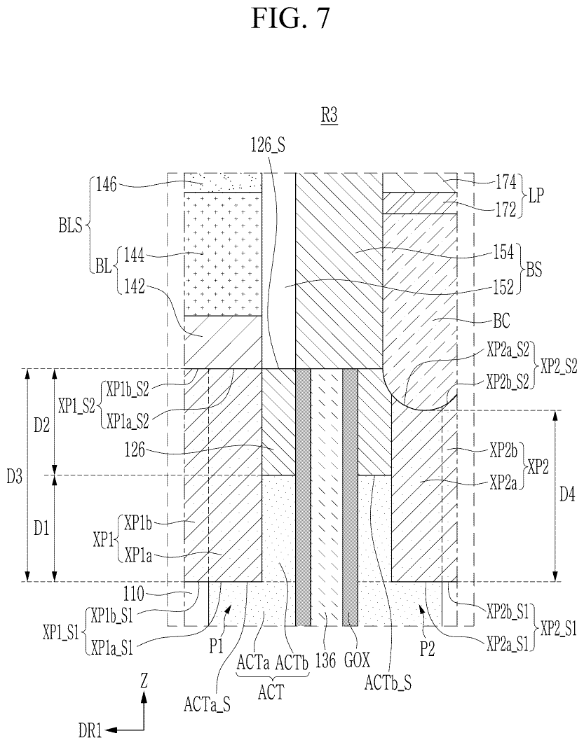

FIG. 1 is a plan view of a portion of a semiconductor device according to an embodiment. FIG. 2 is a cross-sectional view illustrating sections taken along the A-A′, B-B', and C-C′ lines of FIG. 1. FIG. 3 is a cross-sectional view illustrating sections taken along the D-D′, E-E′, and F-F′ lines of FIG. 1. FIG. 4 is a cross-sectional view illustrating a section taken along the G-G′ line of FIG. 1. FIG. 5 is a partially enlarged view enlarging the R1 region of FIG. 2. FIG. 6 is a partially enlarged view of the R2 region of FIG. 2. FIG. 7 is a partially enlarged view, in which the R3 region of FIG. 4 is enlarged.

In FIG. 1, for the purpose of explaining the arrangement relationship between the components included in the semiconductor device according to an embodiment, a depiction of components that may be unnecessary for the understanding of the embodiment has been omitted.

Referring to FIGS. 1 to 7, a semiconductor device according to an embodiment may include a substrate 10 including an active region ACT, a word line structure WLS extending in a first direction parallel to an upper surface of the substrate 10 and crossing the active region ACT between a first and second end portions of the active region ACT, a bit line structure BLS extending in a second direction parallel to the upper surface of the substrate, crossing the first end portion of the active region ACT and extending across the word line structure WLS and connected to first end portion of the active region ACT, a storage contact BC connected to the second end portion of the active region ACT which is opposite the first end portion, a first contact pad XP of a plurality of contact pads XP positioned between the first end portion of the active region ACT and the bit line structure BLS and a second contact pad XP of the plurality of contact pads XP positioned between the second end portion of the active region ACT and the storage contact BC, a landing pad LP positioned on the storage contact BC and connected to the second end portion of the active region ACT, and a capacitor DSP positioned on the landing pad LP and connected to the second end portion of the active region ACT.

In one embodiment, the substrate 10 may contain, for example, a semiconductor material such as silicon, germanium, or silicon-germanium, or a Group III-V compound such as GaP, GaAs, or GaSb. In another example, the substrate 10 may be a silicon-on-insulator (Silicon On Insulator, SOI) substrate or a germanium-on-insulator (Germanium On Insulator, GOI) substrate. However, the type of substrate 10 is not limited thereto and may be variously modified.

Although the following description will be described in reference to a single active region ACT, a semiconductor device according to an embodiment may include a plurality of active regions ACT to which the description may apply. One memory cell may be formed in each of the plurality of active regions ACT. For example, a single transistor and a single capacitor formed in one active region ACT may constitute one memory cell.

In one embodiment, a plurality of active regions ACT may be formed on a portion of the substrate 10. For example, the plurality of active regions ACT may include the same material as the substrate 10. In an embodiment, the plurality of active regions ACT may be single crystal silicon, however, it is not limited thereto.

In an embodiment, the plurality of active regions ACT may be arranged in a matrix shape with active regions ACT repeating in a first direction X and a second direction Y in a plan view.

Each of the plurality of active regions ACT may have a shape extending lengthwise in a fourth direction DR1, which may be parallel to the lower surface of the substrate, that is oblique to the first direction X and the second direction Y in a plan view. For example, the active region ACT may have a bar shape extending lengthwise in the fourth direction DR1 in a plan view.

In addition, the plurality of active regions ACT may have a cross-section shape extending lengthwise in a third direction Z perpendicular to the lower surface of the substrate 10 in cross-section.

In the following description, the first direction X and the second direction Y refer to directions parallel to the lower surface of the substrate 10, and the first direction X and the second direction Y may be perpendicular to each other in a plan view.

The third direction Z refers to a direction perpendicular to the lower surface of the substrate 10, and may intersect the first direction X and the second direction Y. The third direction Z may be referred to as a vertical direction.

The fourth direction DR1 may be parallel to the lower surface of the substrate 10, and may be a diagonal direction that intersects with the first direction X and the second direction Y in a plan view. For example, the fourth direction DR1 may be inclined at an acute angle with respect to the second direction Y (e.g., may be an oblique direction).

In an embodiment, the fourth direction DR1 may be inclined at an angle of about 35 degrees to about 50 degrees in a counterclockwise direction with respect to the second direction Y, but is not limited thereto.

In an embodiment, each of the plurality of active regions ACT may include a central portion P3 overlapping with the word line structure WLS extending in the first direction X, and a first end portion P1 and a second end portion P2 positioned on opposing sides of the central portion P3. For example, the first end portion P1 and the second end portion P2 of the active region ACT may be positioned on a first side and a second side opposite the first side in the fourth direction DR1 with respect to the central portion P3.

The first end portion P1, the second end portion P2, and the central portion P3 of the active region ACT may each include an impurity region doped with an impurity (for example, an n-type or p-type impurity). For example, the impurity regions included in each of the first end portion P1 and the second end portion P2 of the active region ACT may correspond to source/drain regions of a transistor constituting a memory cell, and the central portion P3 of the active region ACT may correspond to a channel region of the transistor constituting the memory cell. As another example, an n-type impurity may be doped in each of the first end portion P1 and the second end portion P2 of the active region ACT, and a p-type impurity may be doped in the central portion P3, however, this is not limited thereto.

In an embodiment, a central portion P3 of an active region ACT may refer to a center portion in a longitudinal direction of the active region ACT. The first end portion P1 and the second end portion P2 of the active region ACT may have a point-symmetrical shape in a plan view with respect to the central portion P3. For example, the first end portion P1 and the second end portion P2 of the active region ACT may be positioned on opposite sides of the word line structure WLS overlapping the central portion P3 in the third direction Z. In another embodiment, a first contact pad XP1 positioned at the first end portion P1 of the active region ACT and a second contact pad XP2 positioned at the second end portion P2 may be separated and insulated by the word line structure WLS.

In an embodiment, the active region ACT may include a first side surface extending in the second direction Y and a second side surface extending in the fourth direction DR1, and the first side surface and the second side surface may meet each other at the end of the first end portion P1 of the active region ACT and the end of the second end portion P2, respectively. For example, the first side surface and the second side surface of the active region ACT may have a linear shape in a plan view.

In another example, the first side surface and the second side surface of each of the first end portion P1 and the second end portion P2 of the active region ACT may have a linear shape in a plan view. However, the planar shape of the active region ACT is not limited thereto, and in the process step for forming the active region ACT, it may be variously changed.

In an embodiment, the central portion P3 of a plurality of active regions ACT may be arranged side by side in the first direction X and the second direction Y in a plan view. The first end portion P1 and the second end portion P2 of the plurality of active regions ACT may be arranged side by side in the second direction Y in a plan view. The first end portion P1 and the second end portion P2 of the plurality of active regions ACT may be alternately and adjacently arranged with each other in the first direction X.

The plurality of active regions ACT may be arranged side by side in the first direction X to form a row according to the first direction X, and the plurality of active regions ACT may be arranged side by side in the second direction Y to form a column according to the second direction Y.

In an embodiment, between active regions ACT neighboring each other in the first direction X and that are both in a first row (e.g., a row extending in the first direction), at least a portion of an active region ACT positioned in a second row adjacent to the first row in a second direction Y may be positioned between the active regions ACT. For example, the second end portions P2 of the active regions ACT positioned in the second row adjacent to the first row in the second direction Y may be positioned between the first end portions P1 of active regions ACT adjacent to each other in the first direction X in the first row,.

In addition, the first end portion P1 of an active region ACT positioned in a third row adjacent in the second direction Y may be positioned between the second end portions P2 of the active regions ACT adjacent to each other in the first direction X in the first row. However, the arrangement of the plurality of active regions ACT in a plan view is not limited thereto, and may be variously modified.

As such, since the plurality of active regions ACT are arranged side by side in the first direction X and the second direction Y, the arrangement of components included in the semiconductor device according to an embodiment may be simplified, and the integration of the components included in the semiconductor device may be improved.

In an embodiment, the active region ACT may include a first portion ACTa and a second portion ACTb, which are positioned at different levels and have different widths than each other.

For example, each of the first end portion P1 and the second end portion P2 of the active region ACT may include the first portion ACTa and the second portion ACTb positioned at different levels. For example, each of the first portion ACTa and the second portion ACTb of the active region ACT may be positioned at the first end portion P1 and the second end portion P2.

The first portion ACTa of the active region ACT may be positioned at a lower level than the plurality of contact pads XP to be described below.

The second portion ACTb of the active region ACT may be positioned on the first portion ACTa. The second portion ACTb of the active region ACT may extend in a vertical direction from the first portion ACTa. For example, the second portion ACTb of the active region ACT is positioned at a higher level than the first portion ACTa, and the second portion ACTb of the active region ACT may be positioned so as to overlap the first portion ACTa in the vertical direction.

The width of the first portion ACTa of the active region ACT may be different from the width of the second portion ACTb. For example, the width of the first portion ACTa of the active region ACT may be greater than the width of the second portion ACTb. In this example, the width may refer to the maximum width in the first direction X.

In an embodiment, the first portion ACTa and the second portion ACTb of the active region ACT may be formed together in the same process step using the same material (for example, single crystal silicon).

Accordingly, the first portion ACTa and the second portion ACTb of the active region ACT may be integrally formed, and as the same material is used to form the first portion ACTa and the second portion ACTb, a boundary therebetween may not be visually recognized. However, this is not limited thereto, and the first portion ACTa and the second portion ACTb may have a boundary visible therebetween, as they are separately formed in different process step using different materials.

A more detailed description of the first portion ACTa and the second portion ACTb of the active region ACT will be provided below with reference to FIGS. 5 to 7.

The semiconductor device according to an embodiment may further include a plurality of element isolation layers 110 positioned between the plurality of active regions ACT in the substrate 10, respectively.

The element isolation layer 110 may be positioned in a trench recessing a portion of the substrate 10 in the third direction Z. The plurality of active regions ACT may be defined by the element isolation layers 110 positioned in the substrate 10. For example, the element isolation layers 110 may be positioned between the plurality of active regions ACT adjacent to each other in the first direction X and the second direction Y, respectively.

The element isolation layer 110 may contain an insulating material such as silicon oxide, silicon nitride, or a combination thereof.

Although the element isolation layer 110 is illustrated as having a single layer structure, it is not limited thereto, and in an embodiment the element isolation layer 110 may have a multilayer structure including the same material and/or different materials.

The semiconductor device according to an embodiment may include a plurality of word line structures WLS.

The plurality of word line structures WLS may extend in the first direction X so as to overlap with the central portion P3 of the plurality of active regions ACT, and the word line structures WLS may be arranged spaced apart in the second direction Y with the first end portion P1 and the second end portion P2 of corresponding active regions ACT interposed between neighboring word line structures WLS.

The word line structures WLS may recess of a portion of the active region ACT and a portion of the element isolation layer 110, and may extend in the third direction Z into the active region ACT and the element isolation layer 110. As used herein, when a first object is said to recess a second object, it will be understood that a portion of the first object is positioned in a recess of the second object.

The word line structure WLS may recess the central portion P3 of the active region ACT and extend into the active region ACT in the third direction Z, such that the lengths of the first end portion P1 and the second end portion P2 of the active region ACT in the third direction Z may each be greater than the length of the central portion P3 in the third direction Z.

The word line structure WLS may serve as a gate of a fin field effect transistor (Fin-FET). For example, a word line WL included in the word line structure WLS may correspond to the gate electrode of the transistor constituting the memory cell.

In an embodiment, the word line structure WLS may include a sequentially stacked gate insulating pattern GOX, the word line WL, and a word line capping layer 136.

The gate insulating pattern GOX, the word line WL, and the word line capping layer 136 may sequentially be stacked in a recess of the active region ACT and the element isolation layer 110 in the word line trench where the word line structure WLS is positioned.

The gate insulating pattern GOX may be conformally extended along the inner side surface of the word line trench. A portion of the gate insulating pattern GOX may be extended along the active region ACT, and the remaining portion may be extended along the element isolation layer 110. The gate insulating pattern GOX may be extended along opposing side surfaces of the word line WL and side surfaces of the word line capping layer 136.

The gate insulating pattern GOX may contain silicon oxide, silicon oxynitride, a high-k material having a dielectric constant higher than that of silicon oxide, or a combination thereof. For example, the high-k material may contain any one of HfO₂, HfSiO, HfSiON, HfTaO, HfTiO, HfZrO, ZrO₂, Al₂O₃, or a combination thereof, but is not limited thereto.

The word line WL may be positioned on the gate insulating pattern GOX.

The word line WL includes a first gate pattern 132 and a second gate pattern 134, and may have a multilayer structure. For example, the first gate pattern 132 may contain a metal material such as tungsten, and the second gate pattern 134 may contain, for example, polysilicon. However, the number of layers configuring the word line WL and/or the material included in the layer configuring the word line WL is not limited thereto and may be variously modified. For example, the word line WL may have a single layer structure.

The word line capping layer 136 may be positioned on the word line WL. The word line capping layer 136 may cover the upper surface of the word line WL.

The word line capping layer 136 may contain an insulating material such as silicon oxide, silicon nitride, or a combination thereof. However, the material included in the word line capping layer 136 is not limited thereto, and may be variously changed.

The semiconductor device according to an embodiment may include a plurality of bit line structures BLS.

The plurality of bit line structures BLS may extend lengthwise to intersect with a plurality of word line structures WLS. For example, the plurality of bit line structures BLS may extend lengthwise in the second direction Y intersecting the first direction X, and may be arranged spaced apart from one another in the first direction X.

The plurality of bit line structures BLS may be positioned on a plurality of word line structures WLS, and may extend lengthwise in the second direction Y.

The plurality of bit line structures BLS may extend lengthwise in the second direction Y so as to overlap with the first end portion P1 of each of a plurality of active regions ACT. For example, a plurality of active regions ACT arranged side by side in the second direction Y and constituting one column may each have the first end portion P1 connected to one bit line structure BLS.

A bit line BL included in the plurality of bit line structures BLS may be electrically connected to the first end portion P1 of an active region ACT through a contact pad XP, which will be described later.

In an embodiment, the bit line structure BLS may include the bit line BL and a bit line capping layer 146 which are sequentially stacked.

For example, the bit line BL may have a multilayer structure including a first conductive layer 142 and a second conductive layer 144.

The first conductive layer 142 may contain a metal silicide, for example, cobalt silicide, nickel silicide, or titanium silicide.

The second conductive layer 144 may contain a metal material such as tungsten, niobium, copper, or aluminum. However, the number of conductive layers including the bit line BL and/or the material of the conductive layers is not limited thereto, and may be variously changed. For example, the bit line BL may have a single layer structure or may have a multilayer structure including three or more conductive layers.

The bit line capping layer 146 may be positioned on the bit line BL. The bit line capping layer 146 may cover the upper surface of the bit line BL.

The bit line capping layer 146 may contain an insulating material such as silicon oxide, silicon nitride, or a combination thereof. However, a material included in the bit line capping layer 146 is not limited thereto, and may be variously changed.

The semiconductor device according to an embodiment may include a plurality of storage contacts BC.

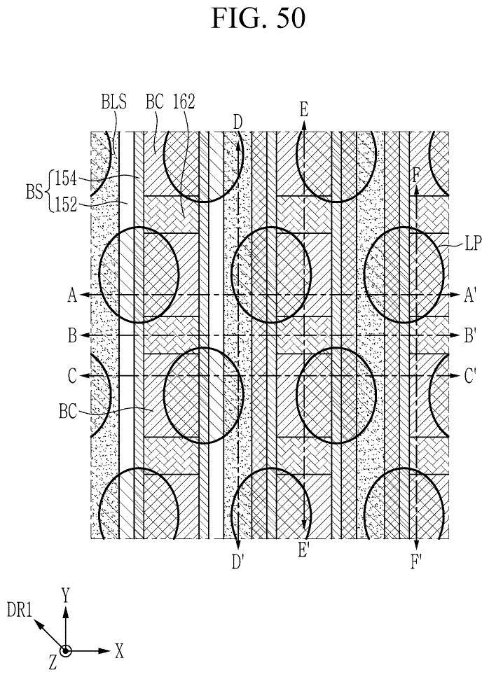

In an embodiment, as illustrated in FIG. 50, the plurality of storage contacts BC may be arranged in a matrix pattern in the first direction X and the second direction Y in a plan view.

In FIG. 50, the storage contact BC is illustrated as having a rectangular shape in a plan view, however, it is not limited thereto, and the storage contact BC may have various shapes in a plan view, such as circular, elliptical, rhombic, and hexagonal shapes.

In an embodiment, the plurality of storage contacts BC may be positioned on the second end portion P2 of the plurality of active regions ACT. The plurality of storage contacts BC may be positioned so as to each overlap the second end portion P2 of a corresponding active region ACT, and may be electrically connected to the second end portion P2.

The storage contact BC may contain a conductive material. The storage contact BC may contain polysilicon doped with impurities. However, this is not limited thereto, and the material included in the storage contact BC may be variously changed.

In an embodiment, the plurality of contact pads XP may include a plurality of first contact pads XP1 with each first contact pad X1 positioned on the first end portion P1 of a corresponding one of the a plurality of active regions ACT, and a plurality of second contact pads XP2 with each second contact pad positioned on a second end portion P2 of a corresponding one of the plurality of active regions ACT.

For example, the plurality of first contact pads XP1 may be spaced apart and arranged in the second direction Y with a corresponding word line structure WLS interposed therebetween. The plurality of second contact pads XP2 may be arranged spaced apart from each other in the second direction Y with a corresponding word line structure WLS interposed therebetween. The plurality of first contact pads XP1 and the plurality of second contact pads XP2 may be alternately arranged in parallel in the first direction X.

In an embodiment, the plurality of contact pads XP may have a rectangular shape in a plan view. For example, the contact pad XP may have a rectangular shape having a short axis in the first direction X and a long axis in the second direction Y. However, the planar shape of the contact pad XP is not limited thereto and may be variously modified.

In an embodiment, the first contact pad XP1 may be positioned to overlap a portion of the active region ACT in the third direction Z. The first contact pad XP1 may be positioned to overlap the first end portion P1 of the active region ACT in the third direction Z. For example, a portion of the first contact pad XP1 may overlap the first end portion P1 in the third direction Z, and the remaining portion may overlap the element isolation layer 110.

The first contact pad XP1 may be electrically connected to the first end portion P1 of the active region ACT. The first contact pad XP1 is positioned between the first end portion P1 of the active region ACT and the bit line structure BLS, and may electrically connect the bit line structure BLS and the first end portion P1 of the active region ACT.

The second contact pad XP2 may be positioned to overlap a portion of the active region ACT in the third direction Z. The second contact pad XP2 may be positioned to overlap the second end portion P2 of the active region ACT in the third direction Z. For example, a portion of the second contact pad XP2 may overlap the second end portion P2 in the third direction Z, and the remaining portion may overlap the element isolation layer 110.

The second contact pad XP2 may be electrically connected to the second end portion P2 of the active region ACT. The second contact pad XP2 is positioned between the second end portion P2 of the active region ACT and the storage contact BC, and may electrically connect the storage contact BC and the second end portion P2 of the active region ACT.

The contact pad XP may contain a conductive material such as polysilicon doped with an impurity (for example, an n-type or p-type impurity). For example, the contact pad XP may include an impurity to the same as the impurity included in each of the first end portion P1 and the second end portion P2 of the active region ACT, and may include an impurity different from the impurity included in the central portion P3 of the active region ACT.

In an example, the impurity included in the first end portion P1 and the second end portion P2 of the active region ACT, and the contact pad XP may be an n-type impurity such as phosphorus (P), arsenic (As), bismuth (Bi), antimony (Sb), or a combination thereof.

In addition, the impurity included in the central portion P3 of the active region ACT may be a p-type impurity such as aluminum (Al), boron (B), indium (In), gallium (Ga), or a combination thereof. However, the type of impurity doped in the material including the contact pad XP and/or the first end portion P1, the second end portion P2, the central portion P3 of the active region ACT, and each of the contact pad XP may be variously changed.

The arrangement relationship between the contact pad XP and the active region ACT, the width of the contact pad XP, and detailed information on the length of the contact pad XP will be described later with reference to FIGS. 5 to 7.

The semiconductor device according to an embodiment may further include an active capping pattern 126 positioned on the active region ACT, a first pad isolation pattern 122 positioned between the active region ACT and the contact pad XP, and a second pad isolation pattern 124 positioned between the contact pads XP adjacent to each other.

For example, the active capping pattern 126 may be positioned to overlap a portion of the active region ACT. The active capping pattern 126 may be positioned on the second portion ACTb of the active region ACT. The active capping pattern 126 may extend in the third direction Z on the second portion ACTb of the active region ACT. The active capping pattern 126 may be positioned spaced apart from the first portion ACTa in a third direction Z with the second portion ACTb of the active region ACT interposed therebetween.

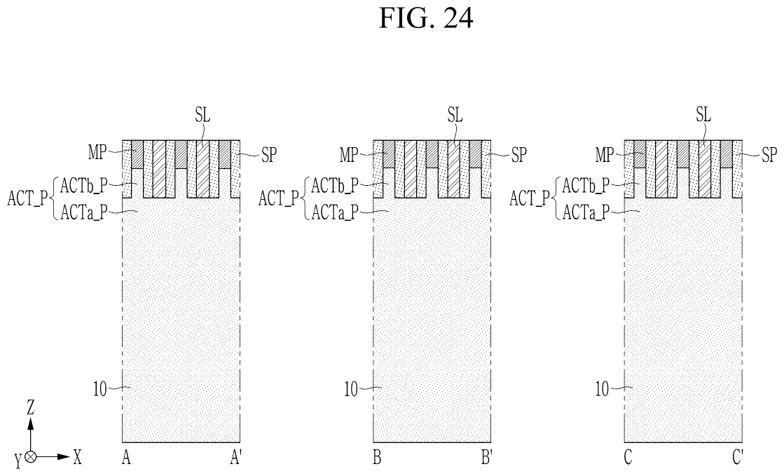

The active capping pattern 126 may be a remaining portion utilized as an etching mask pattern (see ‘MP’ of FIG. 24) in process steps of patterning the substrate 10 to form a first portion ACTa and a second portion ACTb of the active region ACT having different widths, and a detailed description thereof will be provided later.

The first pad isolation pattern 122 may be positioned on the element isolation layer 110.

The first pad isolation pattern 122 may be positioned so as to overlap the element isolation layer 110 in the third direction Z, and may be positioned so as to not overlap the active region ACT in the third direction Z.

The first pad isolation pattern 122 may be positioned between the first contact pad XP1 and the second contact pad XP2 adjacent to each other in the first direction X. The first pad isolation pattern 122 may be positioned between word line structures WLS adjacent to each other in the second direction Y.

As shown in FIG. 2, the first pad isolation pattern 122 is positioned between the second portion ACTb of the active region ACT and the contact pad XP, which are adjacent to each other in the first direction X, and between the active capping pattern 126 and the contact pad XP, and may extend in the third direction Z.

A side surface of the first pad isolation pattern 122 positioned at one side in the first direction X contacts the second portion ACTb of the active region ACT and the active capping pattern 126, and a side surface positioned at the other side in the first direction X may contact the contact pad XP. However, this is not limited thereto, and at least one other configuration may be further positioned in at least one among between the first pad isolation pattern 122 and the second portion ACTb of the active region ACT, between the first pad isolation pattern 122 and the contact pad XP, and between the first pad isolation pattern 122 and the active capping pattern 126 in the first direction X.

Also, as shown in FIG. 3, the first pad isolation pattern 122 may be positioned between the second portion ACTb of the active region ACT, which are adjacent to each other in the second direction Y, and the word line structure WLS, and between the active capping pattern 126 and the word line structure WLS, and may extend in the third direction Z.

A side surface of the first pad isolation pattern 122 positioned at a first side in the second direction Y is in contact with the second portion ACTb of the active region ACT and the active capping pattern 126, and a side surface positioned at a second first side in the second direction Y may be in contact with the gate insulating pattern GOX. However, this is not limited thereto, and in at least one of between the first pad isolation pattern 122 and the second portion ACTb of the active region ACT, between the first pad isolation pattern 122 and the active capping pattern 126, and between the first pad isolation pattern 122 and the gate insulating pattern GOX, which are adjacent to each other in the second direction Y, another configuration may be further positioned.

The second pad isolation pattern 124 may be positioned on the element isolation layer 110.

The second pad isolation pattern 124 may be positioned between the first contact pad XP1 and the second contact pad XP2 adjacent to each other in the first direction X.

As shown in FIG. 2, the second pad isolation pattern 124 is positioned between the first contact pad XP1 and the second contact pad XP2 that are adjacent to each other in the first direction X, and may extend in the third direction Z.

A side surface of the second pad isolation pattern 124 positioned at a first side in the first direction X is in contact with the first contact pad XP1, and a side surface of the second pad isolation pattern 124 positioned at a second side may be in contact with the second contact pad XP2. However, this is not limited thereto, and another configuration may be further positioned between the second pad isolation pattern 124 and the first contact pad XP1 and/or the second contact pad XP2.

The active capping pattern 126, the first pad isolation pattern 122, and the second pad isolation pattern 124 each may contain an insulating material such as silicon oxide, silicon nitride, silicon oxynitride, and/or a low dielectric material. For example, the active capping pattern 126 may contain silicon nitride, and the first pad isolation pattern 122 and the second pad isolation pattern 124 may include silicon oxide, but are not limited thereto.

The semiconductor device according to an embodiment may further include a spacer structure BS positioned on a side surface of the bit line structure BLS.

Specifically, the spacer structure BS may be positioned on both side surfaces of the bit line structure BLS. The spacer structure BS may be extended along the side surface of the bit line structure BLS in a substantially third direction Z.

The spacer structure BS may be positioned between adjacent bit line structures BLS and the storage contact BC, and between adjacent bit line structures BLS and the landing pad LP to be described later.

The spacer structure BS positioned on a first side surface of the bit line structure BLS is positioned so as to overlap the first pad isolation pattern 122 and the active capping pattern 126 in the third direction Z, and the spacer structure BS positioned on a second side surface may be positioned so as to overlap the second pad isolation pattern 124 in the third direction Z. For example, a first spacer 152 positioned on the first side surface of the bit line structure BLS is positioned on the upper surface of each of the active capping pattern 126 and the first pad isolation pattern 122, and a second spacer 154 may be positioned on the upper surface of the first pad isolation pattern 122.

In addition, the first spacer 152 and the second spacer 154 positioned on the second side surface of the bit line structure BLS may be positioned on the upper surface of the second pad isolation pattern 124.

In an embodiment, the spacer structure BS may have a multilayer structure including the same or different insulating material.

For example, the spacer structure BS may include the first spacer 152 and the second spacer 154 sequentially stacked on the side surface of the bit line structure BLS.

The first spacer 152 may extend along the side surface of the bit line structure BLS. The second spacer 154 may be positioned between the first spacer 152 and the storage contact BC, and between the first spacer 152 and the landing pad LP to be described below.

The upper surfaces of the first spacer 152 and the second spacer 154 may be positioned at substantially the same level as the upper surface of the bit line structure BLS.

The first spacer 152 and the second spacer 154 each may contain an insulating material such as silicon oxide, silicon nitride, silicon oxynitride, silicon oxycarbide, silicon carbonitride, silicon oxycarbonitride, or a combination thereof. For example, the first spacer 152 may contain silicon oxide, and the second spacer 154 may contain silicon nitride. However, the number and material of spacers constituting the spacer structure BS are not limited thereto and may be variously changed. For example, the spacer structure BS may have a single layer structure or may have a multilayer structure including three or more spacers.

The semiconductor device according to an embodiment may further include a plurality of fence patterns 162 positioned between storage contacts BC adjacent to each other.

The plurality of fence patterns 162 may be positioned between adjacent storage contacts BC, and may insulate and separate them.

The fence pattern 162 may extend in the third direction Z between spacer structures BS positioned on side surfaces of adjacent bit line structures BLS and between adjacent storage contacts BC, and may be in contact with the word line capping layer 136.

The fence pattern 162 may recess a portion of the word line capping layer 136. Accordingly, the lower surface and the adjacent side surface of the fence pattern 162 may be surrounded by the word line capping layer 162. However, the embodiment is not limited thereto, and in some embodiments, the fence pattern 162 may recess the word line capping layer 162 together with the adjacent gate insulating pattern GOX.

The fence pattern 162 may contain an insulating material such as silicon oxide, silicon nitride, silicon oxynitride, silicon oxycarbide, silicon carbonitride, silicon oxycarbonitride, or combinations thereof. For example, the fence pattern 162 may contain silicon nitride, but is not limited thereto.

The semiconductor device according to an embodiment may include a plurality of landing pads LP.

The plurality of landing pads LP may be positioned to correspond to each of a plurality of storage contacts BC positioned on the second end portion P2 of the plurality of active regions ACT. For example, as illustrated in FIG. 50, the plurality of landing pads LP may be arranged in a matrix form in a plan view in the first direction X and the second direction Y. The plurality of landing pads LP may be arranged in a honeycomb pattern, for example, in which each vertex of the connected hexagons in a plan view and the center of the hexagon are respectively disposed.

For example, the plurality of landing pads LP may be arranged in a line in the first direction X, and may be alternately arranged on one side and the other side of the first direction X with respect to the bit line BL in the second direction Y, so as to be arranged in a zigzag pattern in a plan view. However, the arrangement pattern in a plan view of the plurality of landing pads LP is not limited thereto and may be variously modified.

In FIG. 50, although each of the plurality of landing pads LP is shown as having a circular shape in a plan view, it is not limited thereto, and each of the plurality of landing pads LP may have various shapes such as an elliptical, rectangular, square, rhombic, and hexagonal shape in a plan view.

In an embodiment, the landing pad LP may have a multilayer structure including a silicide layer 172 and a pad conductive layer 174.

The silicide layer 172 may be positioned on the upper surface of the storage contact BC. The silicide layer 172 may be positioned between spacer structures BS adjacent to each other.

The pad conductive layer 174 may overlap at least a portion of the storage contact BC in the third direction Z. For example, a portion of the pad conductive layer 174 may overlap with the storage contact BC in the third direction Z, and the remaining portion may overlap with the bit line structure BLS and the spacer structure BS in the third direction Z.

The uppermost surface of the pad conductive layer 174 is positioned at a higher level than the uppermost surfaces of the bit line structure BLS and the spacer structure BS, and may cover the upper surfaces of the bit line structure BLS and the spacer structure BS. The spacer structure BS may be positioned between the bit line structure BLS and the pad conductive layer 174.

In addition, the uppermost surface of the pad conductive layer 174 may be positioned at a higher level than the uppermost surface of the fence pattern 162. The pad conductive layer 174 may cover the side surface and upper surface of the fence pattern 162.

The landing pad LP may be electrically connected to the second end portion P2 of the active region ACT through the storage contact BC.

The silicide layer 172 may contain a metal silicide material such as cobalt silicide, nickel silicide, or manganese silicide, and the pad conductive layer 174 may contain at least one of a metal material such as tungsten, niobium, copper, or aluminum, doped polysilicon, conductive metal nitride, conductive metal silicon nitride, metal carbonitride, conductive metal oxide, and a two-dimensional material. However, the material included in each of the silicide layer 172 and the pad conductive layer 174 is not limited thereto and may be variously changed.

In some embodiments, the landing pad LP may further include a conductive barrier layer (not shown) positioned between the silicide layer 172 and the pad conductive layer 174. For example, the conductive barrier layer may be conformally positioned between the pad conductive layer 174 and the bit line structure BLS, between the pad conductive layer 174 and the spacer structure BS, and between the silicide layer 172 and the pad conductive layer 174.

The conductive barrier layer may contain a metal material such as Ti, TiN, or a metal nitride, but is not limited thereto.

The semiconductor device according to an embodiment may further include a plurality of insulating patterns 164 positioned between adjacent landing pads LP.

The insulating pattern 164 may be positioned to fill a space between the plurality of landing pads LP. The insulating pattern 164 may surround the side surface of the landing pad LP. The plurality of landing pads LP may be separated and insulated from each other by an insulating pattern 164.

The insulating pattern 164 may recess a portion of the bit line structure BLS and the spacer structure BS. For example, the insulating pattern 164 may recess a portion of the bit line capping layer 146 forming the bit line structure BLS and a portion of the spacer structure BS.

The insulating pattern 164 may contain an insulating material such as silicon nitride, silicon oxynitride, silicon oxide, or a combination thereof. However, the material included in the insulating pattern 164 is not limited thereto and may be variously changed.

In an embodiment, the insulating pattern 164 is illustrated as having a single layer structure, however, in some embodiments, the insulating pattern 164 may have a multilayer structure. For example, the insulating pattern 164 may include a first material layer and a second material layer sequentially stacked.

Here, the first material layer may contain a low dielectric constant (low-k) material having a low dielectric constant such as silicon oxide, or SiOCH, SiOC, and the second material layer may contain silicon nitride or silicon oxynitride. However, the shape and material of the landing pad LP are not limited thereto, and may be variously modified.

Although not shown in detail, unlike as illustrated in FIG. 2 and FIG. 3, in some embodiments, the landing pad LP may be configured, and an upper surface of a pad conductive layer 174 positioned on the silicide layer 172 may include a first portion and a second portion.

For example, the first portion of the pad conductive layer 174 may be positioned at substantially the same level as the upper surface of the spacer structure BS and the upper surface of the bit line capping layer 146. The second portion of the pad conductive layer 174 is positioned on the first portion, and may recess a portion of each of the bit line structure BLS, the spacer structure BS, and the first portion of the pad conductive layer 174.

In this case, the insulating pattern 164 for separating and insulating the landing pad LP may cover the bit line structure BLS, the spacer structure BS, and the first portion of the pad conductive layer 174. The second portion of the pad conductive layer 174 may be connected to the first portion of the conductive layer 164 through the insulating pattern 164. Accordingly, the insulating pattern 164 may surround the side surface of the second portion of the pad conductive layer 174, and may be positioned between the second portions of pad conductive layers 174 that are adjacent to each other.

This may be a result of a difference in the sequence of process for forming the landing pad LP and the insulating pattern 164.

The semiconductor device according to an embodiment may further include an etch stop layer positioned on the insulating pattern 164.

The etch stop layer 180 may be positioned so as to be non-overlapping with the landing pad LP in the third direction Z and to be overlapping with the insulating pattern 164 in the third direction Z. For example, the etch stop layer 180 may cover the upper surface of the insulating pattern 164.

The etch stop layer 180 may contain an insulating material such as, for example, silicon nitride. However, this is not limited thereto, and the arrangement of the etch stop layer 180 and/or the material included in the etch stop layer 180 may be variously changed.

The semiconductor device according to an embodiment may include a plurality of capacitors DSP respectively positioned on the plurality of landing pads LP.

The plurality of capacitors DSP may be arranged in a matrix pattern in the first direction X and the second direction Y, as shown in FIG. 1. For example, the plurality of capacitors DSP may be arranged in a honeycomb pattern in which each vertex of the hexagon connected in a plan view and the center of the hexagon are respectively positioned.

The plurality of capacitors DSP may have substantially the same planar shape as the above-described plurality of landing pads LP. For example, the plurality of capacitors DSP may be arranged in a line in the first direction X, and may be alternately arranged on one side and the other side of the first direction X with respect to the bit line BL in the second direction Y, so as to be arranged in a zigzag pattern in a plan view. However, the arrangement in a plan view of the plurality of capacitors DSP is not limited thereto, and may be variously changed.

In FIG. 1, although each of the plurality of capacitors DSP is illustrated as having a circular shape in a plan view, it is not limited thereto, and each of the plurality of capacitors DSP may have various shapes such as an elliptical, rectangular, square, rhombic, or hexagonal shape in a plan view.

The capacitor DSP may be positioned to be entirely overlapped or partially overlapped with the landing pad LP in the third direction Z. For example, the capacitor DSP may be positioned to overlap with a portion of the landing pad LP in the third direction Z.

The capacitor DSP may be electrically connected to the active region ACT through the landing pad LP and the storage contact BC. For example, the capacitor DSP may be electrically connected to the second end portion P2 of the active region ACT.

The capacitor DSP may include a first electrode 192, a second electrode 196, and a dielectric layer 194 positioned between the first electrode 192 and the second electrode 196.

The first electrode 192 may be connected to the landing pad LP through the etch stop layer 180. The first electrode 192 may extend in the third direction Z on the landing pad LP.

The first electrode 192 may contain a conductive material such as metal, conductive metal nitride, or a combination thereof. For example, the first electrode 192 may contain TiN, Ru, TaN, WN, Pt, Ir, or a combination thereof. However, the material contained in the first electrode 192 is not limited thereto and may be variously changed.

The dielectric layer 194 may be conformally extended along the upper surface and the side surface profile of the first electrode 192. For example, the dielectric layer 194 may cover the side surface and the upper surface of the first electrode 192. A portion of the dielectric layer 194 may be positioned on the upper surface of the etch stop layer 180. For example, a portion of the dielectric layer 194 may be positioned between the etch stop layer 180 and the second electrode 196.

The dielectric layer 194 may contain an insulating material such as tantalum oxide (Ta₂O₅), aluminum oxide (Al₂O₃), titanium oxide (TiO₂), or a combination thereof. However, this is not limited thereto, and the material included in the dielectric layer 194 may be variously changed.

The second electrode 196 may be positioned on the dielectric layer 194. The second electrode 196 may entirely cover the first electrode 192. For example, the second electrode 196 may cover the upper surface and the side surface of the first electrode 192.

The second electrode 196 may contain a metal material such as W, Ti, Ru, or SiGe. For example, the second electrode 196 may contain tungsten (W). However, the material contained in the second electrode 196 is not limited thereto, and may be variously changed. For example, the second electrode 196 may contain a conductive metal nitride, a metal silicide, or a combination thereof.

Although not shown in detail, unlike as illustrated in FIGS. 2 and 3, in some embodiments, the first electrode 192 configuring the capacitor DSP may be further extended and positioned in the third direction Z to recess a portion of the etch stop layer 180, a portion of the bit line structure BLS, a portion of the spacer structure BS, and a portion of the landing pad LP.

In this case, the pad conductive layer 174 configuring the landing pad LP may be positioned at substantially the same level as an upper surface of the spacer structure BS and an upper surface of the bit line capping layer 146, and the etch stop layer 180 may cover the bit line structure BLS, the spacer structure BS, and the pad conductive layer 174.

Accordingly, the lower electrode 192 configuring the capacitor DSP penetrates the etch stop layer 180 and recesses a portion of the bit line structure BLS, a portion of the spacer structure BS, and a portion of the landing pad LP, and is connected to the pad conductive layer 174 of the landing pad LP. The lower surface of the lower electrode 192 may include a curved surface.

This may be a result of a difference in the process methods for forming the landing pad LP and the capacitor DSP.

Hereinafter, with further reference to FIGS. 5 to 7, the plurality of contact pads XP will be described in detail.

With further reference to FIGS. 5 to 7 along with FIGS. 1 to 4, in an embodiment, the first contact pad XP1 may include a first pad portion XP1a overlapping the active region ACT in the third direction Z, and a second pad portion XP1b overlapping the element isolation layer 110 in the third direction Z.

The first contact pad XP1 may include a lower surface XP1_S1 and an upper surface XP1_S) that face each other in a third direction Z. The lower surface XP1_S1 of the first contact pad XP1 is constituted by the lower surface XP1a_S1 of the first pad portion XP1a and the lower surface XP1b_S1 of the second pad portion XP1b, and the upper surface XP1_S2 of the first contact pad XP1 may be constituted by the upper surface XP1a_S2 of the first pad portion XP1a and the upper surface XP1b_S2 of the second pad portion XP1b.

In addition, the first pad portion XP1a of the first contact pad XP1 may include a first side surface XP1a_S3 and a second side surface XP1a_S4 facing each other in the first direction X.

Specifically, as shown in FIG. 5, the first pad portion XP1a included in the first contact pad XP1 may overlap the first portion ACTa of the active region ACT in the third direction Z, and may overlap the second portion ACTb of the active region ACT in the first direction X.

The lower surface XP1a_S1 of the first pad portion XP1a included in the first contact pad XP1 may be in contact with the first portion ACTa of the active region ACT, and the upper surface XP1a_S2 of the first pad portion XP1a may be in contact with the bit line structure BLS. However, this is not limited thereto, and another configuration may be further positioned between the first pad portion XP1a included in the first contact pad XP1 and the first portion ACTa of the active region ACT and/or between the first pad portion XP1a and the bit line structure BLS.

In addition, the first side surface XP1a_S3 of the first pad portion XP1a included in the first contact pad XP1 may be in contact with the second pad isolation pattern 124.

A portion of the second side surface XP1a_S4 of the first pad portion XP1a included in the first contact pad XP1 may be in contact with the second portion ACTb of the active region ACT, and the remaining portion may be in contact with the active capping pattern 126. However, this is not limited thereto, and another configuration may be further positioned in at least one of between the first pad portion XP1a included in the first contact pad XP1 and the second pad isolation pattern 124, between the first pad portion XP1a and the second portion ACTb of the active region ACT, and between the first pad portion XP1a and the active capping pattern 126.

As shown in FIG. 6, the second pad portion XP1b of the first contact pad XP1 may be positioned on the element isolation layer 110, and may be non-overlapping with the active region ACT in the third direction Z.

A lower surface XP1b_S1 of the second pad portion XP1b included in the first contact pad XP1 may be in contact with the upper surface of the element isolation layer 110, and an upper surface XP1b_S2 of the second pad portion XP1b may contact the bit line structure BLS. However, this is not limited thereto, and another configuration may be further positioned between the second pad portion XP1b included in the first contact pad XP1 and the element isolation layer 110 and/or between the second pad portion XP1b and the bit line structure BLS.

In addition, the second pad portion XP1b of the first contact pad XP1 may include a first side surface XP1b_S3 and a second side surface XP1b_S4 which face each other in the first direction X.

Here, the first side surface XP1b_S3 of the second pad portion XP1b included in the first contact pad XP1 may be aligned with substantially the same boundary as the first side surface XP1a_S3 of the first pad portion XP1a included in the above-described first contact pad XP1, and may constitute one side surface of the first contact pad XP1, and the second side surface XP1b_S4 of the second pad portion XP1b may be aligned with substantially the same boundary as the second side surface XP1a_S4 of the above-described first pad portion XP1a, and may constitute the other side surface of the first contact pad XP1.

The first side surface XP1b_S3 of the second pad portion XP1b included in the first contact pad XP1 may be in contact with the second pad isolation pattern 124, and the second side surface XP1b_S4 may be in contact with the first pad isolation pattern 122. However, the embodiment is not limited thereto, and another configuration may be further positioned between the second pad portion XP1b included in the first contact pad XP1 and the first pad isolation pattern 122 and/or between the second pad isolation pattern 124.

In an embodiment, the second contact pad XP2 may include a first pad portion XP2a overlapping with the active region ACT in a third direction Z, and a second pad portion XP2b overlapping with the element isolation layer 110 in the third direction Z.

The second contact pad XP2 may include a lower surface XP2_S1 and an upper surface XP2_S2 facing each other in a third direction Z.

The lower surface XP2_S1 of the second contact pad XP2 may be constituted by the lower surface XP2a_S1 of the first pad portion XP2a and the lower surface XP2b_S1 of the second pad portion XP2b, and the upper surface XP2_S2 of the second contact pad XP2 may be constituted by the upper surface XP2a_S2 of the first pad portion XP2a and the upper surface XP2b_S2 of the second pad portion XP2b.

In addition, the first pad portion XP2a included in the second contact pad XP2 may include a first side surface XP2a_S3 and a second side surface XP2a_S4 facing each other in the first direction X.

Specifically, as illustrated in FIG. 6, the first pad portion XP2a included in the second contact pad XP2 may overlap the first portion ACTa of the active region ACT in the third direction Z, and may overlap the second portion ACTb of the active region ACT in the first direction X.

The lower surface XP2a_S1 of the first pad portion XP2a included in the second contact pad XP2 may be in contact with the first portion ACTa of the active region ACT, and the upper surface XP2a_S2 of the first pad portion XP2a may be in contact with the storage contact BC. However, this is not limited thereto, and another configuration may be further positioned between the first pad portion XP2a of the second contact pad XP2 and the first portion ACTa of the active region ACT and/or between the first pad portion XP2a and the storage contact BC.

Also, a portion of the first side surface XP2a_S3 of the first pad portion XP2a included in the second contact pad XP2 may contact the second portion ACTb of the active region ACT, and the remaining portion may contact the active capping pattern 126.

The second side surface XP2a_S4 of the first pad portion XP2a included in the second contact pad XP2 may be in contact with the second pad isolation pattern 124. However, this is not limited thereto, and at least one other configuration may be further positioned between the first pad portion XP2a included in the second contact pad XP2 and the second portion ACTb of the active region ACT, between the first pad portion XP2a and the active capping pattern 126, and between the first pad portion XP2a and the second pad isolation pattern 124.

As shown in FIG. 5, the second pad portion XP2b of the second contact pad XP2 may be positioned on the element isolation layer 110, and may be non-overlapping with the active region ACT in the third direction Z.

The lower surface XP2b_S1 of the second pad portion XP2b included in the second contact pad XP2 may be in contact with the upper surface of the element isolation layer 110, and the upper surface XP2b_S2 of the second pad portion XP2b may contact the storage contact BC. However, it is not limited thereto, and another configuration may be further positioned between the second pad portion XP2b included in the second contact pad XP2 and the element isolation layer 110 and/or between the second pad portion XP2b and the storage contact BC.

Also, the second pad portion XP2b included in the second contact pad XP2 may include a first side surface XP2b_S3 and a second side surface XP2b_S4 facing each other in the first direction X.

Here, the first side surface XP2b_S3 of the second pad portion XP2b included in the second contact pad XP2 may be aligned on substantially the same boundary as the first side surface XP2a_S3 of the first pad portion XP2a included in the above-described second contact pad XP2, and may constitute one side surface of the second contact pad XP2. The second side surface XP2b_S4 of the second pad portion XP2b may be aligned on substantially the same boundary as the second side surface XP2a_S4 of the above-described first pad portion XP2a, and may constitute the other side surface of the second contact pad XP2.

The first side surface XP2b_S3 of the second pad portion XP2b included in the second contact pad XP2 may be in contact with the first pad isolation pattern 122, and the second side surface XP2b_S4 may be in contact with the second pad isolation pattern 124. However, it is not limited thereto, and another configuration may be further positioned between the second pad portion XP2b included in the second contact pad XP2 and the first pad isolation pattern 122 and/or between the second pad isolation pattern 124.

In an embodiment, as the first pad portion XP2a and the second pad portion XP2b included in the second contact pad XP2, and the active capping pattern 126 may be recessed concavely by the storage contact BC, each of the upper surface XP2a_S1 of the first pad portion XP2a, the upper surface XP2b_S1 of the second pad portion XP2b, and the upper surface of the active capping pattern 126 may have a concave curved shape.

In addition, as the first pad isolation pattern 122 and the second pad isolation pattern 124, each adjacent to the first pad portion XP2a and the second pad portion XP2b included in the second contact pad XP2, may be recessed by the storage contact BC, a portion of the upper surface of each of the first pad isolation pattern 122 and the second pad isolation pattern 124 may include a concave curved shape. However, the arrangement relationship among the storage contact BC, the first pad portion XP2a and the second pad portion XP2b included in the second contact pad XP2, the active capping pattern 126, and the pad isolation patterns 122, 124 is not limited thereto, and may be variously changed.

As shown in FIGS. 5 to 7, in an embodiment, at least a portion of each of the first contact pad XP1 and the second contact pad XP2 may be positioned in a recess at each of the first end portion P1 and the second end portion P2 of the active region ACT, wherein a bottom surface of the recess may be defined by the upper surface ACTa_S of the first portion ACTa of the active region ACT, and an inner wall of the recess may be defined by the side surface of the second portion ACTb of the active region ACT and the side surface of the active capping pattern 126.

This may be a result of forming a recess, defined as the first portion ACTa and the second portion ACTb, at both end portions P1 and P2 included in the active region ACT by patterning the substrate 10, and then forming the first contact pad XP1 and the second contact pad XP2 in the recess such that they are self-aligned.

Specifically, the first pad portion XP1a included in the first contact pad XP1 and the first pad portion XP1b included in the second contact pad XP2 may be positioned, at the first end portion P1 and the second end portion P2 of the active region ACT, respectively, in a recess in which a bottom surface may be defined by the upper surface ACTa_S of the first portion ACTa of the active region ACT, and an inner wall may be defined by the side surface of the second portion ACTb of the active region ACT and the side surface of the active capping pattern 126.

Accordingly, the lower surfaces XP1a_S1 and XP2a_S1 of the first pad portion XP1a included in the first contact pad XP1 and the first pad portion XP2a included in the second contact pad XP2 may be covered by the first portion ACT_a of the active region ACT.

The lower surfaces XP1b_S1 and XP2b_S1 of the second pad portions XP1b and XP2b included in the first contact pad XP1 and the second contact pad XP2, respectively, may be covered by the element isolation layer 110.

In addition, the second side surface XP1a_S4 of the first pad portion XP1a included in the first contact pad XP1 and the first side surface XP2a_S3 of the first pad portion XP2a included in the second contact pad XP2 may be covered by the second portion ACTb of the active region ACT and the active capping pattern 126.

Specifically, the first portion ACTa of the active region ACT may be positioned at a lower level than the first contact pad XP1 and the second contact pad XP2. The upper surface ACTa_S of the first portion ACTa of the active region ACT may be positioned at substantially the same level as the upper surface of the element isolation layer 110.

The second portion ACTb of the active region ACT may extend in the third direction Z from the upper surface ACTa_S of the first portion ACTa along each side surface of the first contact pad XP1 and the second contact pad XP2.

For example, the second portion ACTb of the active region ACT may be extended in the third direction Z along the second side surface XP1a_S4 of the first pad portion XP1a included in the first contact pad XP1 and the first side surface XP2a_S3 of the first pad portion XP2a included in the second contact pad XP2.

Accordingly, at the first end portion P1 of the active region ACT, the first contact pad XP1 and the second portion ACTb of the active region ACT may be positioned on the upper surface ACTa_S of the first portion ACTa of the active region ACT.

For example, at the first end portion P1 of the active region ACT, a portion of the first portion ACTa of the active region ACT may overlap with the first pad portion XP1a included in the first contact pad XP1 in the third direction Z, and the remaining portion may overlap, in the third direction Z, with the second portion ACTb of the active region ACT extending along the second side surface XP1a_S4 of the first pad portion XP1a.

In addition, at the second end portion P2 of the active region ACT, the second contact pad XP2 and the second portion ACTb of the active region ACT may be positioned on the upper surface ACTa_S of the first portion ACTa of the active region ACT.

For example, at the second end portion P2 of the active region ACT, a portion of the first portion ACTa of the active region ACT may overlap with the first pad portion XP2a included in the second contact pad XP2 in the third direction Z, and the remaining portion may overlap with the second portion ACTb of the active region ACT, which extends along the first side surface XP2a_S3 of the first pad portion XP2a, in the third direction Z.

As such, when the lower surface and side surface of each of the first contact pad XP1, which connects the active region ACT and the bit line structure BLS, and the second contact pad XP2, which connects the active region ACT and the storage contact BC, may be positioned in contact with the active region ACT, the contact area between the contact pads XP1 and XP2 and the active region ACT may be relatively increased compared to the case where only the lower surface of each of the first contact pad XP1 and the second contact pad XP2 is positioned in contact with the active region ACT, so that electrical characteristics may be improved.

In an embodiment, the upper surface XP1_S2 of the first contact pad XP1 and the upper surface XP2_S2 of the second contact pad XP2 may be positioned at different levels. Accordingly, the lower surface of the bit line structure BLS, which contacts the upper surface XP1_S2 of the first contact pad XP1, and the lower surface of the storage contact BC, which contacts the upper surface XP2_S2 of the second contact pad XP2, may also be positioned at different levels. For example, when the upper surface XP1_S2 of the first contact pad XP1 is positioned at a higher level than the upper surface XP2_S2 of the second contact pad XP2, the lower surface of the bit line structure BLS may be positioned at a higher level than the lower surface of the storage contact BC.

Here, the lower surface level of the storage contact BC may refer to the level of the portion positioned at the lowermost among the lower surface of the storage contact BC.

As illustrated in FIG. 5 and FIG. 6, in an embodiment, the second portion ACTb of the active region ACT may have a first width W1 in the first direction X, the first contact pad XP1 may have a second width W2 in the first direction X, the first portion ACTa of the active region ACT may have a third width W3 in the first direction X, and the second contact pad XP2 may have a fourth width W4 in the first direction X.

Here, each of the first width W1, the second width W2 the third width W3, and the fourth width W4 may mean the maximum width in the first direction X. In addition, the second width W2 may refer to the maximum width in the first direction X of the first pad portion XP1a and the second pad portion XP1b included in the first contact pad XP1, and the fourth width W4 may refer to the maximum width in the first direction X of the first pad portion XP2a and the second pad portion XP2b included in the second contact pad XP2.

In an embodiment, the maximum width of the active capping pattern 126 in the first direction X may be substantially equal to the maximum width of the second portion ACTb of the active region ACT in the first direction X. For example, the active capping pattern 126 and the second portion ACTb of the active region ACT each may have the first width W1, which is a maximum width in the first direction X.

This may be a result of the active capping pattern 126, as described above, corresponding to a portion remaining after being used as an etching mask pattern (see ‘MP’ of FIG. 24) in process such as forming the first portion ACTa and the second portion ACTb of the active region ACT having different widths by patterning the substrate 10.

In an embodiment, the second width W2 and the fourth width W4 may be substantially the same. For example, the width of the first contact pad XP1 and the width of the second contact pad XP2 may be substantially the same. However, this is not limited thereto, and the second width W2 and the fourth width W4 may be different. For example, the second width W2 may be greater than the fourth width (W4).

In addition, the first width W1 may be smaller than the second width W2, the third width W3, and the fourth width W4, and each of the second width W2 and the fourth width W4 may be greater than the first width W1 and smaller than the third width W3. For example, the maximum width of each of the first contact pad XP1 and the second contact pad XP2 in the first direction X may be greater than the maximum width of the second portion ACTb of the active region ACT in the first direction X, and may be less than the maximum width of the first portion ACTa of the active region ACT in the first direction X.

In an embodiment, the sum of the first width W1 and the second width W2 may be substantially equal to the third width W3. In addition, a sum of the first width W1 and the fourth width W4 may be substantially equal to the third width W3. For example, the sum of the maximum width in the first direction X of the first contact pad XP1 and the maximum width in the first direction X of the second portion ACTb of the active region ACT may be substantially equal to the maximum width in the first direction X of the first portion ACTa of the active region ACT.

Accordingly, the first side surface XP1a_S3 of the first pad portion XP1a included in the first contact pad XP1 may be aligned with substantially the same boundary as the side surface of the first portion ACTa of the active region ACT, and the second side surface XP2a_S4 of the first pad portion XP2a included in the second contact pad XP2 may be aligned with substantially the same boundary as the side surface of the first portion ACTa of the active region ACT.

In addition, the sum of the maximum width of the second contact pad XP2 in the first direction X and the maximum width of the second portion ACTb of the active region ACT in the first direction X may be substantially equal to the maximum width of the first portion ACTa of the active region ACT in the first direction X.

This may result from forming a recess at both end portions P1 and P2 of the active region ACT by patterning the substrate 10, where the recess is defined by the first portion ACTa and the second portion ACTb of the active region ACT, and forming the first contact pad XP1 and the second contact pad XP2 in a self-aligned manner in the recess. However, the relationship among the first width W1, the second width W2, the third width W3, and the fourth width W4 is not limited thereto, and may be variously modified.

In an embodiment, a maximum width of the bit line structure BLS in the first direction X may be substantially the same as a maximum width of the first contact pad XP1 in the first direction X. For example, each of the bit line structure BLS and the first contact pad XP1 may have the second width W2, which is a maximum width in the first direction X. However, it is not limited thereto, and the maximum width of the first contact pad XP1 in the first direction X may be greater than the maximum width of the bit line structure BLS.

In an embodiment, a maximum width of the storage contact BC in a first direction X may be greater than a maximum width of the second contact pad XP2 in the first direction X. For example, the maximum width of the storage contact BC in the first direction X may be greater than the fourth width W4.

Accordingly, the second contact pad XP2 may overlap with a portion of the storage contact BC in the third direction Z. However, it is not limited thereto, and the relationship between the maximum width of the second contact pad XP2 in the first direction X and the maximum width of the storage contact BC in the first direction X may be variously changed.

As shown in FIG. 7, in an embodiment, the second portion ACTb of the active region ACT may have a first length D1 in the third direction Z, the active capping pattern 126 may have a second length D2 in the third direction Z, the first contact pad XP1 may have a third length D3 in the third direction Z, and the second contact pad XP2 may have a fourth length D4 in the third direction Z.

Here, the first length D1 may refer to the minimum distance in the third direction Z from the upper surface ACTa_S of the first portion ACTa of the active region ACT to the upper surface ACTb_S of the second portion ACTb.

The second length D2 may refer to a minimum distance in the third direction Z from the upper surface ACTb_S of the second portion ACTb of the active region ACT to the upper surface 126_S of the active capping pattern 126.

The third length D3 may refer to a minimum distance in the third direction Z from the lower surface XP1_S1 of the first contact pad XP1 to the upper surface XP1_S2. For example, each of the first pad portion XP1a and the second pad portion XP1b included in the first contact pad XP1 may have the third length D3 in the third direction Z that is substantially the same.

The fourth length D4 may refer to the minimum distance in the third direction Z from the lower surface XP2_S1 to the upper surface XP2_S2 of the second contact pad XP2.

As described above, since the second contact pad XP2 may be recessed by the storage contact BC, the first pad portion XP2a and the second pad portion XP2b included in the second contact pad XP2 may have different lengths in the third direction Z.

Accordingly, the fourth length D4 may refer to the minimum distance in the third direction Z between the lower surface XP2a_S1 and the upper surface XP2a_S2 of the first pad portion XP2a included in the second contact pad XP2.

In an embodiment, the third length D3 may be greater than the first length D1 and the second length D2. For example, the length of the first contact pad XP1 may be greater than the length of the second portion ACTb of the active region ACT and the length of the active capping pattern 126.

Specifically, the lower surface XP1_S1 of the first contact pad XP1 is positioned at a level lower than the upper surface ACTb_S of the second portion ACTb of the active region ACT, and the upper surface XP1_S2 of the first contact pad XP may be positioned at a level higher than the upper surface ACTb_S of the second portion ACTb of the active region ACT.

The upper surface ACTa_S of the first portion ACTa of the active region ACT may be positioned at substantially the same level as the upper surface of the element isolation layer 110.

Accordingly, the lower surface XP1a_S1 of the first pad portion XP1a constituting the lower surface XP_S1 of the first contact pad XP and the lower surface XP1b_S1 of the second pad portion XP1b may be positioned at substantially the same level.

In an embodiment, the fourth length D4 may be greater than the first length D1 and the second length D2. For example, the length of the second contact pad XP2 may be greater than the length of the second portion ACTb of the active region ACT and the length of the active capping pattern 126.

Specifically, the lower surface XP2_S1 of the second contact pad XP2 is positioned at a lower level than the upper surface ACTb_S2 of the second portion ACTb of the active region ACT, and the upper surface XP2_S2 of the second contact pad XP2 may be positioned at a higher level than the upper surface ACTb_S2 of the second portion ACTb of the active region ACT.

Here, as the second contact pad XP2 may be recessed by the storage contact BC, the level of the upper surface XP2_S2 of the second contact pad XP2 may mean the level of the portion of the upper surface XP2_S2 positioned at the lowest among the portions of the upper surface XP2_S2. For example, the level of the upper surface XP2_S2 of the second contact pad XP2 may refer to the level of the portion positioned at the lowermost among the upper surfaces XP2a_S2 of the first pad portion XP2a included in the second contact pad XP2.

The lower surface XP2_S1 of the second contact pad XP2 may be positioned at substantially the same level as the upper surface ACTa_S of the first portion ACTa of the active region ACT and the upper surface of the element isolation layer 110.

Accordingly, the lower surface XP2a_S1 of the first pad portion XP2a and the lower surface XP2b_S1 of the second pad portion XP2b, which constitute the lower surface XP2_S1 of the second contact pad XP2, may be positioned at substantially the same level.

In an embodiment, the third length D3 and the fourth length D4 may be different. For example, the third length D3 may be greater than the fourth length D4. For example, the length of the first contact pad XP1 may be greater than the length of the second contact pad XP2.

Specifically, the lower surface XP1_S1 of the first contact pad XP1 and the lower surface XP2_S1 of the second contact pad XP2 may be positioned at substantially the same level, and the upper surface XP1_S2 of the first contact pad XP1 may be positioned at a different level from the upper surface XP2_S2 of the second contact pad. For example, the upper surface XP1_S2 of the first contact pad XP1 may be positioned at a higher level than the upper surface XP2_S2 of the second contact pad.

As described above, the lower surface XP1_S1 of the first contact pad XP1 and the lower surface XP2_S1 of the second contact pad XP2 may be positioned at substantially the same level as the upper surface ACTa_S of the first portion ACTa of the active region ACT and the upper surface of the element isolation layer 110.

In addition, the upper surface XP1_S2 of the first contact pad XP1 may be positioned at substantially the same level as the upper surface 126_S of the active capping pattern 126.

The upper surface XP2_S2 of the second contact pad XP2 may be positioned at a level between the upper surface 126_S of the active capping pattern 126 and the upper surface ACTb_S of the second portion ACTb of the active region ACT. For example, the upper surface XP2_S2 of the second contact pad XP2 may be positioned at a level lower than the upper surface 126_S of the active capping pattern 126, and may be positioned at a level higher than the upper surface ACTb_S of the second portion ACTb of the active region ACT.

In an embodiment, a sum of the first length D1 and the second length D2 may be substantially equal to the third length D3.

Specifically, the sum of the length of the second portion ACTb of the active region ACT and the length of the active capping pattern 126 may be substantially equal to the length of the first contact pad XP1.

As described above, this may result from the active capping pattern 126 being used as an etching mask pattern (see “MP” in FIG. 24) in a patterning process of the substrate 10 to form the first portion ACTa and the second portion ACTb of the active region ACT having different widths, and remaining thereafter. In a subsequent process, the first contact pad XP1 may be formed in a self-aligned manner in a recess defined by the first portion ACTa and the second portion ACTb of the active region ACT.

As such, the length of the first contact pad XP1 in the third direction Z may vary according to the length of the active capping pattern 126 in the third direction Z. However, the relationship among the first length D1, the second length D2, and the third length D3 is not limited thereto, and may be variously modified.

In an embodiment, the sum of the first length D1 and the second length D2 may be different from the fourth length D4. For example, the sum of the first length D1 and the second length D2 may be greater than the fourth length D4.

Specifically, the sum of the length of the second portion ACTb of the active region ACT and the length of the active capping pattern 126 may be different from the length of the second contact pad XP2. For example, the sum of a length of the second portion ACTb of the active region ACT and a length of the active capping pattern 126 may be greater than a length of the second contact pad XP2. However, the relationship among the first length D1, the second length D2, and the fourth length D4 is not limited thereto, and may be variously modified.

According to an embodiment of the semiconductor device, both a lower surface and a side surface of each of the first contact pad XP1, which connects the active region ACT and the bit line structure BLS, and the second contact pad XP2, which connects the active region ACT and the storage contact BC, may be in contact with the active region ACT. As a result, the contact area between the contact pads XP1 and XP2 and the active region ACT increases compared to the case where only the lower surface of each contact pad is in contact with the active region, thereby improving electrical contact characteristics.

In addition, before the process of forming the plurality of contact pads XP, a recess may be formed at both end portions P1 and P2 of the active region ACT by patterning the substrate 10, the recess being defined by the first portion ACTa and the second portion ACTb of the active region ACT. Then, the plurality of contact pads XP may be formed in a self-aligned manner in the recess, thereby preventing the contact pads XP from being misaligned with respect to the end portions P1 and P2 of the active region ACT.

Accordingly, it is possible to prevent short-circuits between adjacent active regions ACT and/or between components respectively connected to the adjacent active regions ACT through the plurality of contact pads XP, thereby improving the reliability and productivity of the semiconductor device.

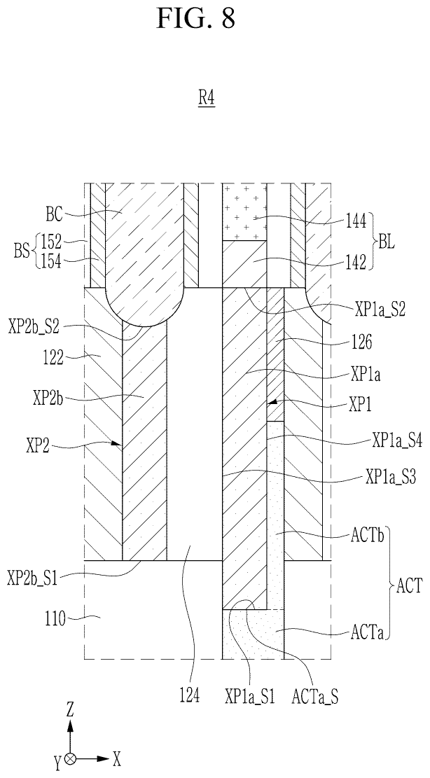

Hereinafter, with reference to FIGS. 8 to 19, a semiconductor device according to various embodiments will be described. In the following embodiments, the same reference numerals are used to refer to components that are the same or substantially the same to those described in the previous embodiments and descriptions thereof that would be redundant may be omitted or simplified, and differences will be mainly described.

FIGS. 8 to 19 are views illustrating cross-sections of a semiconductor device according to some embodiments.

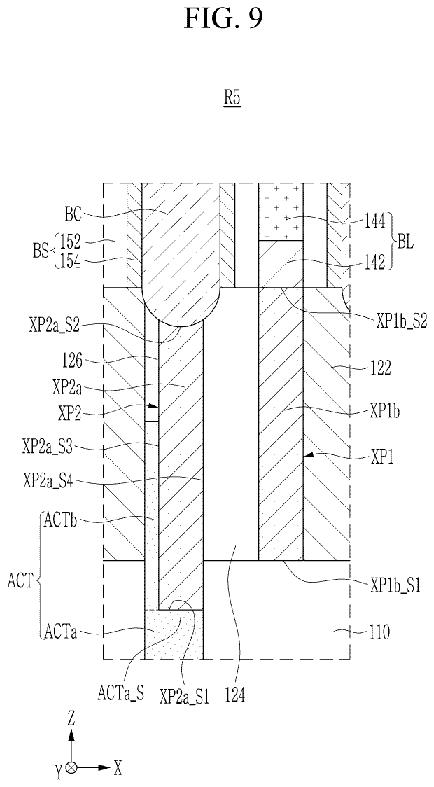

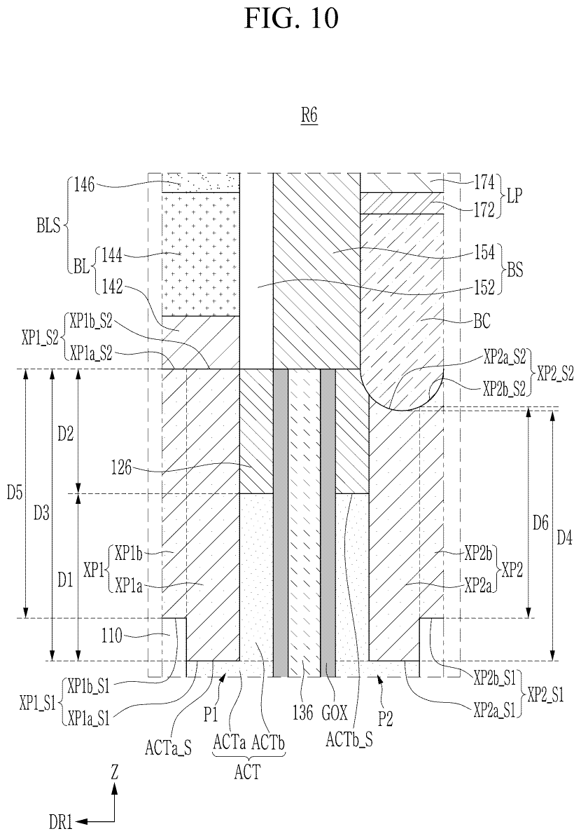

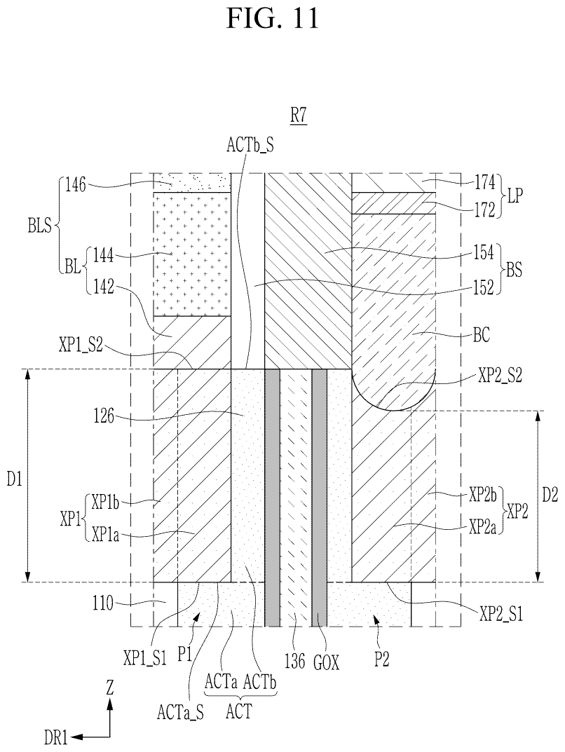

FIG. 8 is a partially enlarged view illustrating an R4 region corresponding to the R1 region of FIG. 2 according to some embodiments. FIG. 9 is a partially enlarged view illustrating an R5 region corresponding to the R2 region of FIG. 2 according to some embodiments. FIGS. 10 and 11 are partially enlarged views respectively illustrating R6 and R7 regions corresponding to the R3 region of FIG. 4 according to some embodiments.

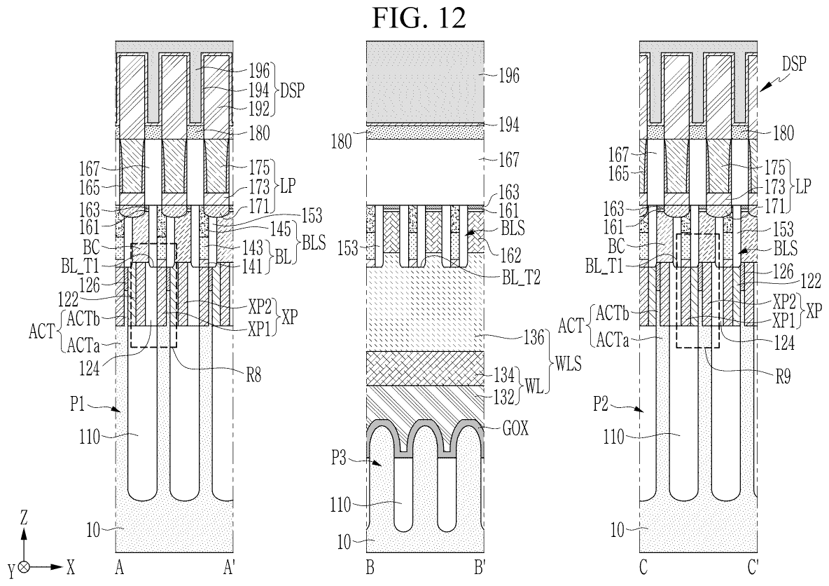

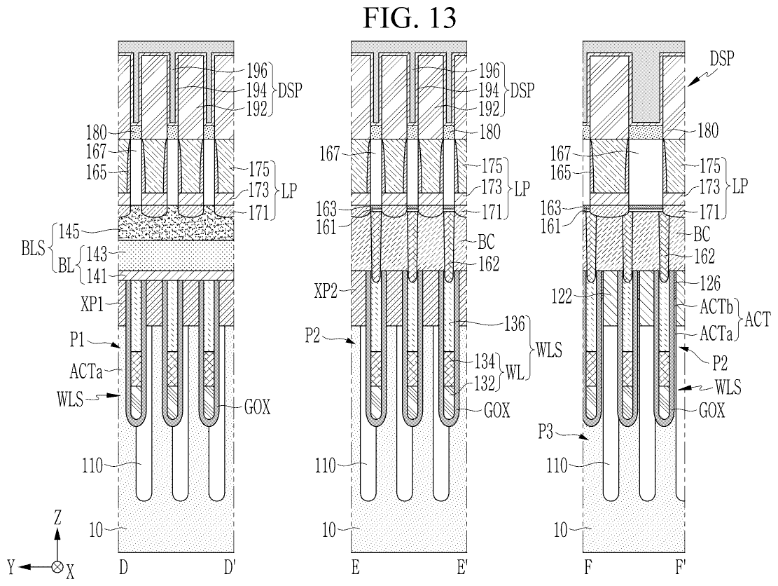

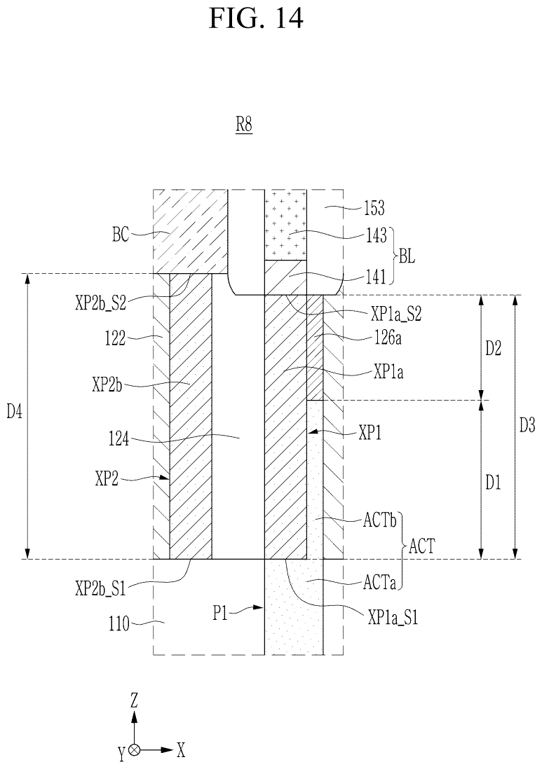

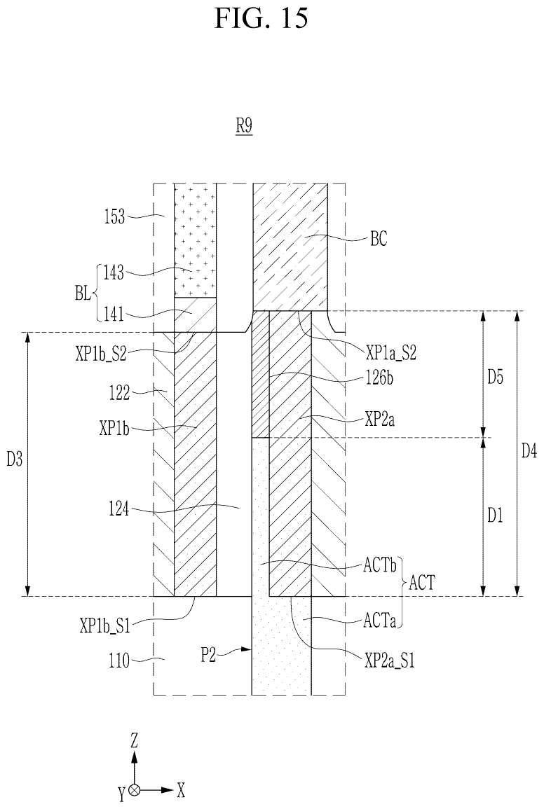

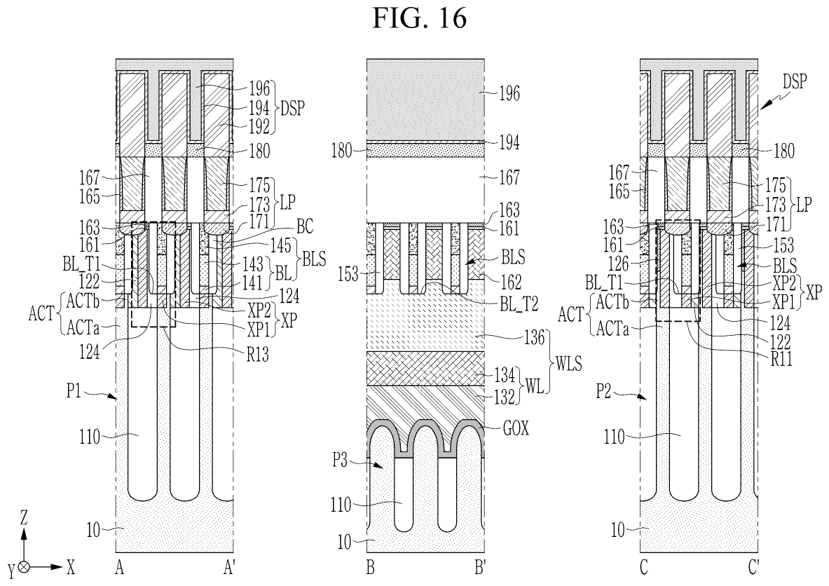

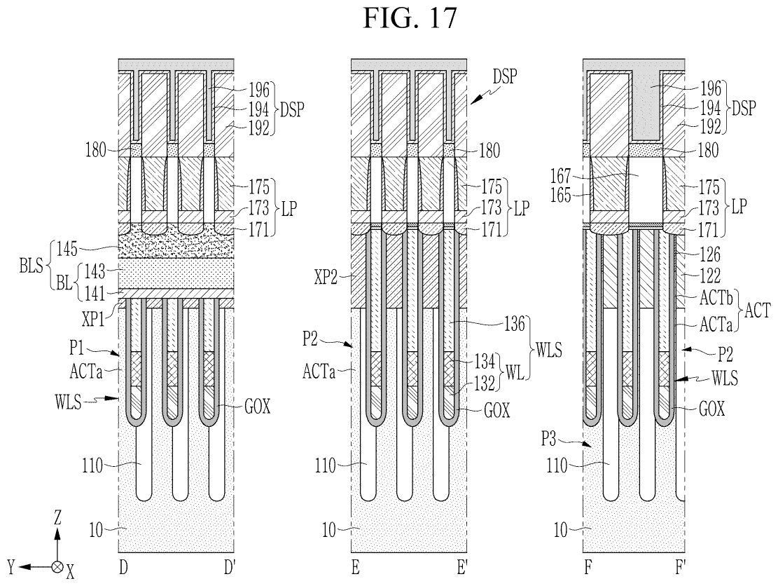

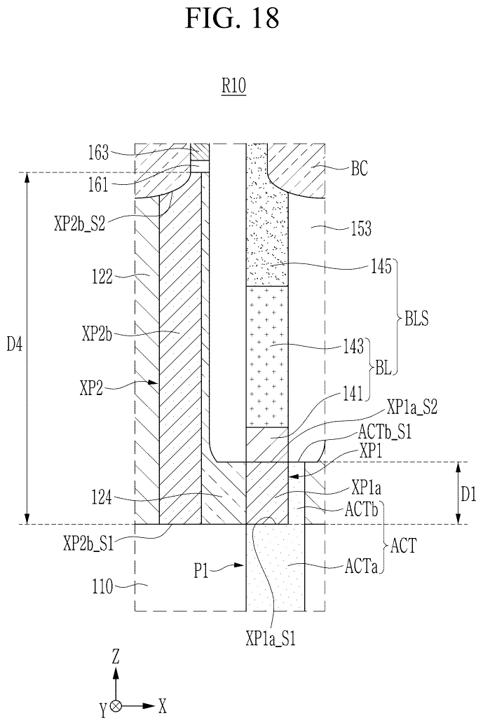

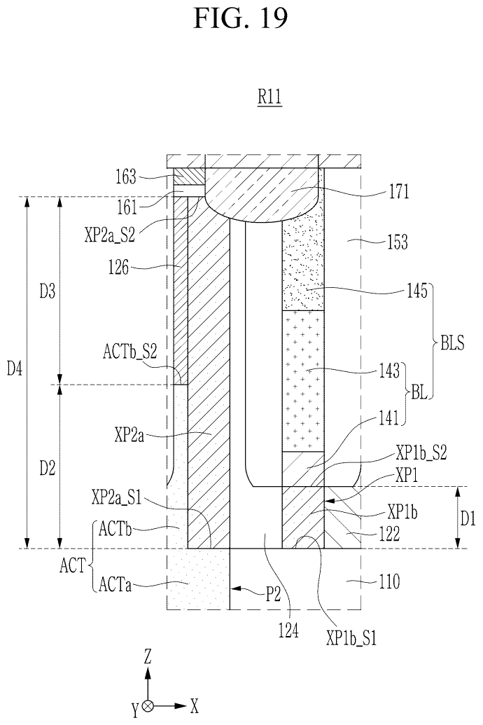

FIG. 12 and FIG. 16 are cross-sectional views illustrating cross-sections taken along the A-A′, B-B', and C-C′ lines of FIG. 1 according to some embodiments. FIGS. 13 and 17 are cross-sectional views illustrating sections taken along the D-D′, E-E′, and F-F′ lines of FIG. 1 according to some embodiments. FIG. 14 is a partially enlarged view showing the R8 region of FIG. 12. FIG. 15 is a partially enlarged view of the R9 region of FIG. 12. FIG. 18 is a partially enlarged view of the R10 region of FIG. 16. FIG. 19 is a partially enlarged view of the R11 region of FIG. 18.

According to the semiconductor device of the embodiment shown in FIGS. 8 to 10, unlike the semiconductor device of the embodiment, there is a difference in that a length of the first pad portion XP1a and the second pad portion XP1b of the first contact pad XP1 differs in the third direction Z, and a length of the first pad portion XP2a and the second pad portion XP2b of the second contact pad XP2 differs in the third direction Z.

In addition, according to the embodiment, unlike the above embodiment, the first pad portion XP1a and the second pad portion XP1b of the first contact pad XP1 may be positioned at different levels on their respective lower surfaces XP1a_S1 and XP1b_S1) and the first pad portion XP2a and the second pad portion XP2b of the second contact pad XP2 may be positioned at different levels on their respective lower surfaces XP2a_S1 and XP2b_S1.

For example, referring to FIGS. 8 to 10, the first pad portion XP1a included in the first contact pad XP1 may overlap the first portion ACTa of the active region ACT in the third direction Z, and may overlap the second portion ACTb of the active region ACT in the first direction X.

The first contact pad XP1 may include a lower surface XP1_S1 and an upper surface XP1_S2 facing each other in the third direction Z.

The lower surface XP1_S1 of the first contact pad XP1 may be formed by the lower surface XP1a_S1 of the first pad portion XP1a and the lower surface XP1b_S1 of the second pad portion XP1b, and the upper surface XP1_S2 of the first contact pad XP1 may be formed by the upper surface XP1a_S2 of the first pad portion XP1a and the upper surface XP1b_S2 of the second pad portion XP1b.

The lower surface XP1a_S1 of the first pad portion XP1a included in the first contact pad XP1 may be in contact with the first portion ACTa of the active region ACT, and the upper surface XP1a_S2 of the first pad portion XP1a may be in contact with the bit line structure BLS.

As shown in FIG. 8, in the embodiment, the lower surface XP1a_S1 of the first pad portion XP1a may be positioned at a level lower than the upper surface of the element isolation layer 110. For example, the upper surface ACTa_S of the first portion ACTa of the active region ACT contacting the lower surface XP1a_S1 of the first pad portion XP1a may be positioned at a level lower than the upper surface of the element isolation layer 110.

In addition, the first side surface XP1a_S3 of the first pad portion XP1a included in the first contact pad XP1 may contact the second pad isolation pattern 124 and the element isolation layer 110. For example, a portion of the first side surface XP1a_S3)of the first pad portion XP1a may be in contact with the second pad isolation pattern 124, and the remaining portion may be in contact with the element isolation layer 110.

The arrangement relationship among the second side surface XP1a_S4 of the first pad portion XP1a included in the first contact pad XP1, the second portion ACTb of the active region ACT, and the active capping pattern 126 may be applied in substantially the same manner as described above with reference to FIG. 5, and therefore a detailed description of some features may be omitted.

As illustrated in FIG. 9, the second pad portion XP1b of the first contact pad XP1 may be positioned on the element isolation layer 110 and may be non-overlapping with the active region ACT in the third direction Z.

In the embodiment, the lower surface XP1b_S1 of the second pad portion XP1b included in the first contact pad XP1 may be in contact with the element isolation layer 110, and the upper surface XP1b_S2 may be in contact with the bit line structure BLS.

As shown in FIG. 10, in the embodiment, the lower surface XP1b_S1 of the second pad portion XP1b included in the first contact pad XP1 may be positioned at a different level from the lower surface XP1a_S1 of the first pad portion XP1a included in the first contact pad XP1. For example, the lower surface XP1b_S1 of the second pad portion XP1b included in the first contact pad XP1 may be positioned at a higher level than the lower surface XP1a_S1 of the first pad portion XP1a.

The second pad portion XP1b included in the first contact pad XP1, as described above with reference to FIG. 6, may be the same or substantially the same as the second pad portion XP1b of the first contact pad XP1 according to the embodiment. Accordingly, a detailed description thereof may be omitted.

In the embodiment, the second contact pad XP2 may include a first pad portion XP2a overlapping the active region ACT in the third direction Z, and a second pad portion XP2b overlapping the element isolation layer 110 in the third direction Z.

The second contact pad XP2 may include a lower surface XP2_S1 and an upper surface XP2_S2 that face each other in a third direction Z.

The lower surface XP2_S1 of the second contact pad XP2 may be constituted by the lower surface XP2a_S1 of the first pad portion XP2a and the lower surface XP2b_S1 of the second pad portion XP2b, and the upper surface XP2_S2 of the second contact pad XP2 may be constituted by the upper surface XP2a_S2 of the first pad portion XP2a and the upper surface XP2b_S2 of the second pad portion XP2b.

In addition, the first pad portion XP2a of the second contact pad XP2 may include a first side surface XP2a_S3 and a second side surface XP2a_S4 facing each other in the first direction X.

The lower surface XP2a_S1 of the first pad portion XP2a included in the second contact pad XP2 may be in contact with the first portion ACTa of the active region ACT, and the upper surface XP2a_S2 of the first pad portion XP2a may be in contact with the storage contact BC.

As shown in FIG. 9, in this embodiment, the lower surface XP2a_S1 of the first pad portion XP2a included in the second contact pad XP2 may be positioned at a level lower than the upper surface of the element isolation layer 110. For example, the upper surface ACTa_S of the first portion ACTa of the active region ACT in contact with the lower surface XP2a_S1 of the first pad portion XP2a may be positioned at a level lower than the upper surface of the element isolation layer 110.

In addition, the second side surface XP2a_S4 of the first pad portion XP2a included in the second contact pad XP2 may contact the second pad isolation pattern 124 and the element isolation layer 110. For example, in the embodiment a portion of the second side surface XP2a_S4 of the first pad portion XP2a may be in contact with the second pad isolation pattern 124, and the remaining portion may be in contact with the element isolation layer 110.

The arrangement relationship among the first side surface XP2a_S3 of the first pad portion XP2a included in the second contact pad XP2, the second portion ACTb of the active region ACT, and the active capping pattern 126 may be substantially the same as described above with reference to FIG. 6, and therefore, a detailed description thereof may be omitted.

As shown in FIG. 8, the second pad portion XP2b of the second contact pad XP2 may be positioned on the element isolation layer 110, and may be non-overlapping with the active region ACT in the third direction Z.

In the embodiment, the lower surface XP2b_S1 of the second pad portion XP2b included in the second contact pad XP2 may be in contact with the element isolation layer 110, and the upper surface XP2b_S2 may be in contact with the storage contact BC.

As shown in FIG. 10, in the embodiment, the lower surface XP2b_S1 of the second pad portion XP2b included in the second contact pad XP2 may be positioned at a different level from the lower surface XP2a_S1 of the first pad portion XP2a included in the second contact pad XP2. For example, the lower surface XP2b_S1 of the second pad portion XP2b included in the second contact pad XP2 may be positioned at a higher level than the lower surface XP2a_S1 of the first pad portion XP2a.

The second pad portion XP2b included in the second contact pad XP2, as described above with reference to FIG. 5, may be the same or substantially the same as the second pad portion XP2b of the second contact pad XP2 according to the embodiment. Therefore, a detailed description thereof may be omitted.

In the embodiment, the second portion ACTb of the active region ACT may have a first length D1 in a third direction Z, the active capping pattern 126 may have a second length D2 in the third direction Z, the first pad portion XP1a of the first contact pad XP1 may have a third length D3 in the third direction Z, and the first pad portion XP2a of the second contact pad XP2 may have a fourth length D4 in the third direction Z.

Also, in the embodiment, the second pad portion XP1b of the first contact pad XP1 may have a fifth length D5 in the third direction Z, and the second pad portion XP2b of the second contact pad XP2 may have the fourth length D4 in the third direction Z.

Here, the first length D1 may refer to a minimum distance in a third direction Z from an upper surface ACTa_S of a first portion ACTa of the active region ACT to an upper surface ACTb_S of a second portion ACTb.

The second length D2 may refer to the minimum distance in the third direction Z from the upper surface ACTb_S of the second portion ACTb of the active region ACT to the upper surface 126_S of the active capping pattern 126.

The third length D3 may refer to the minimum distance in the third direction Z from the lower surface XP1a_S1 to the upper surface XP1a_S2 of the first pad portion XP1a included in the first contact pad XP1.

The fourth length D4 may refer to a minimum distance in the third direction Z from the lower surface XP2a_S1 to the upper surface XP2a_S2 of the first pad portion XP2a included in the second contact pad XP2.

The fifth length D5 may refer to a minimum distance in the third direction Z from the lower surface XP1b_S1 to the upper surface XP1b_S2 of the second pad portion XP1b included in the first contact pad XP1.

The sixth length D6 may refer to a minimum distance in the third direction Z from the lower surface XP2b_S1 to the upper surface XP2b_S2 of the second pad portion XP2b included in the second contact pad XP2.

The description regarding the relationship among the first length D1, the second length D2, the third length D3, and the fourth length D4, as described above with reference to FIG. 7, may be substantially equally applicable to the embodiment. Therefore, a detailed description of the relationship among D1, D2, D3, and D4 will be omitted.

In the embodiment, the third length D3 may be different from the fifth length D5. For example, the third length D3 may be greater than the fifth length D5. For example, the length of the first pad portion XP1a of the first contact pad XP1 in the third direction Z may be greater than the length of the second pad portion XP1b in the third direction Z.

In addition, in the embodiment, the fourth length D4 may be different from the sixth length D6. For example, the fourth length D4 may be greater than the sixth length D6. For example, the length of the first pad portion XP2a included in the second contact pad XP2 in the third direction Z may be greater than the length of the second pad portion XP2b in the third direction Z.

In the embodiment, the fifth length D5 may be different from the sixth length (D6). For example, the fifth length D5 may be greater than the sixth length D6. For example, a length of the second pad portion XP1b included in the first contact pad XP1 in the third direction Z may be greater than a length of the second pad portion XP2b included in the second contact pad XP2 in the third direction Z. However, the relationship among the third length D3, the fourth length D4, the fifth length D5, and the sixth length D6 is not limited thereto, and may be variously modified.

In the embodiment, a portion of the lower surface XP1_S1 of the first contact pad XP1 may be positioned on the element isolation layer 110, and the remaining portion may be positioned on the first portion ACTa of the active region ACT.

Specifically, the lower surface XP1a_S1 of the first pad portion XP1a included in the first contact pad XP1 may positioned on the first portion ACTa of the active region ACT, and the lower surface XP1b_S1 of the second pad portion XP1b may be positioned on the element isolation layer 110.

The upper surface XP1a_S2 of the first pad portion XP1a included in the first contact pad XP1 and the upper surface XP1b_S2 of the second pad portion XP1b may be positioned at substantially the same level.

In the embodiment, a portion of the lower surface XP2_S1 of the second contact pad XP2 may be positioned on the element isolation layer 110, and the remaining portion may be positioned on the first portion ACTa of the active region ACT.

Specifically, the lower surface XP2a_S1 of the first pad portion XP2a included in the second contact pad XP2 may be positioned on the first portion ACTa of the active region ACT, and the lower surface XP2b_S1 of the second pad portion XP2b may be positioned on the element isolation layer 110.

The lower surface XP1a_S1 of the first pad portion XP1a included in the first contact pad XP1 and the lower surface XP2a_S1 of the first pad portion XP2a included in the second contact pad XP2 may be positioned at substantially the same level, and the lower surface XP1b_S1 of the second pad portion XP1b included in the first contact pad XP1 and the lower surface XP2b_S1 of the second pad portion XP2b included in the second contact pad XP2 may be positioned at substantially the same level.

The upper surface XP2a_S2 of the first pad portion XP2a included in the second contact pad XP2 and the upper surface XP2b_S2 of the second pad portion XP2b may be positioned at different levels.

Here, each level of the upper surface XP2a_S2 of the first pad portion XP2a included in the second contact pad XP2 and the upper surface XP2b_S2 of the second pad portion XP2b may refer to the level of the portion positioned at the lowermost in each of the upper surface XP2a_S2 of the first pad portion XP2a and the upper surface XP2b_S2 of the second pad portion XP2b.

This may be a result of each of the first pad portion XP2a and the second pad portion XP2b included in the second contact pad XP2 being recessed by the storage contact BC, as described above.

In addition, the upper surface XP1a_S2 of the first pad portion XP1a included in the first contact pad XP1 and the upper surface XP1b_S2 of the second pad portion XP1b may be positioned at a different level from each of the upper surface XP2a_S2 of the first pad portion XP2a and the upper surface XP2b_S2 of the second pad portion XP2b included in the second contact pad XP2.

Unlike shown in FIGS. 8 to 10, in some embodiments, each of the first contact pad XP1 and the second contact pad XP2 may further include a third pad portion (not shown) positioned on the side surface of the first portion ACTa of the active region ACT.

Specifically, the first pad portion XP1a of the first contact pad XP1 may extend in the third direction Z between the second portion ACTb of the active region ACT and the second pad isolation pattern 124, and between the active capping pattern 126 and the second pad isolation pattern 124, and may overlap the first portion ACTa of the active region ACT and the element isolation layer 110.

The third pad portion (not shown) of the first contact pad XP1 may recess a portion of the element isolation layer 110 from the lower surface of the first pad portion XP1a, and may extend in the third direction Z along the side surface of the first portion ACTa of the active region ACT.

Accordingly, one side surface of the third pad portion (not shown) may be in contact with the first portion ACTa of the active region ACT, and the other side surface may be in contact with the element isolation layer 110.

As such, in some embodiments, when the first contact pad XP1 further includes a third pad portion (not shown) positioned on a side surface of the first portion ACTa of the active region ACT, the second pad portion XP1b included in the first contact pad XP1 may recess a portion of the element isolation layer 110, and a lower surface of the second pad portion XP1b may be positioned at substantially the same level as a lower surface of the third pad portion (not shown).

This may result from a process performed before the formation of the first contact pad XP1, in which the element isolation layer 110 is recessed in the same process step at regions where both the second pad portion XP1b and the third pad portion (not shown) of the first contact pad XP1 are to be positioned.

Although the description has been made with reference to the first contact pad XP1, the description of the third pad portion may be substantially equally applied to the second contact pad XP2.

According to the semiconductor device of the embodiment shown in FIGS. 8 to 10, compared to the semiconductor device according to above embodiment, as the contact area between each side surface of the first contact pad XP1 and the side surface of the second contact pad XP2 and the second portion ACTb of the active region ACT may be relatively increased, electrical characteristics may be improved.

According to the embodiment shown in FIG. 11, unlike the semiconductor device according to above embodiment, it is different in that the active capping pattern (see ‘126’ in FIG. 7) is omitted.

In addition, according to the embodiment shown in FIG. 11, unlike the semiconductor device according to above embodiment, there is a difference in that the relationship between the length of the first contact pad XP1 in the third direction Z and the length of the second portion ACTb of the active region ACT in the third direction Z is different.

The contents regarding the semiconductor device according to the embodiment shown in FIG. 7 may be substantially equally applied to the semiconductor device according to embodiment, and thus, hereinafter, differences from the semiconductor device according to the embodiment shown in FIG. 7 will be mainly described, and other contents will be omitted.

Specifically, referring to FIG. 11, in the embodiment, as the active capping pattern (see ‘126’ of FIG. 7) covering the second portion ACTb of the active region ACT is omitted, the second portion ACTb of the active region ACT may be in contact with a portion of the spacer structure BS.

In the embodiment, the lower surface XP1_S1 of the first contact pad XP1 may be in contact with the element isolation layer 110 and the first portion ACTa of the active region ACT, and the upper surface XP1_S2 may be in contact with the bit line structure BLS.

In the embodiment, the bit line structure BLS is shown as overlapping the first contact pad XP1 in the third direction Z, and not overlapping the second portion ACTb of the active region ACT in the third direction Z, however, this is not limited thereto. For example, unlike as shown in FIG. 11, in some embodiments, a portion of the bit line structure BLS may overlap the upper surface XP1_S2 of the first contact pad XP1, and the remaining portion may overlap the upper surface ACTb_S of the second portion ACTb of the active region ACT.

In the embodiment, the upper surface XP1_S2 of the first contact pad XP1 may be positioned at substantially the same level as the upper surface ACTb_S of the second portion ACTb of the active region ACT. For example, the upper surface XP1_S2 of the first contact pad XP1 and the upper surface ACTb_S of the second portion ACTb of the active region ACT may be substantially planar.

In the embodiment, the upper surface XP1_S2 of the first contact pad XP1 may be positioned at substantially the same level as the upper surface of the gate insulating pattern GOX constituting the word line structure WLS and the upper surface of the word line capping layer 136.

In the embodiment, the lower surface XP2_S1 of the second contact pad XP2 may be in contact with the element isolation layer 110 and the first portion ACTa of the active region ACT, and the upper surface XP2_S2 may be in contact with the storage contact BC.

In the embodiment, the storage contact BC is illustrated as overlapping the second contact pad XP2 in the third direction Z, and as not overlapping the second portion ACTb of the active region ACT in the third direction Z, but is not limited thereto. For example, unlike as shown in FIG. 11, in some embodiments, a portion of the storage contact BC overlaps the upper surface XP2_S2 of the second contact pad XP2, and the remaining portion may overlap the upper surface ACTb_S of the second portion ACTb of the active region ACT.

In the embodiment, the upper surface XP2_S2 of the second contact pad XP2 may be positioned at a lower level than the upper surface ACTb_S of the second portion ACTb of the active region ACT.

Here, the level of the upper surface XP2_S2 of the second contact pad XP2 may refer to the level of the lowest portion of the upper surface XP2_S2.

In addition, the upper surface XP2_S2 of the second contact pad XP2 may be positioned at a lower level than the upper surface XP1_S2 of the first contact pad XP1. The upper surface XP2_S2 of the second contact pad XP2 may be positioned at a lower level than the upper surface of the gate insulating pattern GOX constituting the word line structure WLS and the upper surface of the word line capping layer 136.

In the embodiment, the lower surface XP1_S1 of the first contact pad XP1 and the lower surface XP2_S1 of the second contact pad XP2 may be positioned at substantially the same level. For example, the lower surface XP1_S1 of the first contact pad XP1 and the lower surface XP2_S1 of the second contact pad XP2 may be positioned at substantially the same level as the upper surface of the element isolation layer 110 and the upper surface ACTa_S of the first portion ACTa of the active region ACT.

In the embodiment, the first contact pad XP1 and the second portion ACTb of the active region ACT may have a first length D1 in the third direction Z, and the second contact pad XP2 may have a second length D2 in the third direction Z.

Here, the first length D1 may refer to a minimum length in the third direction Z between the lower surface XP1_S1 and the upper surface XP1_S2 of the first contact pad XP1, and a minimum distance in the third direction Z between the upper surface ACTa_S of the first portion ACTa of the active region ACT and the upper surface ACTb_S of the second portion ACTb.

The second length D2 may refer to a minimum distance in the third direction Z between the lower surface XP2_S1 and the upper surface XP2_S2 of the second contact pad XP2.

In the embodiment, the first length D1 may be different from the second length D2. For example, the first length D1 may be greater than the second length D2. For example, the length of the first contact pad XP1 and the length of the second portion ACTb of the active region ACT may be substantially the same, and the length of the second contact pad XP2 may be smaller than each of the length of the first contact pad XP1 and the length of the second portion ACTb of the active region ACT.

This may result from the omission of the active capping pattern 126, as the mask pattern (see “MP” in FIG. 24) is used during a patterning process of the substrate 10 to form the first portion ACTa and the second portion ACTb of the active region ACT having different widths, and is removed before performing the process of forming the contact pad XP.

The semiconductor device of the embodiment may have substantially the same effects as that of the semiconductor device according to above embodiment.

According to the semiconductor device of the embodiment shown in FIGS. 12 to 15, unlike the semiconductor device of the embodiment described above with reference to FIGS. 2 to 7, there is a difference in that the arrangement relationship between the bit line structure BLS and the storage contact BC is changed.

In addition, according to the embodiment, unlike the semiconductor device according to above embodiment, there is a difference in that the configuration and structure of the landing pad LP are changed.

This may be a result of a difference in the process method for forming the bit line structure BLS and the landing pad LP in the embodiment, compared to the process method for forming the bit line structure BLS and the landing pad LP in another embodiment.

Hereinafter, the differences between the semiconductor device according to above embodiment and the semiconductor device according to the embodiment will be mainly described.

Referring to FIGS. 12 to 15, the semiconductor device according to the embodiment may further include a first buffer layer 161 and a second buffer layer 163 sequentially stacked on the storage contact BC and the fence pattern 162.

The first buffer layer 161 and the second buffer layer 162 may contain materials having different etching selectivities. For example, the first buffer layer 161 may contain an insulating material such as silicon oxide, and the second buffer layer 162 may contain an insulating material such as silicon nitride. However, this is not limited thereto, and the material contained in the first and second buffer layers 161, 162 may be variously changed.

In the embodiment, the bit line structure BLS may be positioned between adjacent storage contacts BC, and may be positioned in a first bit line trench BL_T1 that recesses the first contact pad XP1, the first and second pad isolation patterns 122 and 124, and the active capping pattern 126.

The bottom surface of the first bit line trench BL_T1 may be defined by the first contact pad XP1, the first and second pad isolation patterns 122 and 124, and the active capping pattern 126, and the inner wall may be defined by storage contacts BC adjacent to each other and buffer layers 161 and 163.

In the embodiment, the bit line structure BLS may be positioned between adjacent fence patterns 162, and may be positioned in a second bit line trench BL_T2 that recesses a portion of the word line capping layer 136.

The bottom surface of the second bit line trench BL_T2 may be defined by the word line capping layer 136, and the inner wall may be defined by the word line capping layer 136, adjacent fence patterns 162, and buffer layers 161 and 163.

In the embodiment, the bit line spacer 153 positioned on the side surface of the bit line structure BLS may have a single layer structure. For example, the bit line spacer 153 may contain silicon oxide, but is not limited thereto.

In addition, in the embodiment, although the bit line spacer 153 is shown as having a single layer structure, the number of insulating layers constituting the bit line spacer 153 is not limited thereto and may be variously changed.

The bit line spacer 153 may be extended along the inner wall of each of the first bit line trench BL_T1 and the second bit line trench BL_T2. The bit line spacer 153 may not be positioned on each bottom surface of the first bit line trench BL_T1 and the second bit line trench BL_T2.

The bit line structure BLS may be positioned on the bit line spacer 153 in each of the first bit line trench BL_T1 and the second bit line trench BL_T2.

The bit line structure BLS may be positioned on the first contact pad XP1 in the first bit line trench BL_T1. The bit line structure BLS may be electrically connected to the first end portion P1 of the active region ACT through the first contact pad XP1.

Also, the bit line structure BLS may be positioned on the word line capping layer 136 in the second bit line trench BL_T2.

In the embodiment, the bit line structure BLS may include sequentially stacked a bit line BL and a bit line capping layer 145. The bit line BL may have a multilayer structure including a first conductive layer 141 and a second conductive layer 143.

In the embodiment, the first conductive layer 141, the second conductive layer 143, and a bit line capping layer 145 constituting the bit line BL may be substantially to the same as the first conductive layer 142, the second conductive layer 144, and the bit line capping layer 146 constituting the bit line BL as described above with reference to FIG. 2. Therefore, a detailed description thereof may be omitted.

In the embodiment, the storage contact BC may be positioned between bit line spacers 153 that are adjacent to each other. Both side surfaces of the storage contact BC may be in contact with the bit line spacer 153. However, this is not limited thereto, and another configuration may be further positioned between both side surfaces of the storage contact BC and the bit line spacer 153.

In the embodiment, unlike the storage contact BC illustrated in the embodiment shown in FIGS. 2 to 7, the storage contact BC may not recess the second contact pad XP2. For example, the lower surface of the second contact pad XP2 may have a linear shape.

The semiconductor device according to the embodiment may further include a mold layer 167 positioned on the bit line structure BLS and buffer layers 161 and 163.

The mold layer 167 may cover the upper surface of the bit line structure BLS, the upper surface of the bit line spacer 153, and the upper surface of the second buffer layer 163.

The mold layer 167 may contain an insulating material having an etch selectivity with respect to silicon oxide. The mold layer 167 may contain an insulating material such as, for example, silicon nitride, SiOCN, SiOC, or a combination thereof, but is not limited thereto.

In the embodiment, the landing pad LP may be positioned in the mold layer 167, and may be surrounded by the mold layer 167. The landing pad LP may penetrate the mold layer 167 and be connected to the storage contact BC. The landing pad LP may recess a portion of each of the storage contact BC, the bit line capping layer 145 configuring the bit line structure BLS, the bit line spacer 153, and the buffer layers 161 and 163.

In the embodiment, the landing pad LP may contact the upper surface of the storage contact BC. The landing pad LP may be positioned to overlap with at least a portion of the storage contact BC in the third direction Z. For example, a central axis of the landing pad LP may not be aligned with a central axis of the storage contact BC, and may be positioned offset from each other.

In the embodiment, the landing pad LP may include a first pad conductive layer 171, a silicide layer 173, and a second pad conductive layer 175 sequentially stacked.

The first pad conductive layer 171 may be positioned at a lower level than the mold layer 167. The first pad conductive layer 171 may recess a portion of each of the storage contact BC, the first buffer layer 161, the second buffer layer 163, the bit line spacer 153, and the bit line capping layer 145, and may be in contact with these.

The first pad conductive layer 171 may contain doped polysilicon as an impurity-doped polysilicon, but is not limited thereto. For example, the first pad conductive layer 171 may contain doped polysilicon having the same impurity as the first contact pad XP and the storage contact BC.

The silicide layer 173 may be positioned in the mold layer 167. The silicide layer 173 may be positioned on the first pad conductive layer 173. The width of the upper surface of the first pad conductive layer 173 may be substantially the same as the width of the silicide layer 173.

The second pad conductive layer 175 may be positioned on the silicide layer 173. The second pad conductive layer 175 may be extended in the third direction Z in the mold layer 167, and may have, for example, a pillar shape or a cylinder shape. The upper surface of the second pad conductive layer 175 may be positioned at substantially the same level as the upper surface of the mold layer 167.

In the embodiment, the materials included in the silicide layer 173 and the second pad conductive layer 175 may be substantially the same as the silicide layer 172 and the conductive layer 174 constituting the landing pad LP in the embodiment shown in FIG. 2. Therefore, a detailed description thereof may be omitted.

Although not shown in detail, unlike as illustrated in FIG. 12 and FIG. 13, in some embodiments, substantially the same as the embodiment shown in FIG. 2 and FIG. 3, the landing pad LP may be configured such that the first pad conductive layer 171 may be omitted, and the landing pad LP may include the silicide layer 173 and the second pad conductive layer 175.

In this case, the buffer layers 161 and 163, the mold layer 167, and the pad spacer 165 may be omitted, and a plurality of insulating patterns (not shown) positioned between landing pads LP adjacent to each other, substantially the same as in the embodiment according to FIG. 2 and FIG. 3, may be further included.

Accordingly, the silicide layer 173 constituting the landing pad LP may be positioned on the upper surface of the storage contact BC, and the second pad conductive layer 175 may be positioned to entirely cover the upper surface of the silicide layer 173, the upper surface of the bit line spacer 153, and the bit line capping layer 145.

The landing pad LP may be separated and insulated by the plurality of insulating patterns substantially in the same manner as in the embodiment shown in FIGS. 2 and 3, and the insulating pattern positioned between the landing pads LP may recess a portion of the second pad conductive layer 175, the bit line spacer 153, and the bit line capping layer 145.

In addition, the second pad conductive layer 175 forming the landing pad LP covers the side surface and upper surface of the fence pattern 162, and the insulating pattern that separates and insulates the landing pad LP may recess a portion of the fence pattern 162.

This may be a result of the process method for forming the landing pad LP being different.

The semiconductor device according to the embodiment may further include a pad spacer 165 positioned on a side surface of a second pad conductive layer 175 configuring a landing pad LP.

The pad spacer 165 may extend in the third direction Z along the side surface of the second pad conductive layer 175. The pad spacer 165 may be positioned between the mold layer 167 and the side surface of the second pad conductive layer 175.

The pad spacer 165 may contain an insulating material such as silicon nitride, but is not limited thereto.

In the embodiment, etch stop layer 180 may be positioned on mold layer 167. The landing pad 180 may be connected through the capacitor DSP etch stop layer 180. The descriptions of the etch stop layer 180 and the capacitor DSP may be substantially equally applicable to those provided above with reference to FIGS. 2 and 3 in the above embodiment. Therefore, a detailed description thereof will be omitted.

Unlike the embodiment shown in FIGS. 12 and 13, in some embodiments, the fence pattern 162 for separating and insulating the storage contact BC may be omitted.

In this case, the storage contact BC may be separated and insulated by the word line structure WLS. For example, the word line structure WLS may be further extended in the third direction Z such that the upper surface may be in contact with the first buffer layer 161, and may separate and insulate the storage contact BC in the second direction Y.

Accordingly, the upper surface of the word line structure WLS may be positioned at substantially the same level as the storage contact BC, and the gate insulating pattern GOX constituting the word line structure WLS may contact storage contacts BC adjacent to each other.

In addition, a portion of the gate insulating pattern GOX and the word line capping layer 163 constituting the upper surface of the word line structure WLS may be recessed by adjacent landing pads LP.

Hereinafter, with further reference to FIG. 14 and FIG. 15, the first contact pad XP1 and the second contact pad XP2 will be described in detail.

The descriptions of the first contact pad XP1 and the second contact pad XP2 provided above with reference to FIGS. 5 to 7 may be substantially equally applicable to the first contact pad XP1 and the second contact pad XP2 of the embodiment. Therefore, the following description focuses on differences from the embodiment shown in FIGS. 5 to 7.

Referring to FIGS. 14 and 15, in the embodiment, the lower surface XP1a_S1 of the first pad portion XP1a included in the first contact pad XP1 may be in contact with the first portion ACTa of the active region ACT, and the upper surface XP1a_S2 may be in contact with the bit line structure BLS.

In addition, the lower surface XP1b_S1 of the second pad portion XP1b included in the first contact pad XP1 may be in contact with the element isolation layer 110, and the upper surface XP1b_S2 may be in contact with the bit line structure BLS.

In the embodiment, the lower surface XP2a_S1 of the first pad portion XP2a included in the second contact pad XP2 may be in contact with the first portion ACTa of the active region ACT, and the upper surface XP2a_S2 may be in contact with the storage contact BC.

In addition, the lower surface XP2b_S1 of the second pad portion XP2b included in the second contact pad XP2 may be in contact with the element isolation layer 110, and the upper surface XP2b_S2 may be in contact with the storage contact BC.

In the embodiment, the upper surface XP2a_S2 of the first pad portion XP2a included in the second contact pad XP2 and the upper surface XP2b_S2 of the second pad portion XP2b may not be recessed by the storage contact BC, unlike the embodiment shown in FIG. 5 and FIG. 6.

Accordingly, the upper surface XP2a_S2 of the first pad portion XP2a included in the second contact pad XP2 and the upper surface XP2b_S2 of the second pad portion XP2b may each have a linear shape.

In the embodiment, the lower surface XP1a_S1 of the first pad portion XP1a included in the first contact pad XP1 may be positioned at substantially the same level as the lower surface XP2a_S1 of the first pad portion XP2a included in the second contact pad XP2, and the upper surface XP1a_S2 of the first pad portion XP1a included in the first contact pad XP1 may be positioned at a different level from the upper surface XP2a_S2 of the first pad portion XP2a included in the second contact pad XP2. For example, the upper surface XP1a_S2 of the first pad portion XP1a included in the first contact pad XP1 may be positioned at a lower level than the upper surface XP2a_S2 of the first pad portion XP2a included in the second contact pad XP2.

Accordingly, the lower surface of the bit line structure BLS in contact with the upper surface XP1a_S2 of the first pad portion XP1a included in the first contact pad XP1 may be positioned at a lower level than the lower surface of the storage contact BC in contact with the upper surface XP2a_S2 of the first pad portion XP2a included in the second contact pad XP2.

In the embodiment, the lower surface XP1b_S1 of the second pad portion XP1b included in the first contact pad XP1 may be positioned at substantially the same level as the lower surface XP2b_S1 of the second pad portion XP2b included in the second contact pad XP2, and the upper surface XP1b_S2 of the second pad portion XP1b included in the first contact pad XP1 may be positioned at a different level from the upper surface XP2b_S2 of the second pad portion XP2b included in the second contact pad XP2. For example, the upper surface XP1b_S2 of a second pad portion XP1b included in the first contact pad XP1 may be positioned at a lower level than the upper surface XP2b_S2 of the second pad portion XP2b included in the second contact pad XP2.

Accordingly, the lower surface of the bit line structure BLS in contact with the upper surface XP1b_S2 of the second pad portion XP1b included in the first contact pad XP1 may be positioned at a lower level than the lower surface of the storage contact BC in contact with the upper surface XP2b_S2 of the second pad portion XP2b included in the second contact pad XP2.

In the embodiment, the second portion ACTb of the active region ACT may have a first length D1 in the third direction Z, the first active capping pattern 126a may have a second length D2 in the third direction Z, the first pad portion XP1a and the second pad portion XP1b included in the first contact pad XP1 may have a third length D3 in the third direction Z, the first pad portion XP1a and the second pad portion XP2b included in the second contact pad XP2 may have a fourth length D4 in the third direction Z, and the second active capping pattern 126b may have a fifth length D5 in the third direction Z.

Here, the first active capping pattern 126a may refer to an active capping pattern positioned on the second portion ACTb of the active region ACT that is in contact with the first pad portion XP1a included in the first contact pad XP1, and the second active capping pattern 126b may refer to an active capping pattern positioned on the second portion ACTb of the active region ACT that is in contact with the first pad portion XP2a included in the second contact pad XP2.

Also, each of the first length D1, the second length D2, the third length D3, the fourth length D4, and the fifth length D5 may refer to a maximum length in the third direction Z.

In the embodiment, the sum of the first length D1 and the second length D2 may be substantially the same as the third length D3. For example, the lengths of each of the first pad portion XP1a and the second pad portion XP1b included in the first contact pad XP1 may be substantially equal to the sum of the length of the second portion ACTb of the active region ACT and the length of the first active capping pattern 126a.

In the embodiment, the sum of the first length D1 and the fifth length D5 may be substantially the same as the fourth length D4. For example, the lengths of each of the first pad portion XP2a and the second pad portion XP2b included in the second contact pad XP2 may be substantially the same as the sum of the length of the second portion ACTb of the active region ACT and the length of the second active capping pattern 126b.

In the embodiment, the third length D3 may be different from the fourth length D4. For example, the third length D3 may be smaller than the fourth length D4. For example, the length of the first pad portion XP1a included in the first contact pad XP1 may be less than the length of the first pad portion XP2a included in the second contact pad XP2, and the length of the second pad portion XP1b included in the first contact pad XP1 may be less than the length of the second pad portion XP2b included in the second contact pad XP2.

In addition, the second length D2 may be different from the fifth length D5. For example, the second length D2 may be less than the fifth length D5. For example, the length of the first active capping pattern 126a may be smaller than the length of the second active capping pattern 126b. However, the relationship among the first length D1, the second length D2, the third length D3, the fourth length D4, and the fifth length D5 is not limited thereto and may be variously changed.

According to the embodiment shown in FIGS. 16 to 19, unlike the embodiment shown in FIGS. 12 to 15, there is a difference in that, as the storage contact BC may be omitted, the second contact pad XP2 may be directly connected to the landing pad LP.

Specifically, referring to FIGS. 16 to 19, in the embodiment, as the storage contact (‘BC’ in FIG. 13) may be omitted, the second end portion P2 of the active region ACT may be electrically connected to the second contact pad XP2, which is directly connected to the landing pad LP.

In the embodiment, the second contact pad XP2 may be in contact with the first pad conductive layer 171 constituting the landing pad LP. The second contact pad XP2 may be in contact with the first buffer layer 161. The first pad conductive layer 171 constituting the landing pad LP may recess a portion of each of the bit line structure BLS, the bit line spacer 153, the second contact pad XP2, the second pad isolation pattern 124, and the buffer layers 161 and 163.

In the embodiment, the bottom surface of the first bit line trench BL_T1 may be defined by the first contact pad XP1, the first and second pad isolation patterns 122 and 124, and the second portion ACTb of the active region ACT, and the inner wall may be defined by the first and second pad isolation patterns 122 and 124, the buffer layers 161 and 163, and the active capping pattern 126.

The bit line spacer 153 may extend along the inner wall of the first bit line trench BL_T1, and the bit line structure BLS may be positioned on the bit line spacer 153 in the first bit line trench BL_T1.

Hereinafter, with further reference to FIG. 18 and FIG. 19, the first contact pad XP1 and the second contact pad XP2 will be described in detail.

The first contact pad XP1 and the second contact pad XP2 provided above with reference to FIGS. 5 to 7 may be substantially the same as the first contact pad XP1 and the second contact pad XP2 of the embodiment and a description thereof that would be duplicative may be omitted. Therefore, the following description focuses on differences from the embodiment shown in FIGS. 14 and 15.

Referring to FIGS. 18 and 19, in the embodiment, the lower surface XP1a_S1 of the first pad portion XP1a included in the first contact pad XP1 may be in contact with the first portion ACTa of the active region ACT, and the upper surface XP1a_S2 may be in contact with the bit line structure BLS.

Unlike shown in FIG. 18, in some embodiments, a portion of the lower surface of the bit line structure BLS may be in contact with the first pad portion XP1a included in the first contact pad XP1, and the remaining portion may be in contact with the second portion ACTb of the active region ACT.

In addition, the lower surface XP1b_S1 of the second pad portion XP1b included in the first contact pad XP1 may be in contact with the element isolation layer 110, and the upper surface XP1b_S2 may be in contact with the bit line structure BLS.

In the embodiment, the lower surface XP2a_S1 of the first pad portion XP2a included in the second contact pad XP2 may be in contact with the first portion ACTa of the active region ACT, and the upper surface XP2a_S2 may be in contact with a lower surface of a first pad conductive layer 173 and the first buffer layer 161 configuring the landing pad LP.

In addition, the lower surface XP2b_S1 of the second pad portion XP2b included in the second contact pad XP2 may be in contact with the element isolation layer 110, and the upper surface XP2b_S2 may be in contact with the lower surface of the first pad conductive layer 173 constituting the landing pad LP and the first buffer layer 161.

In the embodiment, the lower surface XP1a_S1 of the first pad portion XP1a included in the first contact pad XP1 may be positioned at substantially the same level as the lower surface XP2a_S1 of the first pad portion XP2a included in the second contact pad XP2, and the upper surface XP1a_S2 of the first pad portion XP1a included in the first contact pad XP1 may be positioned at a different level from the upper surface XP2a_S2 of the first pad portion XP2a included in the second contact pad XP2. For example, the upper surface XP1a_S2 of the first pad portion XP1a included in the first contact pad XP1 may be positioned at a lower level than the upper surface XP2a_S2 of the first pad portion XP2a included in the second contact pad XP2.

Accordingly, the lower surface of the bit line structure BLS contacting the upper surface XP1a_S2 of the first pad portion XP1a included in the first contact pad XP1 may be positioned at a lower level than the lower surface of the first pad conductive layer 171 of the landing pad LP contacting the upper surface XP2a_S2 of the first pad portion XP2a included in the second contact pad XP2.

In addition, in the embodiment, the lower surface XP1b_S1 of the second pad portion XP1b included in the first contact pad XP1 may be positioned at substantially the same level as the lower surface XP2b_S1 of the second pad portion XP2b included in the second contact pad XP2, and the upper surface XP1b_S2 of the second pad portion XP1b included in the first contact pad XP1 may be positioned at a level different from the upper surface XP2b_S2 of the second pad portion XP2b included in the second contact pad XP2. For example, the upper surface XP1b_S2 of the second pad portion XP1b included in the first contact pad XP1 may be positioned at a lower level than the upper surface XP2b_S2 of the second pad portion XP2b included in the second contact pad XP2.

Accordingly, the lower surface of the bit line structure BLS, which is in contact with the upper surface XP1b_S2 of the second pad portion XP1b included in the first contact pad XP1, may be positioned at a lower level than the lower surface of the first pad conductive layer 171 of the landing pad LP, which is in contact with the upper surface XP2b_S2 of the second pad portion XP2b included in the second contact pad XP2.

In the embodiment, the upper surface XP1a_S2 of the first pad portion XP1a included in the first contact pad XP1 may be positioned at substantially the same level as the first upper surface ACTb_S2 of the second portion ACTb of the active region ACT positioned at the first end portion P1, and the upper surface XP1b_S2 of the second pad portion XP1b included in the first contact pad XP1 may be positioned at a lower level than the second upper surface ACTb_S1 of the second portion ACTb of the active region ACT positioned at the second end portion P2.

In addition, in the embodiment, the upper surface XP2a_S2 of the first pad portion XP2a included in the second contact pad XP2 may be positioned at a higher level than the second upper surface ACTb_S of the second portion ACTb of the active region ACT positioned at the second end portion P2 of the active region ACT, and the upper surface XP2b_S2 of the second pad portion XP2b included in the second contact pad XP2 may be positioned at a higher level than the first upper surface ACTb_S1 of the second portion ACTb of the active region ACT positioned at the first end portion P1.

In the embodiment, the second portion ACTb of the active region ACT positioned at the first end portion P1 of the active region ACT, and each of the first pad portion XP1a and the second pad portion XP1b included in the first contact pad XP1, may have a first length D1 in the third direction Z, the second portion ACTb of the active region ACT positioned at the second end portion P2 of the active region ACT may have a second length D2 in the third direction Z, the active capping pattern 126 may have a third length D3 in the third direction Z, and the first pad portion XP2a and the second pad portion XP2b included in the second contact pad XP2 may have a fourth length D4 in the third direction Z.

Here, the first length D1, the second length D2, the third length D3, and the fourth length D4 may refer to the maximum length in the third direction Z.

In the embodiment, the first length D1 may be smaller than the second length D2, the third length D3, and the fourth length D4. For example, the lengths of the first pad portion XP1a and the second pad portion XP1b included in the first contact pad XP1 may be smaller than the length of the second portion ACTb of the active region ACT positioned at the second end portion P2 of the active region ACT, the length of the active capping pattern 126, and the lengths of the first pad portion XP2a and the second pad portion XP2b included in the second contact pad XP2, respectively.

In the embodiment, the sum of the second length D2 and the third length D3 may be substantially the same as the fourth length D4. For example, the lengths of each of the first pad portion XP2a and the second pad portion XP2b included in the second contact pad XP2 may be substantially the same as the sum of the length of the second portion ACTb of the active region ACT positioned at the second end portion P2 of the active region ACT and the length of the active capping pattern 126. However, the relationship among the first length D1, the second length D2, the third length D3, and the fourth length D4 is not limited thereto and may be variously changed.

According to the semiconductor device of the embodiments shown in FIGS. 12 to 19 may have substantially the same effects as that the semiconductor device according to above embodiment.

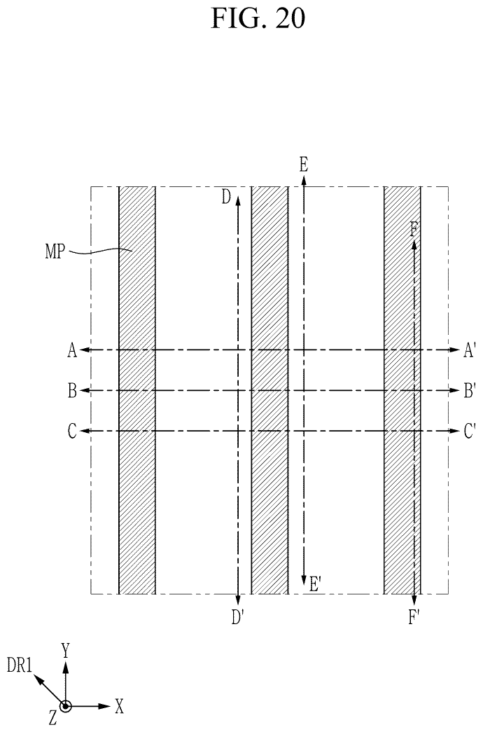

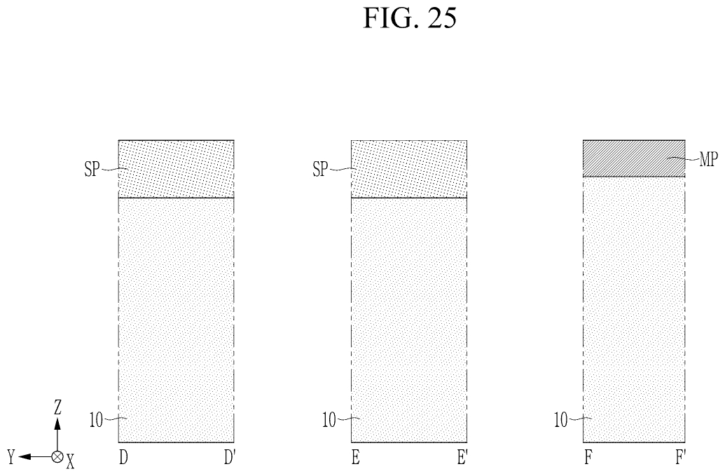

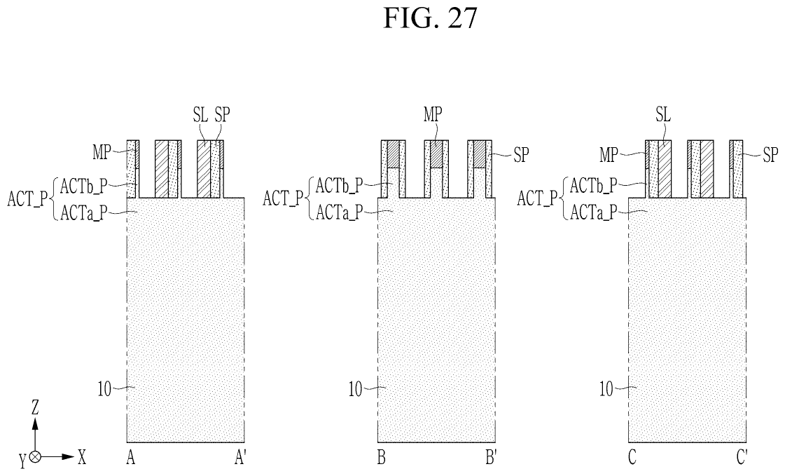

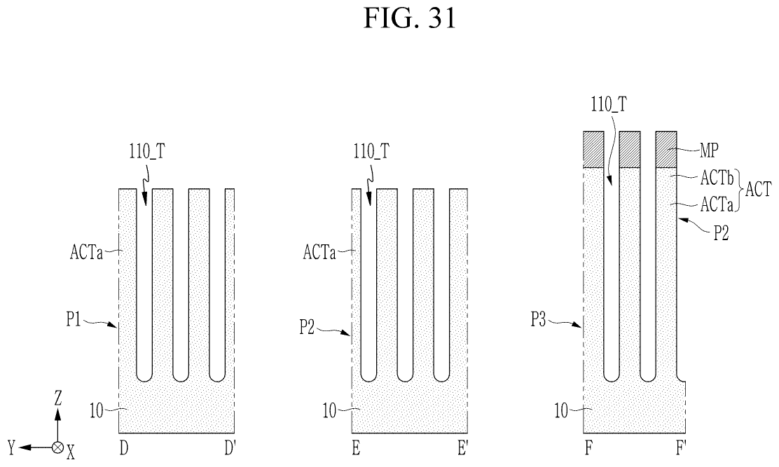

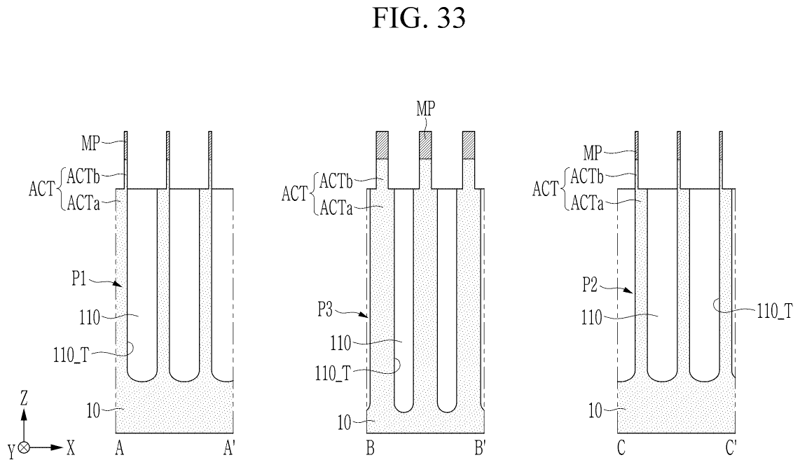

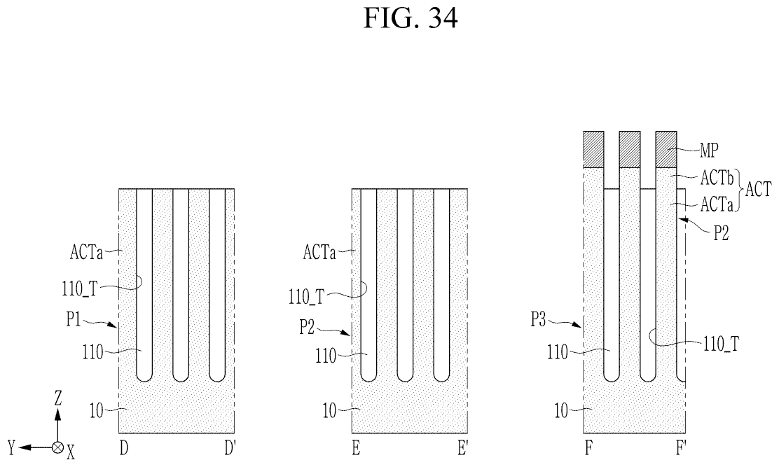

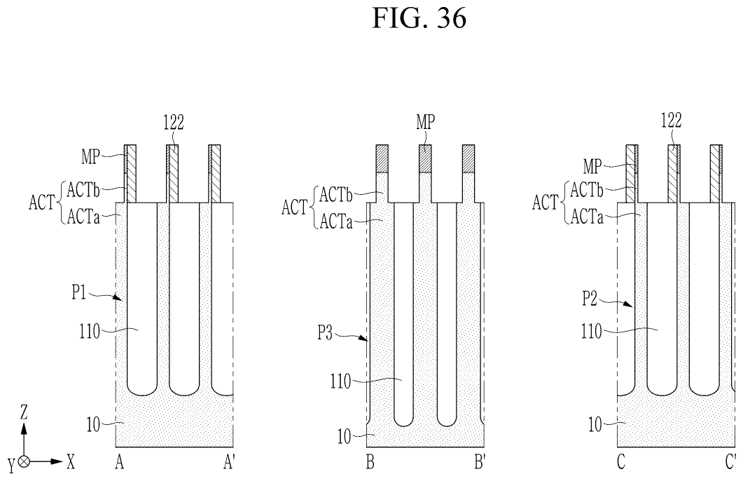

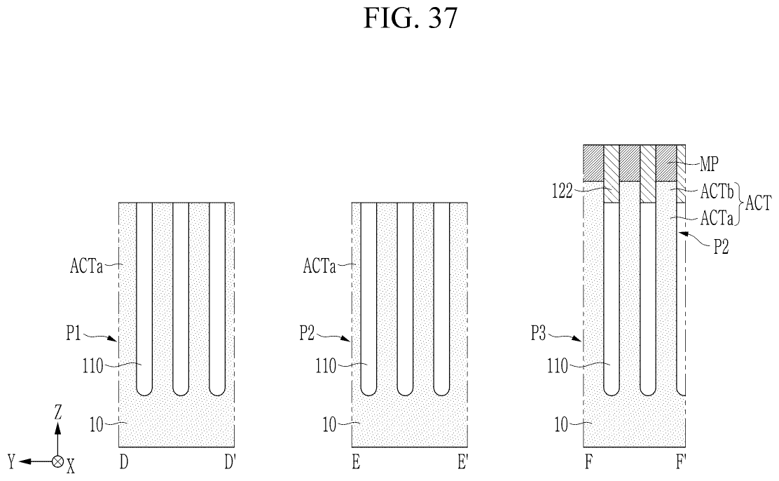

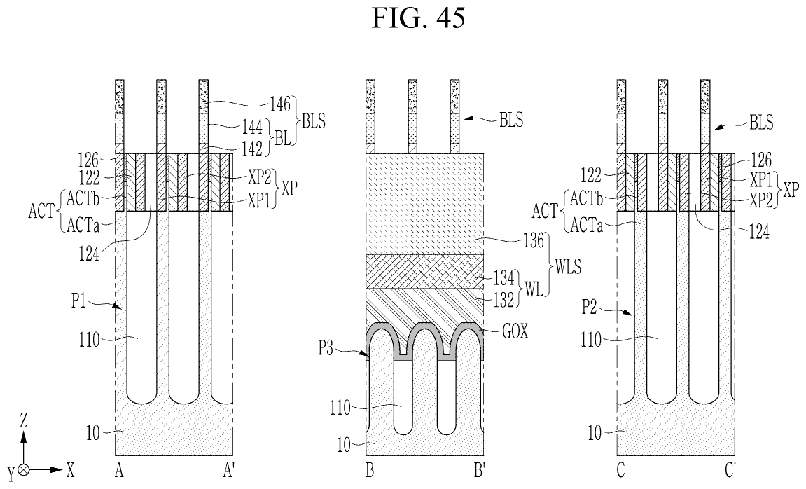

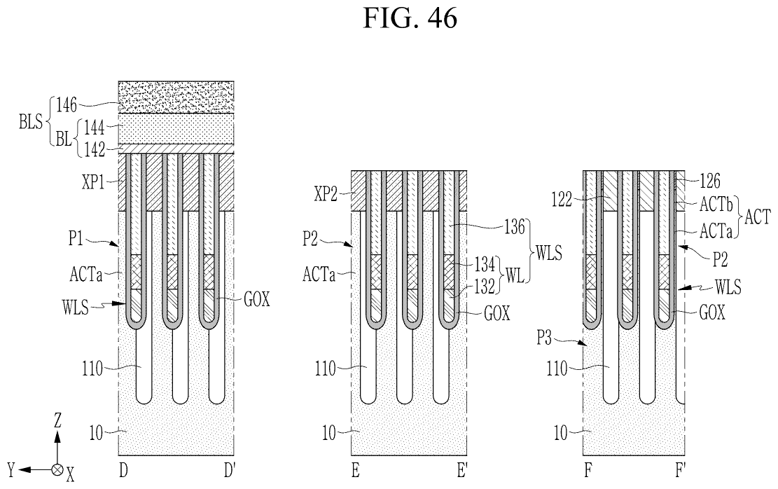

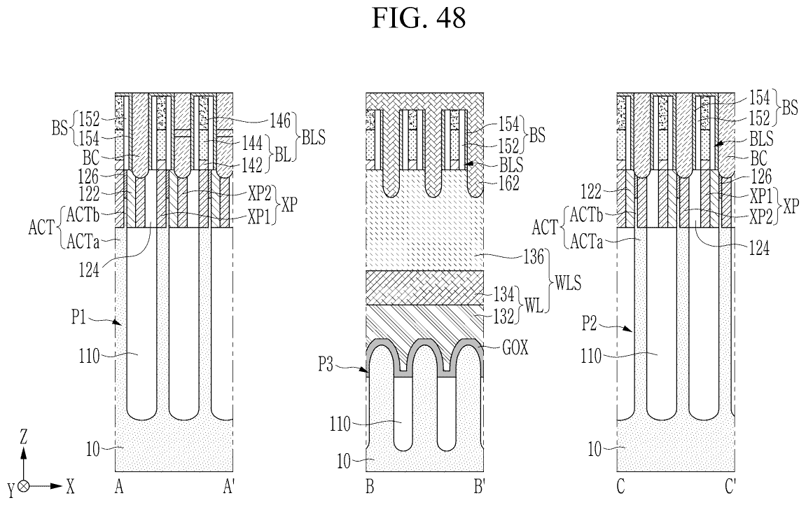

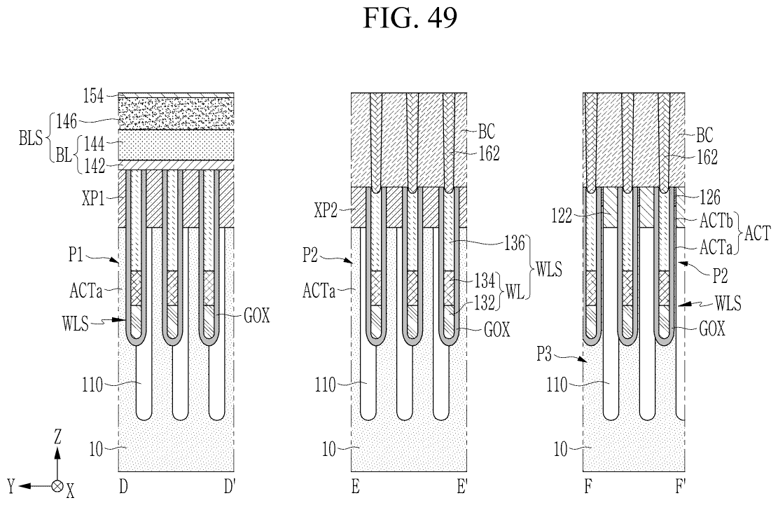

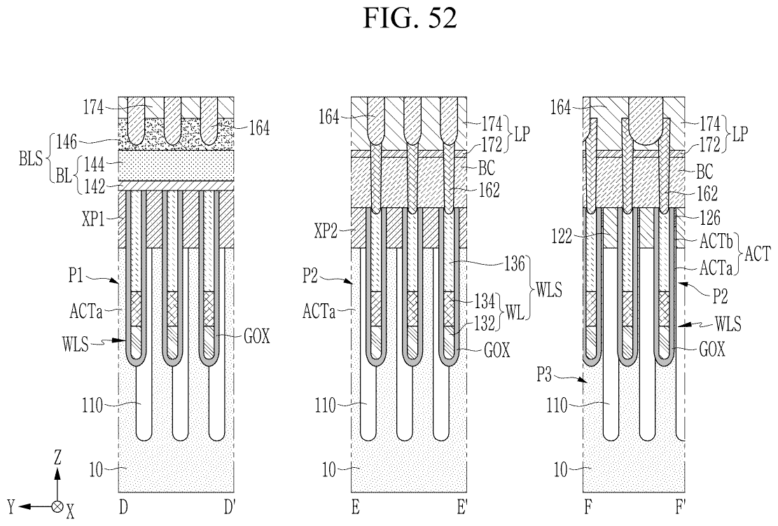

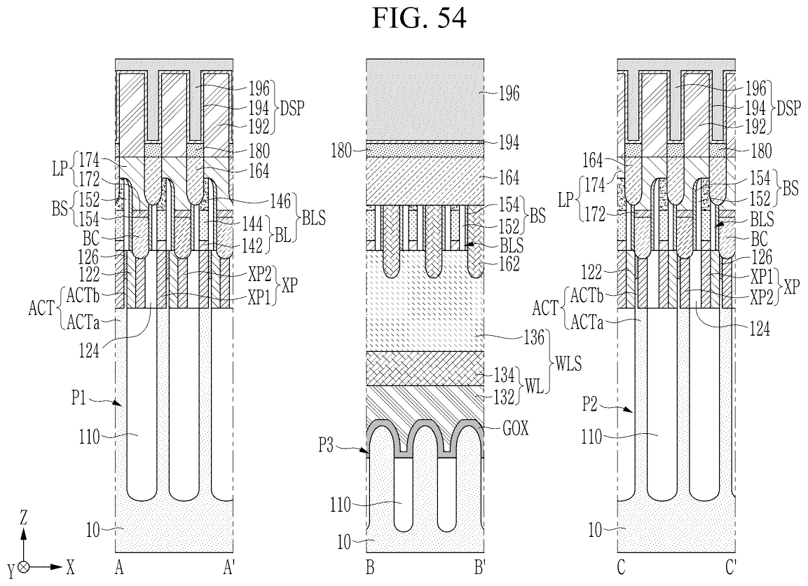

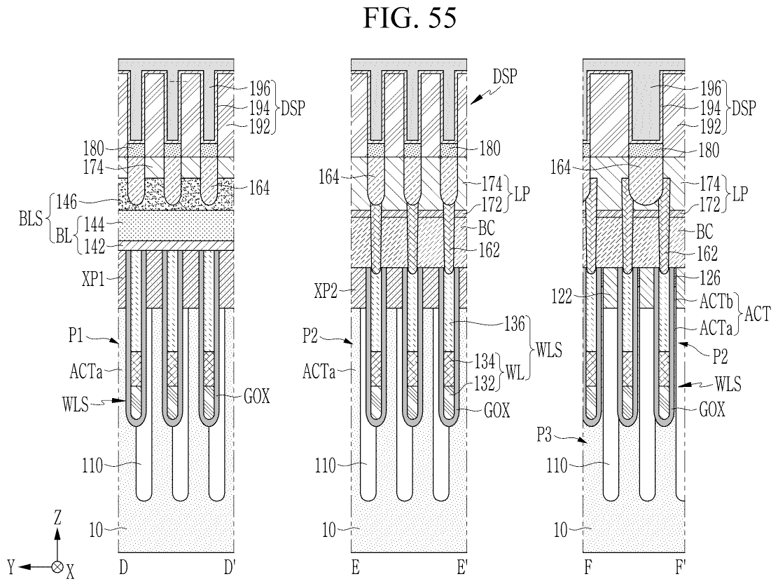

Hereinafter, with reference to FIGS. 20 to 55, a method of manufacturing a semiconductor device will be described. Hereinafter, the same configuration as previously described will be referred to by the same reference numeral, and redundant descriptions may be omitted or simplified, and differences will be mainly described.

FIGS. 20 to 55 are views for explaining the method of manufacturing a semiconductor device according to an embodiment.

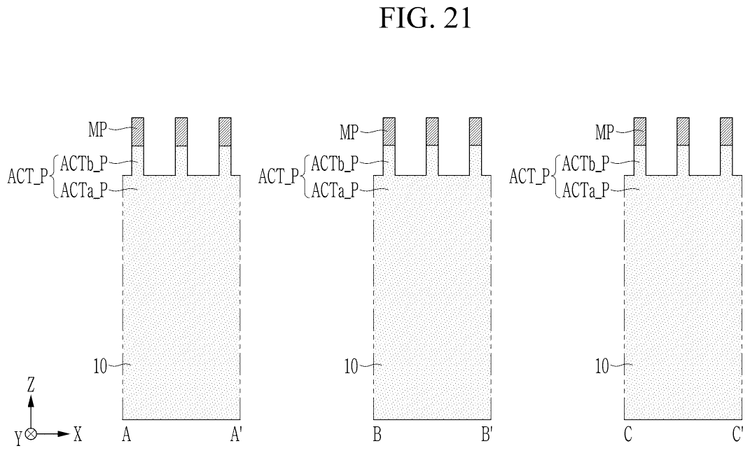

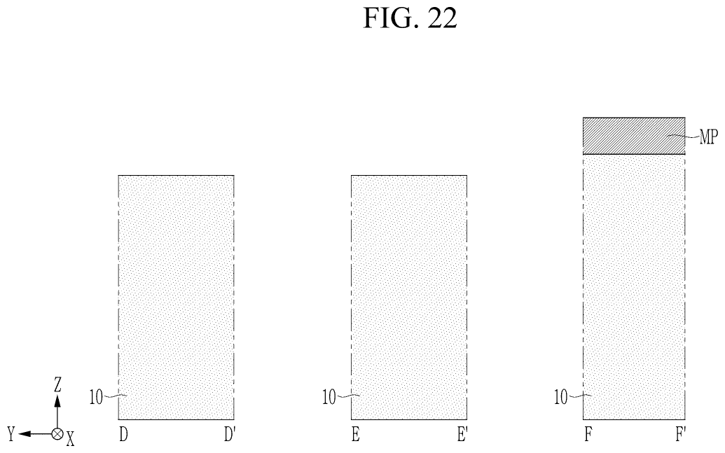

Specifically, FIGS. 20, 23, 26, 29, 32, 35, 38, 41, 44, 47, 50, and 53 are plan views at respective manufacturing process steps for illustrating the method of manufacturing the semiconductor device according to an embodiment, FIGS. 21, 24, 27, 30, 33, 36, 39, 42, 45, 48, 51, and 54 are cross-sectional views taken along lines A-A′, B-B′, and C-C′ at respective manufacturing process steps for illustrating the method of manufacturing a semiconductor device according to an embodiment, and FIGS. 22, 25, 28, 31, 34, 37, 40, 43, 46, 49, 52, and 55 are cross-sectional views taken along lines D-D′, E-E′, and F-F′ at respective manufacturing process steps for illustrating the method of manufacturing a semiconductor device according to an embodiment.

First, referring to FIGS. 20 to 22, the plurality of mask patterns MP may be formed on the substrate 10.

The plurality of mask patterns MP may have a line shape in a plan view, may extend in the second direction Y parallel to the substrate 10, and may be arranged spaced apart in the first direction X. Accordingly, the substrate 10 positioned between adjacent mask patterns MP may be exposed.

In an embodiment, the mask pattern MP may have a single layer structure. The mask pattern MP may contain an insulating material such as silicon oxide, silicon nitride, silicon oxynitride, silicon oxycarbide, silicon carbonitride, silicon oxycarbonitride, or a combination thereof. For example, the mask pattern MP may contain silicon nitride. However, this is not limited thereto.

Unlike as shown in FIGS. 20 to 22, in some embodiments, the mask pattern MP may have a multilayer structure including a plurality of mask layers sequentially stacked. For example, the mask pattern MP may include a first mask layer, a second mask layer, and a third mask layer sequentially stacked.

In an embodiment, the first mask layer may contain a material that prevents the surface of the substrate 10 including silicon from being damaged or contaminated in subsequent process steps by the infiltration of a material such as nitrogen into the surface of the substrate 10. For example, the first mask layer may contain an insulating material such as silicon oxide or oxynitride in order to prevent a material such as nitrogen from penetrating the surface of the substrate 10, but is not limited thereto.

The second mask layer may contain an insulating material for patterning the substrate 10. For example, the second mask layer may contain silicon nitride and silicon oxynitride and the like, but is not limited thereto.

The third mask layer may contain a material having etch selectivity with respect to the second mask layer. The third mask layer may serve to protect the second mask layer. For example, the third mask layer formed on the second mask layer may prevent the thickness of the second mask layer from decreasing in subsequent process steps and may allow the thickness of the second mask layer to be maintained. For example, the third mask layer may contain an insulating material such as silicon oxide, but is not limited thereto.

Subsequently, the substrate 10 may be patterned using the mask pattern MP as an etching mask.

By using the mask pattern MP as an etching mask to pattern the substrate 10, a trench may be formed in a region of the substrate 10 where a portion has been removed. The bottom surface of a trench formed in the substrate 10 is defined by the upper surface of the substrate 10, and the inner wall of the trench may be defined by the mask pattern MP and the side surface of the substrate 10. For example, the substrate 10 region overlapping with the mask pattern MP in the third direction Z may be positioned at a relatively higher level compared to the region not overlapping with the mask pattern MP in the third direction Z, and may have a protruded shape.

In the substrate 10, a region overlapping with the mask pattern MP in the third direction Z may be defined as a second portion ACTb_P of a preliminary active region ACT_P, and a region not overlapping with the mask pattern MP in the third direction Z may be defined as a first portion ACTa_P of the preliminary active region ACT_P.

The second portion ACTb_P of the preliminary active region ACT_P may extend in a protruded shape toward the third direction Z from the upper surface of the first portion ACTa_P, and the width of the second portion ACTb_P of the preliminary active region ACT_P may be smaller than the width of the first portion ACTa_P.

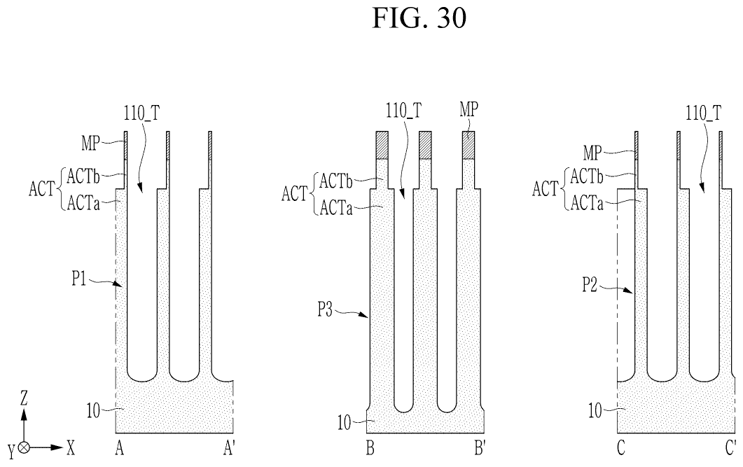

The first portion ACTa_P of the preliminary active region ACT_P corresponds to the first portion (see ‘ACTa’ in FIG. 30) of the active region (see ‘ACT’ in FIG. 30) formed in subsequent process steps, and the second portion ACTb_P of the preliminary active region ACT_P may correspond to the second portion (see ‘ACTb’in FIG. 30) of the active region (see ‘ACT’in FIG. 30).

The method of manufacturing the semiconductor device according to an embodiment may include a process step of doping an impurity into the substrate 10 before or after patterning a portion of the substrate 10.

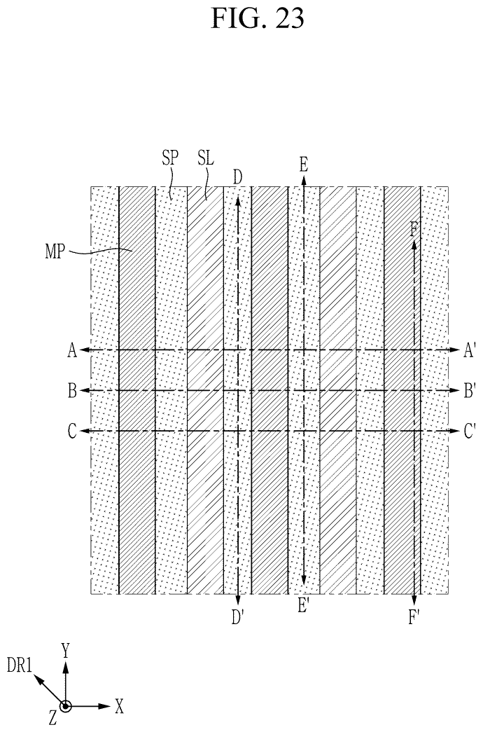

Subsequently, referring to FIGS. 23 to 25, a plurality of spacers SP and a plurality of sacrifice layers SL may be sequentially formed.

The plurality of spacers SP and the plurality of sacrifice layers SL may be extended in the second direction Y in a plan view to have a line shape, and may be arranged spaced apart in the first direction X.

Specifically, an insulating material for forming the spacer SP may be deposited over the entire surface of the substrate 10. The insulating material for forming the spacer SP may be conformally formed along the upper surface of the first portion ACTa_P of the preliminary active region ACT_P, the side surface of the second portion ACTb_P, and the side surface and upper surface of the mask pattern MP.

The insulating material for forming the spacer SP may be an insulating material such as silicon oxide, for example, but is not limited thereto.

Subsequently, a portion of the insulating material deposited over the entire surface of the substrate 10 may be removed to form a spacer SP. The process steps of removing the portion of the insulating material for forming the spacer SP may include, for example, a step of performing an etch back process, but the method of removing the portion of the insulating material is not limited thereto and may be variously modified.

In the process step for removing the portion of an insulating material for forming the spacer SP, the insulating material formed on the upper surface of the first portion ACTa_P of the preliminary active region ACT_P and on the upper surface of the mask pattern MP may be removed, and the remaining insulating material may constitute the spacer SP.

Accordingly, the spacer SP may be positioned on the side surface of the second portion ACTb_P of the preliminary active region ACT_P and on the side surface of the mask pattern MP. The spacer SP may expose the upper surface of the first portion ACTa_P positioned between second portions ACTb_P of adjacent preliminary active regions ACT_P.

Subsequently, the sacrifice layer SL may be formed on the preliminary active region ACT_P of the substrate 10 exposed by the spacer SP.

The sacrifice layer SL may be formed on the upper surface of the first portion ACTa_P of the preliminary active region ACT_P exposed by spacers SP adjacent to each other. For example, the sacrifice layer SL may fill a remaining region after the formation of the spacer SP in a space between adjacent second portions ACTb_P of the preliminary active regions ACT_P and adjacent mask patterns MP. The sacrifice layer SL may be positioned between spacers SP adjacent to each other.

The material for forming the sacrifice layer SL may contain, for example, materials such as SOH (Spin On Hardmask), photoresist, or amorphous carbon, but is not limited thereto.

The process steps for forming the sacrifice layer SL may include forming a material for forming the sacrifice layer SL over the entire surface of the substrate 10, and then performing a planarization process.

Accordingly, the upper surface of the sacrifice layer SL, the upper surface of the spacer SP, and the upper surface of the mask pattern MP may be positioned at substantially the same level, and may be substantially planarized.

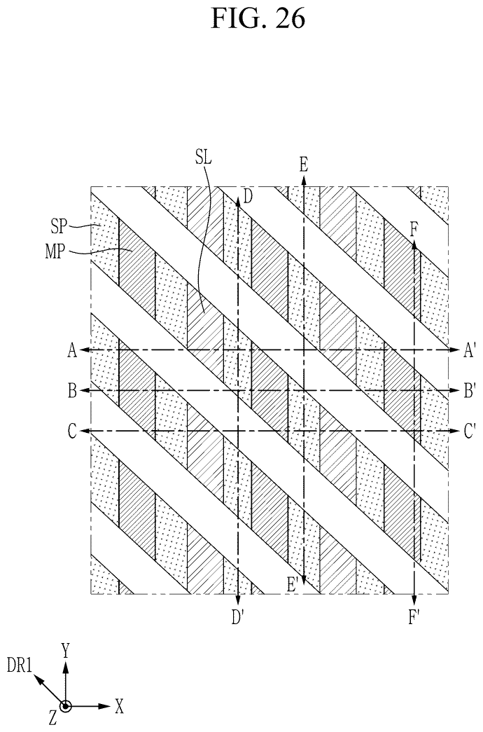

Subsequently, referring to FIGS. 26 to 28, a plurality of first active mask patterns (not shown) for forming the plurality of active regions ACT may be formed by patterning the substrate 10.

Although not illustrated in detail, the plurality of first active mask patterns expose the upper surface of the preliminary active region ACT_P included in the substrate 10, and may be repeatedly arranged while being spaced apart from each other.

The plurality of first active mask patterns may have a linear shape extending in the fourth direction DR1, which is a diagonal direction intersecting in a plan view with the first direction X and the second direction Y.

The plurality of first active mask patterns may be patterned in various shapes in order to form an active region having a designed shape. For example, the plurality of first active mask patterns may be formed through a double patterning process. In another example, the plurality of first active mask patterns may be formed through a patterning process including a single photolithography process and an etching process. As another example, the plurality of first active mask patterns may be formed through a quadruple patterning process in which a double patterning process is performed twice.

By performing a patterning process using the plurality of first active mask patterns as an etching mask, a portion of the preliminary active region ACT_P may be removed, and the remaining preliminary active region ACT_P may be extended in the fourth direction DR1 in a plan view.

In the step of performing a patterning process using the plurality of first active mask patterns as an etching mask, portions of the spacer SP, the mask pattern MP, and the sacrifice layer SL may be removed together.

After patterning on the preliminary active region ACT_P extending in the fourth direction DR1, the remaining spacer SP, the mask pattern MP, and the sacrifice layer SL may be positioned.

As the plurality of first active mask patterns may have a linear shape extending the fourth direction DR1, a trench extending in the fourth direction DR1 in a plan view may be formed in a region where a portion of the preliminary active region ACT_P, the spacer SP, the mask pattern MP, and a portion of the sacrifice layer SL has been removed.

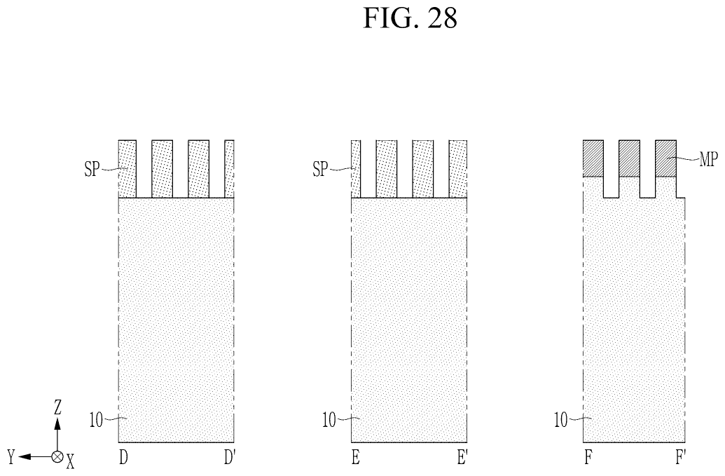

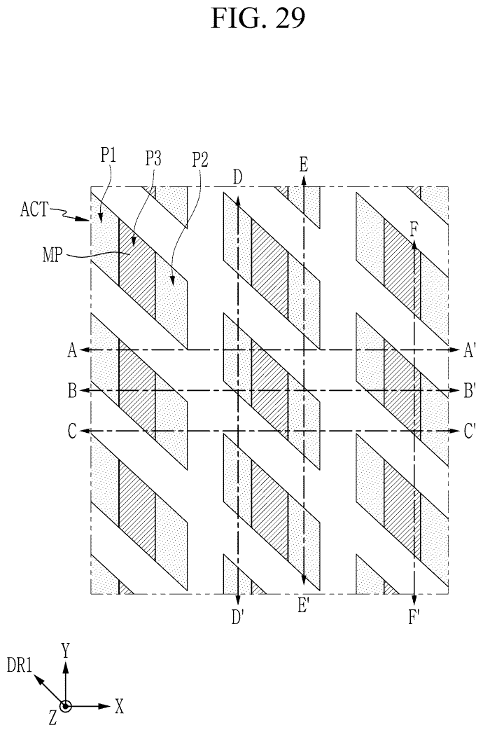

Subsequently, referring additionally to FIGS. 29 to 31 together with FIGS. 28 to 30, the sacrifice layer SL remaining on the preliminary active region ACT_P may be removed. The sacrifice layer SL may be removed by an ashing process or a cleaning process, but is not limited thereto. As the sacrifice layer SL is removed, a portion of the preliminary active region ACT_P positioned in the region where a portion of the sacrifice layer SL has been removed may be exposed.

Subsequently, the plurality of first active mask patterns (not shown) may be separated by etching in a line direction extending in the second direction Y, thereby forming a plurality of second active mask patterns (not shown), and the plurality of active regions ACT may be formed by using these as an etching mask.

As a patterning process is performed using the plurality of second active mask patterns (not shown) as etching masks, the resulting plurality of active regions ACT may be arranged in a plan view in a first direction X and a second direction Y, and each of the active regions ACT may have a bar shape extending in the fourth direction DR1 in plan view.

Specifically, each of the plurality of active regions ACT may include the first end portion P1 and the second end portion P2 positioned at both sides of a fourth direction DR1, and the central portion P3 positioned between the first end portion P1 and the second end portion P2. For example, the first end portion P1 and the second end portion P2 of the active region ACT may be positioned on one side and the other side, respectively, of the central portion P3 based on the fourth direction DR1.

The central portion P3 of the active region ACT may refer to the center in the longitudinal direction of the active region ACT. The first end portion P1 and the second end portion P2 of the active region ACT may have a shape that is point-symmetric in a plan view with respect to the central portion P3.

The active region ACT may include a first side surface extending in the second direction Y and a second side surface extending in the fourth direction (DR1), and the first side surface and the second side surface may meet each other at the respective ends of the first end portion P1 and the second end portion P2 of the active region ACT. However, the planar shape of the active region ACT is not limited thereto, and in the process steps for forming the active region ACT, as the shapes of the above-described the first active mask pattern (not shown) and the second active mask pattern (not shown), which are used as etching masks, may be variously patterned, the planar shape of the active region ACT may be variously changed.

Each of the first portion ACTa_P and the second portion ACTb_P of the preliminary active region ACT_P may constitute the first portion ACTa and the second portion ACTb of the active region ACT at the first end portion P1 and the second end portion P2 of the active region ACT, respectively.

In the process step of patterning using the plurality of second active mask patterns as an etching mask, an element isolation trench 110_T may be formed between the plurality of active regions ACT. For example, the element isolation trench 110_T may be formed in a region of the substrate 10 that does not overlap the spacer SP in the third direction Z.

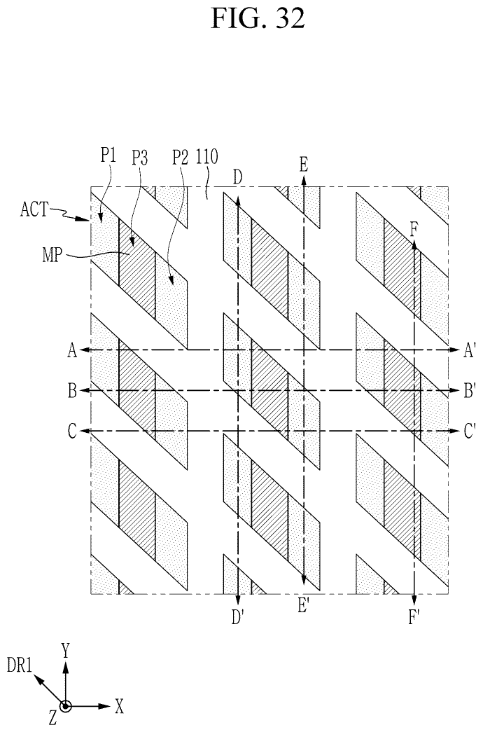

Subsequently, referring to FIGS. 32 to 34, the element isolation layer 110 defining the active region ACT may be formed by filling an insulating material in the element isolation trench 110_T.

The step of forming the element isolation layer 110 may contain filling an insulating material in the element isolation trench 110_T, and removing a portion of the insulating material. The insulating material for forming the element isolation layer 110 may be, for example, silicon oxide, but is not limited thereto.

The step of removing a portion of the insulating material for forming the element isolation layer 110 may include, for example, a step of performing an etch-back process. The etch-back process may be performed after filling an insulating material in the element isolation trench 110_T until the upper surface of the insulating material may be positioned at substantially the same level as the upper surface of the first portion ACTa of the active region ACT.

In the process step of forming the element isolation layer 110, the upper surface of the element isolation layer 110 and the upper surface of the first portion ACTa of the active region ACT may be positioned at substantially the same level and may be substantially planarized. However, the process method of forming the element isolation layer 110 is not limited thereto and may be variously modified.

The second portion ACTb of the active region ACT may be positioned to protrude toward the third direction Z from the upper surface of the first portion ACTa, so that the upper surface of the second portion ACTb of the active region ACT may be positioned at a higher level than the upper surface of the element isolation layer 110.

Accordingly, a space may be formed between the second portions ACTb of the active regions ACT adjacent to each other and the mask patterns MP positioned on these. For example, a trench may be formed, in which inner sidewalls may be defined by the second portions ACTb of each of some of the plurality of active regions ACT that may be adjacent to each other and the mask patterns MP disposed thereon, and a bottom surface may be defined by an upper surface of the element isolation layer 110 and the first portions ACTa of each of some of the plurality of active regions ACT.

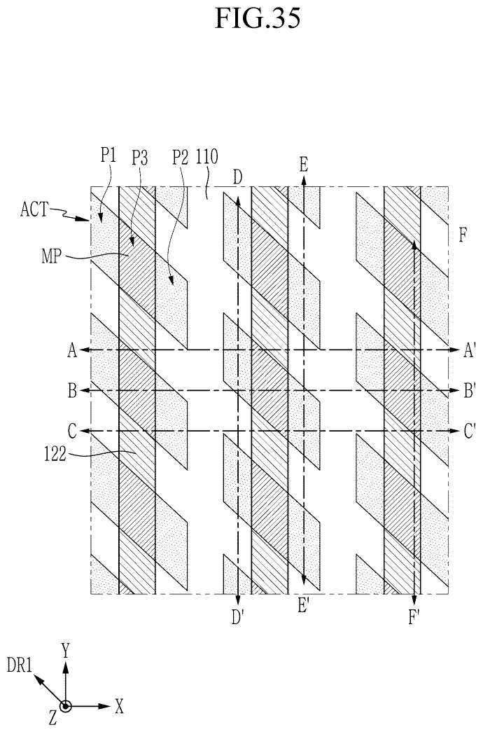

Subsequently, referring to FIGS. 35 to 37, the plurality of first pad isolation patterns 122 may be formed between active regions ACT adjacent to each other in the second direction Y.

A step of forming the plurality of first pad isolation patterns 122 may include conformally depositing an insulating material for forming the first pad isolation patterns 122 over an entire surface of the substrate 10, and removing a portion of the insulating material.

The step of removing the portion of the insulating material to form the first pad isolation pattern 122 may include, for example, performing a wet etch and/or dry etch process, but is not limited thereto.

The portion of the insulating material for forming the first pad isolation pattern 122 may be removed, and the remaining insulating material may be positioned between the central portions P3 of the active regions ACT that may be adjacent in the second direction Y, and may be spaced apart in the second direction Y to constitute the plurality of first pad isolation patterns 122.

The first pad isolation pattern 122 may be positioned between the third central portions P3 of each of the active regions ACT positioned adjacent to each other in the second direction Y, and may cover the upper surface of the element isolation layer 110.

The first pad isolation pattern 122 may extend in the third direction Z along the second portion ACTb of the active region ACT and a side surface of the mask pattern MP, and may be positioned at substantially the same level as an upper surface of the mask pattern MP.

In an embodiment, the step of depositing an insulating material for forming the first pad isolation pattern 122 and the step of removing a portion of the insulating material may be repeatedly performed.

This is to prevent the first pad isolation pattern 122 from being formed with a thickness that does not correspond to a design value, due to a narrow width or spacing between third central portions P3 of the active regions ACT that are adjacent to each other in the second direction Y. For example, the steps for forming the first pad isolation pattern 122 may be repeatedly performed until the upper surface of the first pad isolation pattern 122 may be positioned at substantially the same level as the upper surface of the mask pattern MP.

Accordingly, the first pad isolation pattern 122 may be stably formed between the third central portions P3 of the active regions ACT adjacent in the second direction Y, and the plurality of contact pads XP formed in subsequent process step may be effectively insulated and isolated by the first pad isolation pattern 122.

The insulating material for forming the first pad isolation pattern 122 may be, for example, silicon oxide, but is not limited thereto.

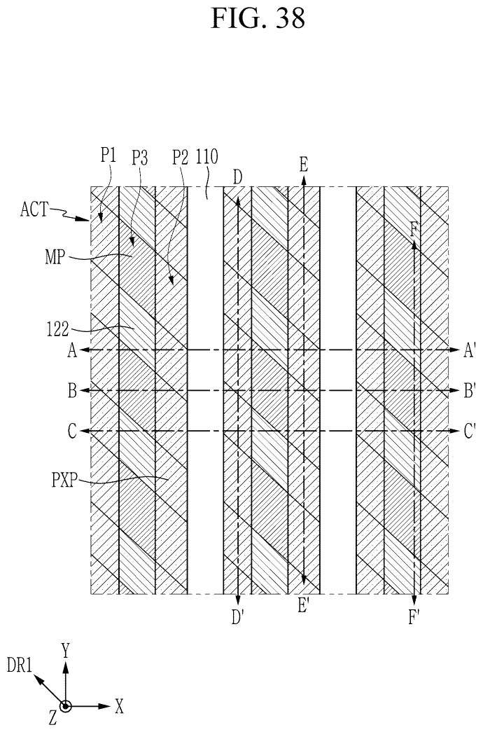

Subsequently, referring to FIGS. 38 to 40, a plurality of preliminary contact pads (PXP) may be formed on the first end portion P1 and the second end portion P2 of each of the plurality of active regions ACT.

The plurality of preliminary contact pads PXP may extend in the second direction Y, have a line shape in a plan view, and may be formed spaced apart in the first direction X.

The plurality of preliminary contact pads PXP may be formed spaced apart from each other in the first direction X, with the second portion ACTb of the active region ACT, the mask pattern MP, and the first pad isolation pattern 122, which may be formed on side surfaces of the ACTb and the MP, interposed therebetween.

Any one of the plurality of preliminary contact pads PXP may extend in the second direction Y, may overlap the first ends P1 of the plurality of active regions ACT and the element isolation layer 110 positioned between positioned between the first ends P1 of adjacent active regions ACT in the third direction Z, and another may extend in the second direction Y and may overlap the second ends P2 of the plurality of active regions ACT and the element isolation layer 110 positioned between the second ends P2 of the plurality of adjacent active regions ACT in the third direction Z.

The plurality of preliminary contact pads PXP may be spaced apart from each other in the first direction X, and may be formed to expose a portion of the element isolation layer 110 that may be positioned between the first end portion P1 of one of a pair of adjacent active regions ACT and the second end portion P2 of the other.

Forming the plurality of preliminary contact pads PXP may include forming a conductive material for forming the preliminary contact pad PXP and removing a portion of the conductive material.

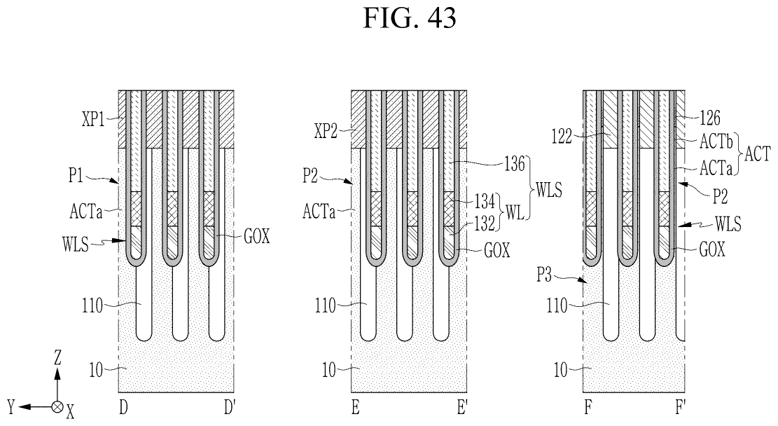

As described above, prior to the process step of forming the preliminary contact pad PXP, a portion of the substrate 10 may be patterned, such that the bottom surface of a recess may be defined by the upper surface of the first portion ACTa of the active region ACT, and the inner wall may be defined by the side surface of the second portion ACTb of the active region and the side surface of the mask pattern MP. After forming the recess, the preliminary contact pad PXP may be formed. As a result, the contact area between the contact pad (see ‘XP’ in FIG. 43) formed in subsequent process step and the active region ACT may be increased.

For example, prior to the process step of forming the preliminary contact pad PXP, after patterning the substrate 10 to form a recess defined by the upper surface of the first portion ACTa of the active region ACT and the side surface of the second portion ACTb, as the preliminary contact pad PXP may be formed, the preliminary contact pad PXP may be formed to be in contact with the first portion ACTa and the second portion ACTb of the active region ACT.

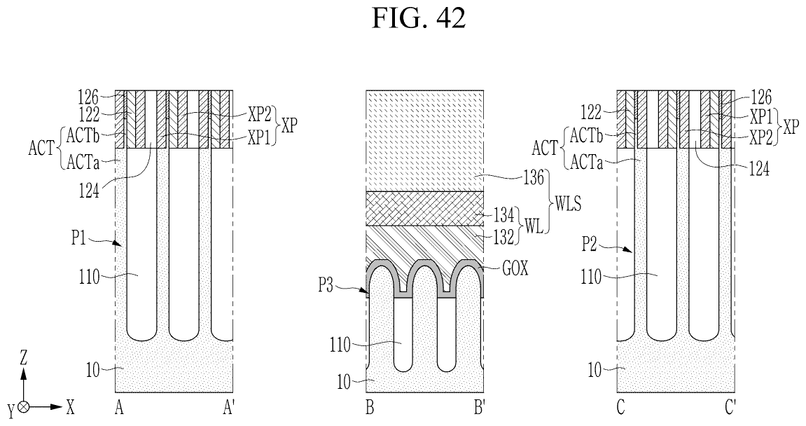

Accordingly, as the lower surface and side surface of the contact pad (see ‘XP’ of FIG. 42), which is formed in subsequent process step, may contact the active region ACT, the contact area between the contact pad (see ‘XP’ of FIG. 42) and the active region ACT may be relatively increased as compared to the case in which only the lower surface of the contact pad (see ‘XP’ of FIG. 42) contacts the active region ACT.

The step of removing a portion of the conductive material may include performing an etch-back process or a dry etching process, but is not limited thereto.

As such, the upper surface of the remaining preliminary contact pad PXP after removing a portion of the conductive material may be positioned at substantially the same level as the upper surface of the mask pattern MP. For example, the length in the third direction Z of the contact pad (see ‘XP’ of FIG. 42) formed in a subsequent process step may be variously changed by the length in the third direction Z of the mask pattern MP formed on the second portion ACTb of the active region ACT.

In addition, the conductive material for forming a plurality of preliminary contact pad PXP may be, for example, doped polysilicon, but is not limited thereto.

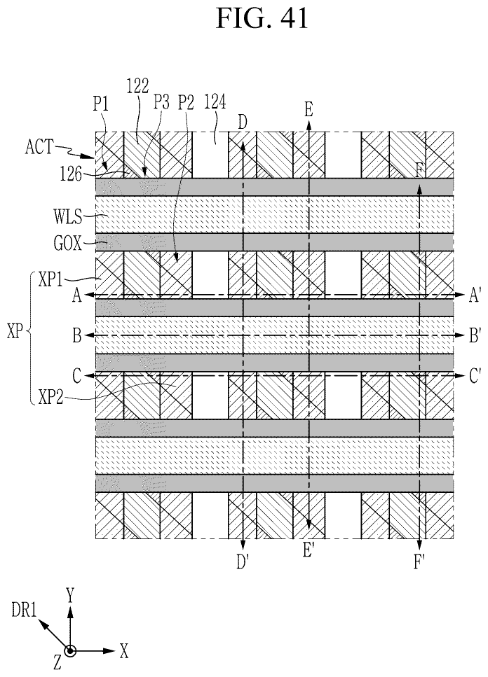

Subsequently, referring to FIGS. 41 to 43, the second pad isolation pattern 124 may be formed between adjacent preliminary contact pads PXP.

A step of forming the second pad isolation pattern 124 may include a step of forming an insulating material for forming the second pad isolation pattern 124 and a step of removing a portion of the insulating material.

The step of removing the portion of the insulating material may include performing an etch-back process or a planarization process, but is not limited thereto.

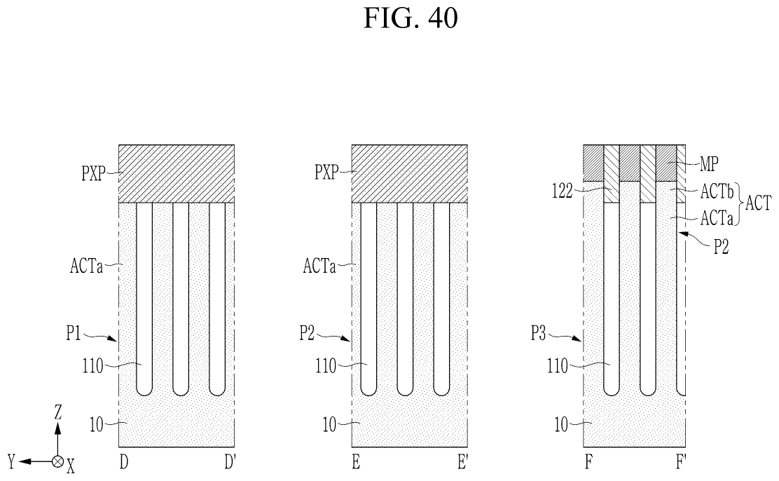

Accordingly, the remaining insulating material constitutes the second pad isolation pattern 124, and the upper surface of the second pad isolation pattern 124 may be positioned at substantially the same level as the upper surface of the first pad isolation pattern 122, the upper surface of the mask pattern MP, and the upper surface of the preliminary contact pad (see ‘PXP’ of FIG. 40), and their upper surfaces may become substantially planar.

Subsequently, the plurality of word line structures WLS may be formed crossing the central portion P3 of the plurality of active regions ACT, extending in the first direction X, and arranged spaced apart in the second direction Y.

Specifically, a plurality of word line trenches extending in the first direction X may be formed by partially removing the central portion P3 of the plurality of active regions ACT and the element isolation layer 110.

One word line trench may be formed in one active region ACT. Accordingly, both end portions of one active region ACT may be classified into the first end portion P1 positioned on one side of the fourth direction DR1 with respect to the word line trench and the second end portion P2 positioned on the other side of the fourth direction DR1.

In addition, as one word line trench may be formed in one active region ACT, the preliminary contact pad having a line shape (see ‘PXP’ in FIG. 41) based on the word line trench may be separated and insulated into the first contact pad XP1 and the second contact pad XP2 respectively connected to the first end portion P1 and the second end portion P2 of the active region ACT.

Accordingly, at each of the first end portion P1 and the second end portion P2 of the active region ACT, the lower surface and the side surface of each of the first contact pad XP1 and the second contact pad XP2 may be positioned in a recess defined by the first portion ACTa and the second portion ACTb of the active region ACT. For example, the lower surface of each of the first contact pad XP1 and the second contact pad XP2 may be in contact with the first portion ACTa of the active region ACT, and the side surface of each of the first contact pad XP1 and the second contact pad XP2 may be in contact with the second portion ACTb of the active region ACT.

As described above, the length of the preliminary contact pad (see ‘PXP’ in FIG. 41) for forming the first contact pad XP1 and the second contact pad XP2 may be substantially the same as the sum of the length of the second portion ACTb of the active region ACT and the length of the active capping pattern 126.

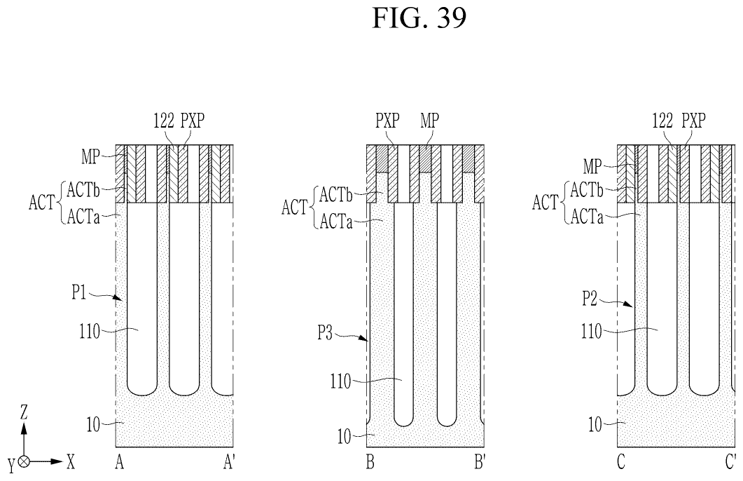

Accordingly, the preliminary contact pad (see ‘PXP’ in FIG. 39), separated and insulated by the word line structure WLS, constitutes the first contact pad XP1 and the second contact pad XP2. Thus, the length of the first contact pad XP1 and the length of the second contact pad XP2 may each be substantially the same as the sum of the length of the second portion ACTb of the active region ACT and the length of the active capping pattern 126.

In cross-section, the word line trench may recess a portion of the active region ACT and a portion of the element isolation layer 110. The word line trench may recess the second portion ACTb of the active region ACT and a portion of the mask pattern (see ‘MP’in FIG. 40).

In addition, in cross-section, the word line trench may extend in the third direction Z between the first contact pads XP1 adjacent to each other and between the second contact pads XP2 adjacent to each other.

Subsequently, the gate insulating pattern GOX may be formed in the word line trench. The gate insulating pattern GOX may be conformally formed along the inner sidewall and bottom surface of the word line trench.

Subsequently, the first gate pattern 132 and the second gate pattern 134 may be sequentially formed on the gate insulating pattern GOX in the word line trench. The first gate pattern 132 and the second gate pattern 134 may constitute the word line WL.

Subsequently, the word line capping layer 136 may be formed on the word line WL. The word line WL and the word line capping layer 136 may fill the word line trench remaining after the gate insulating pattern GOX may be formed.

A step of forming a word line capping layer 136 may include forming an insulating material on the second gate pattern 134 constituting the word line WL, and then performing a planarization process such that upper surfaces of each of the first contact pad XP1, the second contact pad XP2, the mask pattern (see ‘MP’ of FIG. 39), and the first pad isolation pattern 122 may be exposed.

Accordingly, the upper surfaces of the first contact pad XP1, the second contact pad XP2, the mask pattern (see ‘MP’ of FIG. 39), and the first pad isolation pattern 122 may be substantially planar.

The gate insulating pattern GOX, the first gate pattern 132, the second gate pattern 134, and the word line capping layer 136 may constitute the word line structure WLS.

In the step of forming the word line structure WLS, a remaining mask pattern (see ‘MP’ of FIG. 41) may constitute the active capping pattern 126.

Accordingly, the word line structure WLS may be positioned spaced apart from each other with the second portion ACTb of the active region ACT, the active capping pattern 126, and the first pad isolation pattern 122 interposed therebetween.

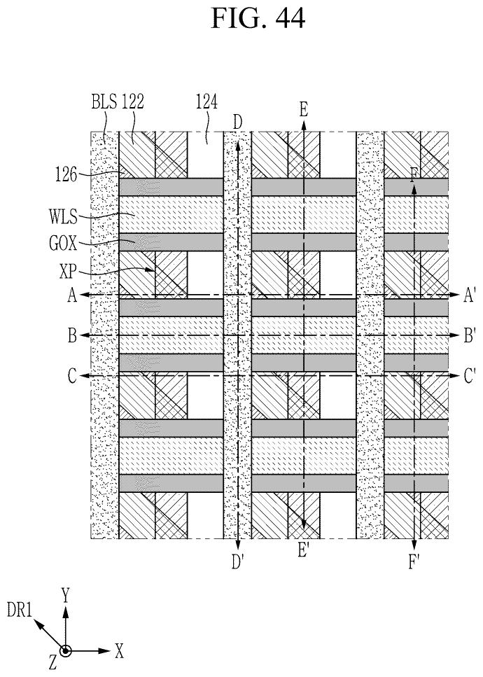

Subsequently, referring to FIGS. 44 to 46, the plurality of bit line structures BLS crossing and extending with the plurality of word line structures WLS may be formed.

The plurality of bit line structures BLS may extend in the second direction Y, and may be formed spaced apart in the first direction X. The bit line structure BLS may extend in the second direction Y so as to cross the first end portion P1 of each of the plurality of active regions ACT.

Specifically, the first conductive layer 142 and the second conductive layer 144 may be sequentially formed on the first contact pad XP1 positioned at the first end portion P1 of the active region ACT. The first conductive layer 142 and the second conductive layer 144 may constitute the bit line BL.

Subsequently, the bit line capping layer 146 may be formed on the second conductive layer 144 constituting the bit line BL. The bit line BL and the bit line capping layer 146 may constitute the bit line structure BLS.

A step of forming a bit line structure BLS may include sequentially stacking the first conductive layer 142, the second conductive layer 144, and the bit line capping layer 146 on an entire surface of a substrate 10, and then patterning the first conductive layer 142, the second conductive layer 144, and the bit line capping layer 146.

The first conductive layer 142, the second conductive layer 144, and the bit line capping layer 146, which remain in the patterning process step, may constitute the bit line structure BLS.

Unlike shown in FIGS. 44 to 46, in which the bit line structure BLS may be formed in a subtractive process, in some embodiments, as shown in FIGS. 12 and 16, after forming the bit line trenches BL_T1 and BL_T2, the bit line spacer 153 and the bit line structure BLS may be sequentially formed in the bit line trenches BL_T1 and BL_T2.

As such, when the bit line structure BLS is formed by a damascene method, patterning defects of patterns constituting the bit line structure BLS may be relatively reduced, in an embodiment, compared to when the bit line structure BLS is formed by the subtractive process.

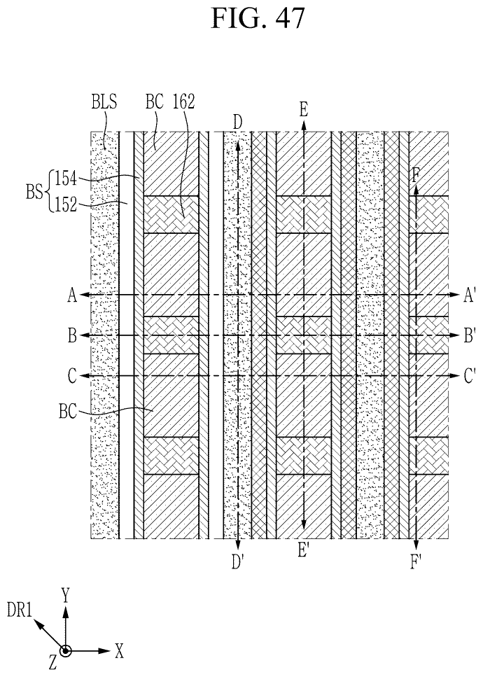

Next, referring to FIGS. 47 to 49, a spacer structure BS may be formed on the side surface of the bit line structure BLS.

Specifically, the first spacer 152 may be formed on both side surfaces of the bit line structure BLS. A step of forming the first spacer 152 may include forming an insulating material for forming the first spacer 152, and removing a portion of the insulating material.

The step of removing the portion of the insulating material may include performing an etch-back process, but is not limited thereto. The insulating material remaining in the step of removing the portion of the insulating material may remain on the side surface of the bit line structure BLS and may constitute the first spacer 152.

Subsequently, the second spacer 154 may be formed on the first spacer 152.

Specifically, a step of forming the second spacer 154 may include the step of conformally forming an insulating material for forming the second spacer 154 and the step of removing a portion of the insulating material.

The step of removing the portion of the insulating material may include, for example, removing a portion of the second spacer 154 positioned between adjacent bit line structures BLS during a patterning process, but is not limited thereto.

In the step of removing a portion of the insulating material, the remaining insulating material may be conformally extended along the upper surface of the bit line structure BLS and the surface of the first spacer 152, and may constitute the second spacer 154.

The first spacer 152 and the second spacer 154 sequentially stacked on the bit line structure BLS may constitute a spacer structure BS.

The insulating material for forming the first spacer 152 may contain silicon oxide, and the insulating material for forming the second spacer 154 may contain silicon nitride, but is not limited thereto.

Subsequently, the storage contact BC may be formed between bit line structures BLS adjacent to each other.

A step of forming the storage contact BC may include forming a storage contact trench that recesses a portion of the first pad isolation pattern 122, the second contact pad XP2, and the second pad isolation pattern 124 between bit line structures BLS, and forming the storage contact in the storage contact trench using a conductive material.

In the step of forming the storage contact trench, as the patterning process may be performed, the inner wall may be defined by the spacer structure BS, the bottom surface may be defined by the first pad isolation pattern 122, the second contact pad XP2, and the second pad isolation pattern 124, and the storage contact trench exposing the second contact pad XP2 may be formed.

The storage contact trench may extend in the second direction Y between adjacent spacer structures BS, and may have a line shape in a plan view.

The step of forming a conductive material in the storage contact trench may include a step of forming a conductive material for forming the storage contact BC so as to fill the storage contact trench, and a step of performing a planarization process with respect to the conductive material.

The conductive material for forming the storage contact BC may be, for example, doped polysilicon, but is not limited thereto.

Accordingly, the conductive material for forming the storage contact BC may be formed on the second contact pad XP2 at the second end portion P2 of the active region ACT, and the upper surface of the conductive material for forming the storage contact BC may be positioned at substantially the same level as the upper surface of the second spacer 154.

Subsequently, as the fence pattern 162 for separating and insulating the conductive material for forming the storage contact BC may be formed, the plurality of storage contacts BC may be formed.

The fence pattern 162 may be formed between spacer structures BS that are adjacent to each other. Between adjacent spacer structures BS, the fence pattern 162 may separate and insulate the conductive material for forming the storage contact BC into the plurality of storage contacts BC. For example, the fence pattern 162 may be formed between the plurality of storage contacts BC that are adjacent to each other in the second direction Y.

A step of forming the fence pattern 162 may include a step of forming a fence trench by patterning a conductive material for forming a storage contact BC, a step of filling an insulating material for forming the fence pattern 162 in the fence trench, and a step of performing a planarization process on the insulating material.

Specifically, an inner wall of the fence trench may be defined by the conductive material for forming the storage contact BC, and a bottom surface may be defined by the word line capping layer 136. The fence trench may recess a portion of the word line capping layer 136. However, it is not limited thereto, and the configuration defining the inner wall and the bottom surface of the fence trench may be variously modified.

Subsequently, after forming the insulating material for forming the fence pattern 162 in the fence trench, a planarization process may be performed on the insulating material, so that the fence pattern 162 may be formed, and the upper surface of the fence pattern 162 may be substantially planar with the upper surface of the storage contact BC.

The insulating material for forming the fence pattern 162 may be, for example, silicon nitride, but is not limited thereto.

In the step of forming the fence pattern 162, a portion of the bit line structure BLS and a portion of the spacer structure BS may be removed together. Accordingly, the fence pattern 162 formed between the bit line structures BLS may cover the upper surface of the bit line structures BLS and the upper surface of the spacer structures BS.

Subsequently, referring to FIGS. 50 to 52, the landing pad LP and the insulating pattern 164 may be formed on the storage contact BC.

Specifically, the step of forming the landing pad LP may include a step of removing a portion of the storage contact BC. The step of removing a portion of the storage contact BC may include performing an etch-back process, but is not limited thereto.

As a portion of the storage contact BC may be removed, the storage contact BC may fill a portion of the region between the bit line structures BLS adjacent to each other. The upper surface of the storage contact BC may be positioned at a lower level than the upper surface of the bit line structure BLS.

In the process steps of removing a portion of the storage contact BC, a portion of the bit line structure BLS and a portion of the spacer structure BS may be removed together.

Subsequently, the landing pad LP may be formed on the storage contact BC.

The step of forming a landing pad LP may include sequentially forming the silicide layer 172 and the pad conductive layer 174 on the storage contact BC.

The silicide layer 172 may be formed on the upper surface of the storage contact BC. The pad conductive layer 174 may be formed to overlap at least a portion of the storage contact BC in the third direction Z. A portion of the pad conductive layer 174 may be formed on the bit line structure BLS and the spacer structure BS, and the remaining portion may be formed on the storage contact BC. The silicide layer 172 and the pad conductive layer 174 may constitute the landing pad LP.

Subsequently, after patterning the pad conductive layer 174 configuring the landing pad LP, the insulating pattern 164 for separating and insulating the landing pad LP may be formed.

A step of forming the insulating pattern 164 may include forming an insulating pattern trench by patterning the pad conductive layer 174 constituting the landing pad LP, thereby recessing a portion of the bit line structure BLS, a portion of the spacer structure BS, and a portion of the fence pattern 164, and then forming an insulating material in the insulating pattern trench followed by a planarization process.

The insulating material for forming the insulating pattern 164 may be silicon nitride, but is not limited thereto. The insulating pattern 164 may be positioned on the bit line structure BLS and the spacer structure BS, and may recess portions of each of them.

In the step of forming the insulating pattern 164, as a planarization process may be performed, the upper surface of the insulating pattern 164 and the upper surface of the landing pad LP may be positioned at substantially the same level.

In the embodiment illustrated in FIGS. 50 to 52, after forming the landing pad LP by a subtractive process, the insulating pattern 164 may be formed, but the order of forming the landing pad LP and the insulating pattern 164 is not limited thereto.

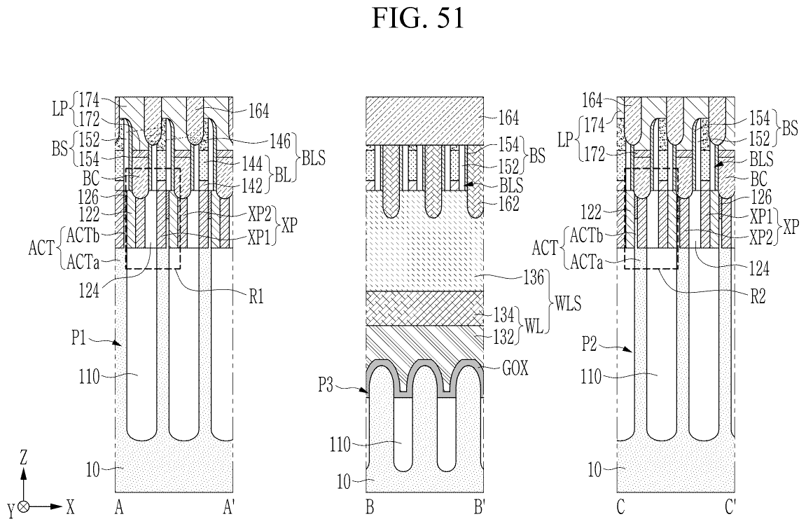

Unlike illustrated in FIGS. 51 to 53, in some embodiments, a portion of the landing pad LP may be formed between adjacent bit line structures BLS by a damascene process, and the insulating pattern 164 may be formed on the portion of the landing pad LP.

Subsequently, a portion of the insulating pattern 164 may be patterned to expose a portion of the landing pad LP, and the landing pad LP and the insulating pattern 164 may be formed by a damascene process, in which the remaining portion of the landing pad LP is formed.

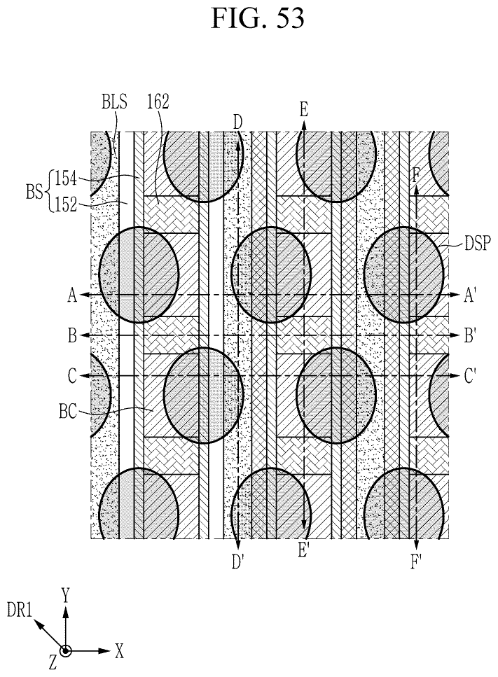

Subsequently, referring to FIGS. 53 to 55, the etch stop layer 180 and the capacitor DSP may be sequentially formed on the landing pad LP and the insulating pattern 164.

Specifically, the etch stop layer 180 may be formed on the landing pad LP and the insulating pattern 164. The etch stop layer 180 may contain, for example, silicon nitride, but is not limited thereto.

Subsequently, after patterning the etch stop layer 180 to expose the landing pad LP, the first electrode 192 on the landing pad LP, the dielectric layer 194 covering the first electrode 192, and the second electrode 196 positioned on the dielectric layer 194 may be sequentially formed.

The first electrode 192, the dielectric layer 194, and the second electrode 196 may constitute the capacitor DSP.

A method of manufacturing a semiconductor device according to an embodiment includes forming a mask pattern on a substrate, patterning the substrate to form an active region extending in a first direction, the active region including a first portion and a second portion extending in a vertical direction from the first portion, forming a preliminary contact pad in contact with the first portion and the second portion of the active region and extending in a second direction crossing the first direction, forming a word line structure extending in a third direction crossing the first direction and the second direction, and forming a bit line structure on the preliminary contact pad extending in the second direction, and wherein in the step of forming the word line structure, the preliminary contact pad is separated into a first contact pad and a second contact pad by the word line structure, and the first contact pad is connected to the bit line structure.

The method of manufacturing the semiconductor device may further include a step of forming a storage contact connected to the second contact pad.

The sum of the length of the mask pattern in a vertical direction and the length of the second portion of the active region in the vertical direction may be substantially equal to the length of the preliminary contact pad in the vertical direction.

The method of manufacturing the semiconductor device may further include a step of forming an element isolation layer after forming the active region, and the upper surface of the element isolation layer may be positioned at substantially the same level as the upper surface of the first portion of the active region.

The maximum width of the first portion of the active region in the third direction may be substantially equal to the sum of the maximum width of the second portion in the third direction and the maximum width of the preliminary contact pad in the third direction.

While the embodiments of the invention have been described in detail above, the scope of rights of the invention is not limited thereto, and various modifications and improvements by those skilled in the art using the basic concepts of the invention as defined in the following claims are also within the scope of rights of the invention.

What is claimed is:

1. A semiconductor device comprising:
a substrate including an active region extending lengthwise in a first direction, the active region comprising a first end portion, a central portion, and a second end portion spaced apart from the first end portion by the central portion in the first direction;
a word line structure extending lengthwise in a second direction crossing the first direction, the word line structure being positioned in the central portion of the active region;
a bit line structure extending lengthwise in a third direction crossing the first direction and the second direction, the bit line structure being connected to the first end portion of the active region;
a landing pad electrically connected to the second end portion of the active region;
a first contact pad positioned between the first end portion of the active region and the bit line structure; and
a second contact pad positioned the second end portion of the active region and the landing pad,
wherein the active region includes:
a first portion positioned at a level lower than the first contact pad and the second contact pad in a fourth direction perpendicular to the first direction, the second direction, and the third direction, and
a second portion extending in the fourth direction from the first portion along a side surface of the first contact pad and the second contact pad,
wherein the first portion of the active region overlaps the first contact pad, the second contact pad, and the second portion in the fourth direction.

2. The semiconductor device of claim 1, further comprising:
a storage contact disposed between the second contact pad and the landing pad, and
wherein the storage contact is electrically connected to the second end portion of the active region.

3. The semiconductor device of claim 2,
wherein the maximum width of each of the first contact pad and the second contact pad in the second direction is less than the maximum width of the first portion of the active region in the second direction, and
the maximum width of each of the first contact pad and the second contact pad in the second direction is greater than the maximum width of the second portion of the active region in the second direction.

4. The semiconductor device of claim 3,
wherein the sum of the maximum width in the second direction of the first contact pad and the maximum width in the second direction of the second portion of the active region is the same as the maximum width in the second direction of the first portion of the active region, and
wherein the sum of the maximum width in the second direction of the second contact pad and the maximum width in the second direction of the second portion of the active region is the same as the maximum width in the second direction of the first portion of the active region.

5. The semiconductor device of claim 2, further comprising:
an element isolation layer positioned in the substrate and defining the active region,
wherein the first contact pad includes a first contact first pad portion positioned on the first portion of the active region and a first contact second pad portion positioned on the element isolation layer, and
wherein the second contact pad includes a second contact first pad portion positioned on the first portion of the active region and a second contact second pad portion positioned on the element isolation layer.

6. The semiconductor device of claim 5,
wherein the lowermost surface of the first contact first pad portion is positioned at a lower level in the fourth direction than the lowermost surface of the first contact second pad portion.

7. The semiconductor device of claim 2,
wherein the lowermost surface of the bit line structure and the lowermost surface of the storage contact are positioned at different levels.

8. The semiconductor device of claim 1,
wherein the lowermost surface of each of the first contact pad and the second contact pad is in contact with the first portion of the active region, and
the side surface of each of the first contact pad and the second contact pad is in contact with the second portion of the active region.

9. The semiconductor device of claim 1,
wherein the first contact pad and the second contact pad contain comprise doped polysilicon.

10. The semiconductor device of claim 1, wherein the second contact pad is in contact with the landing pad.

11. A semiconductor device comprising:
a substrate including an active region extending lengthwise in a first direction, the active region comprising a first end portion, a second end portion, and a central portion between the first end portion and the second end portion in the first direction;
a word line structure extending lengthwise in a second direction crossing the first direction and positioned at the central portion of the active region;
a bit line structure extending lengthwise in a third direction crossing the first direction and the second direction and connected to the first end portion of the active region;
a storage contact connected to the second end portion of the active region; and
a plurality of contact pads including a first contact pad positioned between the first end portion of the active region and the bit line structure, and a second contact pad positioned between the second end portion of the active region and the storage contact,
wherein the active region includes:
a first portion positioned at a lower level than the plurality of contact pads in a fourth direction perpendicular to the first direction, the second direction, and the third direction, and
a second portion extending in the fourth direction from the first portion along a side of the plurality of contact pads,
wherein the first portion of the active region overlaps the plurality of contact pads and the second portion in the fourth direction, and
wherein the uppermost surface of the first contact pad and the uppermost surface of the second contact pad are each positioned at different levels in the fourth direction.

12. The semiconductor device of claim 11,
wherein each lowermost surface of the first contact pad and the second contact pad is positioned at a lower level in the fourth direction than the uppermost surface of the second portion of the active region, and
each uppermost surface of the first contact pad and the second contact pad is positioned at a higher level in the fourth direction than the uppermost surface of the second portion of the active region.

13. The semiconductor device of claim 11,
wherein the uppermost surface of the first contact pad contacting the bit line structure is positioned at a lower level in the fourth direction than the uppermost surface of the second contact pad contacting the storage contact.

14. The semiconductor device of claim 11,
wherein the uppermost surface of the first contact pad is positioned at the same level in the fourth direction as the uppermost surface of the second portion of the active region, and
the uppermost surface of the second contact pad is positioned at a level lower in the fourth direction than the second portion of the active region.

15. The semiconductor device of claim 11, further comprising:
an element isolation layer positioned in the substrate and defining the active region,
wherein the uppermost surface of the element isolation layer is positioned at the same level in the fourth direction as the uppermost surface of the first portion of the active region, and
each of the first contact pad and the second contact pad overlaps the element isolation layer in the fourth direction.

16. A semiconductor device comprising:
a substrate including an active region extending lengthwise in a first direction and including a first end portion and a second end portion spaced apart from each other by a central portion in the first direction;
a word line structure extending lengthwise in a second direction crossing the first direction and the central portion of the active region;
a bit line structure extending lengthwise in a third direction crossing the first direction and the second direction and connected to the first end portion of the active region;
a storage contact connected to the second end portion of the active region;
a landing pad positioned on the storage contact;
a capacitor positioned on the landing pad;
a first contact pad positioned between the first end portion of the active region and the bit line structure; and
a second contact pad positioned between the second end portion of the active region and the storage contact,
wherein the active region includes:
a first portion positioned at a lower level than the first contact pad and the second contact pad in a fourth direction perpendicular to the first direction, the second direction, and the third direction, and
a second portion extending in the fourth direction from the first portion along side surfaces of the first contact pad and the second contact pad,
wherein the first portion of the active region overlaps the first contact pad, the second contact pad, and the second portion in the fourth direction,
wherein the uppermost surface of the second portion of the active region is positioned at a lower level in the fourth direction than the uppermost surface of the first contact pad and the uppermost surface of the second contact pad.

17. The semiconductor device of claim 16, further comprising:
an active capping pattern overlapping the second portion of the active region in the fourth direction, and
wherein the active capping pattern extends along each side surface of the first contact pad and the second contact pad.

18. The semiconductor device of claim 17,
wherein the length of the first contact pad in the fourth direction is the same as the sum of the length of the second portion of the active region in the fourth direction and the length of the active capping pattern in the fourth direction.

19. The semiconductor device of claim 17,
wherein the maximum width of the second portion of the active region in the second direction is the same as the maximum width of the active capping pattern in the second direction.

20. The semiconductor device of claim 16,
wherein the uppermost surface of the first contact pad contacting the bit line structure is positioned at a higher level in the fourth direction than the uppermost surface of the second contact pad contacting the storage contact.
